(19) United States
(12) Patent Application Publication
(10) Pub. No.: US 2024/0202405 A1
(43) Pub. Date: Jun. 20, 2024

(54) METHOD AND SYSTEM FOR ANALYZING AND ESTABLISHING TRUST IN SYSTEMS THAT INCLUDE ARTIFICICAL INTELLIGENCE SYSTEMS

(71) Applicant: ObjectSecurity LLC, San Diego, CA (US)

(72) Inventors: Ulrich LANG, San Diego, CA (US); Reza FATAHI, Encino, CA (US); Jason KRAMER, Studio City, CA (US); Brendan WEIBEL, Bellevue, WA (US)

(73) Assignee: ObjectSecurity LLC, San Diego, CA (US)

(21) Appl. No.: 18/196,950

(22) Filed: May 12, 2023

Related U.S. Application Data
(60) Provisional application No. 63/342,049, filed on May 13, 2022.
(60) Provisional application No. 63/396,287, filed on Aug. 9, 2022.
(60) Provisional application No. 63/443,859, filed on Feb. 7, 2023.
(60) Provisional application No. 63/458,741, filed on Apr. 12, 2023.

(51) Int. Cl. G06F 30/27

(52) U.S. Cl. CPC G06F 30/27

(57) ABSTRACT

Method and system for analyzing a computing system for properties of a machine learning model in the computing system include loading input data for the machine learning model; generating a surrogate model that simulates the behavior and/or characteristics, or an approximation of the behavior and/or the characteristics of the machine learning model, by using segments or an entirety of the loaded input data; adjusting the input data and/or the surrogate model to enable an analysis; loading and executing the analysis of a correlation between inputs and outputs of the surrogate model to identify a result pertaining to the input data and/or the machine learning model; generating an output data describing the result; storing the output data pertaining to the result in the memory; determining if the result satisfies a predetermined condition, and if so, executing an action corresponding to the result on the computing system.

This application claims priority to U.S. Provisional Application Nos. 63/342,049 entitled “Method and System for Analyzing and Protecting Machine Learning Systems”, 63/396,287 entitled “Method and System for Analyzing and Protecting Machine Learning Systems”, 63/443,859 entitled “Method and System for Measuring and Explaining Complex Deep Neural Networks”, and 63/458,741 entitled “Method and System for Reverse Engineering AI/ML Components”, which were filed on May 13, 2022, Aug. 9, 2023, Feb. 7, 2023 and Apr. 12, 2023 respectively, and which are all incorporated herein by reference.

This invention was made with government support under FA8750-22-C-0075 awarded by United States Air Force. The government has certain rights in the invention.

### BACKGROUND OF THE INVENTION

### 1. Field of the Invention

This application relates generally, but not exclusively, to a novel method relating to analyzing computing systems, including, but not limited to, those including artificial intelligence (AI), such as but not limited to, data science, machine learning, etc. More particularly, embodiments of the invention are directed at automatically and semi-automatically training, detecting, analyzing, monitoring, protecting, and hardening AI systems and their components, including dependencies, binaries, source code, data, etc., to improve the system's trust, reliability, accuracy, fairness, security, etc., and protect it from potential vulnerabilities, weaknesses, threats, limitations, etc.

### 2. Description of the Related Art

### INTRODUCTION

Artificial intelligence (AI) is a field, which combines computer science and robust datasets, to enable problem-solving, often performing complex tasks that simulate human intelligence processes. Several areas fall under the umbrella term of artificial intelligence, including (but not limited to) machine learning, data science (DS), computer vision, natural language processing (NLP), deep learning (DL), expert systems, etc., and they can work inside of or alongside other systems like models and simulations. Artificial intelligence systems can perform a variety of tasks, including image classification, natural language processing, image and video analysis, decision-making, recommend products, play video games, control robots, synthesize speech, generate text and images, generate code, monitoring and surveillance and many other tasks. In addition, they are being increasingly used to make (often autonomous) mission critical decisions in sectors such as in defense, critical infrastructure, finance, healthcare, energy, automotive, oil and gas, etc. For example, AI systems are being used to perform robotic surgeries, detect cancers, and create new medicines in healthcare. They are being used to guide self-driving vehicles, lane detection, and anomalous part detection on assembly lines in the automotive industry. The use of AI can help improve efficiency and accuracy of tasks, reduce costs, and lead to innovative intelligent systems that can help improve people's lives.

These models are typically trained with large volumes of data with specific parameters that optimally learn patterns from the given data and from specific features. Once they have been trained, they may be used to make predictions on new data. Benefits of artificial intelligence include being able to rapidly analyze large volumes of data that would otherwise take humans days, weeks, or even months to sift through, detect patterns that are not as apparent to humans, generate new data, operate in hazardous environments, perform tasks with high accuracy and consistency, etc.

While AI systems can be very beneficial, there are also disadvantages and risks to using them. These AI systems are typically trained as black-boxes with very little insight into their decision-making and underlying behavior. Therefore, it is difficult to ensure AI systems are working as intended, and they are difficult to audit. For example, AI systems may be perpetuating biases present in their training data, such as discrimination against race and gender. It is also difficult to obtain sufficient data for training, and training samples may not cover out-of-distribution (OOD) data. In addition, they may be prone to adversarial attacks, wherein an attack manipulates the AI model or data (incl. training or inference data) in a way that affects the model's behavior and decision-making. Since AI models are usually expensive to train and operate, are often highly proprietary, and frequently provide information about crucial systems and their data and behavior, they are also a target for theft. They may also lead to safety, privacy, and security hazards. Training models can also be a time consuming and resource-intensive process that includes lots of trial and error. Due to these challenges, there is an increasing need in the industry for flexible and scalable tools that aid in the training of AI systems, mitigate potential risks, explain the underlying behavior of the system, and ensure they are compliant and safe against adversarial attacks as well as other risks and vulnerabilities. The following section includes more background details about some of these gaps in conventional AI systems. There is a need for better mechanisms and tools that ensure AI systems are accurate, reliable, explainable, robust, transparent, non-biased, fair, flexible, scalable, safe, and secure.

### Automated Training

Conventional automated AI training tools do not include explainability, do not have a reinforcement learning mechanism, do not consider metrics beyond accuracy like robustness, safety, security, privacy, biases, and transparency, and are limited in the frameworks, model, and data they support. Training AI systems is a challenging task that requires large volumes of data, access to adequate computing resources, as well as expertise about frameworks, models, and how to optimize data for AI, etc. Selecting the most suitable framework and model for a given use case can be challenging and result in a time-consuming process of trial and error. Each decision made before and during the training process can heavily affect the resulting model. The amount of data used for training and the quality and variability of that data can greatly impact the resulting model as well.

In recent years, there has been a push towards Automated Machine Learning (AutoML), wherein machine learning engineers and data scientists are aided in the process of selecting and building a model. However, conventional AutoML systems have many disadvantages and challenges associated with them. One challenge with conventional AutoML systems is the lack of control that users have over their models. AI systems are already typically trained as black-box models with very little insights into their behavior, so using conventional AutoML tools can result in even less knowledge of how the system was developed and why specific decisions were made prior and during training. Additionally, if updates or changes need to be made to the model, conventional AutoML systems typically do not handle them or understand what or why these changes need to be made. Additionally, they are typically trained to optimize accuracy, but there are other important factors that should be considered, such as robustness, safety, security, privacy, biases, transparency, etc. In addition, multiple AI systems may need to be trained to work concurrently, which is not supported by conventional AutoML systems. They do not provide details on how to repeat the steps taken by the system, why those steps were taken, and do not provide a report for auditability. This lack of accountability can be especially dangerous in mission critical applications where understanding and being able to trust the decision-making of the system is crucial.

Moreover, conventional AutoML systems are typically slow and require users to start over every time there is a change to the dataset or the model. Many do not support parallel, distributed, or other mechanisms of improving the efficiency of the training process. They are also not very flexible, wherein they only support a subset of available frameworks. Therefore, engineers are currently reliant on multiple AutoML systems for training models from frameworks not supported by a singular AutoML system. They are also limited to the types of data they support, and the types of objectives the AI system may have. They often lack customization and are limited to a few predefined model types. There is also no improvement based on previous results or reinforcement mechanism, where they are no table to effectively learn from prior results to improve future AutoML training. Lastly, conventional automated systems typically do not support more complex models, such as Large Language Models (LLMs), generative adversarial networks (GANs), transformers, etc.

### Adversarial Attacks

Conventional AI systems are prone to adversarial attacks. On the flipside, adversarial attacks and defenses typically only work on a subset of models and are generally not scalable to more complex models. AI systems are being increasingly used across many industries, making these systems more susceptible to attacks and widening the attack surface. Ensuring the safety and security of AI systems may be critical to protecting proprietary data, a company's reputation, and people's lives. For example, an attack on an automotive vehicle's self-driving AI system could result in catastrophic consequences, such as a dangerous crash, which could lead to injuries and harm to the public's trust in the company, its products, and its reputation. There has been a significant increase in research into the risks and vulnerabilities of AI systems, which include adversarial attacks that attempt to trick the system into revealing proprietary data or affecting its decision-making. These attacks often include small perturbations to input data that are difficult for a human to detect but drastically affect the AI system's decision-making process. An attack can take place before, during or after training, and before, during or after inference. For example, an attacker may introduce malicious data to the training data to introduce a backdoor to the system, reduce the model's accuracy, introduce biases, etc. Another example is of an evasion attack, where an attacker provides specific data during inference to attack the model. Since these attacks are often difficult to detect, they are very dangerous and impactful. Adversarial attacks also include black-box, white-box, and gray-box attacks. Other examples include physical environment attacks, copy-cat attacks, model extraction attacks, model inversion attacks, patch attacks, byzantine attacks, as well as others.

Conventional tools for testing models for adversarial attacks are suboptimal. They are not very flexible or generalizable, and typically only cover a limited number of framework, model, and data types. They are also not scalable, and are mostly reliant on the input data provided by a user to generate the attacks. They require a high level of expertise in AI and often are only semi-automatic at best. They also lack a specific scoring mechanism for determining how robust the system is, if it is safe enough to deploy, and what changes need to be made to the system. Another challenge is that AI technology is rapidly evolving, making it difficult to keep up with the attack surface. In addition, conventional tools for defending and hardening AI systems have many challenges and disadvantages. Currently, far more adversarial attacks than adversarial defenses exist. Additionally, they are typically optimized to be robust against a specific type of attack. Then, when new types of attacked data are introduced, they are not robust against those attacks. Adversarial attacks are also constantly evolving, making it difficult to quickly create defenses that adapt to them. Conventional tools for adversarial defense also suffer from many of the same issues as adversarial attacks, such as not being flexible or generalizable and only covering a limited number of framework, model, and data types, requiring a high level of expertise, not scalable, etc. They are also often not adaptable to the data, framework, model, objective, and the specific vulnerabilities of the model. Moreover, conventional approaches to adversarial defense are tested on baseline models but are not tested on more complex models or larger models. As a result, using conventional adversarial attack and adversarial defense tools can be a time-consuming process and difficult to use and keep up with.

### Explainability

Conventional AI systems do not easily provide robust explainability. One major challenge of training and using AI systems is the lack of visibility into the systems and how they come to their decisions. Knowing this information is crucial for being able to trust the system and having a clear understanding of the steps taken to come to a decision. AI systems are typically provided training data and specific configurations, and directed to automatically learn patterns in the training data. This mechanism inherently leads to a lack of explainability and transparency in the model. AI systems usually do not explain their decision making, which makes it more difficult to trust and adopt AI systems, especially for mission-critical environments and AI systems connected to the physical world. Explainability can greatly impact other aspects like robustness, fairness, privacy, etc., since it provides engineers more transparency into how the model is behaving and if it is meeting expectations and standards. Explainability can for example be presented in the form of text-based and visual-based explanations that describe how the model came to its decision. In turn, this results in more confidence and trust in the model's predictions. It can also decrease burdens related to compliance, auditing, debugging, and risk management, wherein it can be used to prove that the model is acting in a compliant and safe manner. In summary, explainability can greatly improve the trust of AI systems, detect and mitigate biases, ensure privacy of data, analyze robustness, etc.—but conventional approaches and tools make it challenging to produce robust explainability.

### Fairness

Conventional AI systems are prone to fairness issues, and existing approaches to ensure fairness of AI systems are very limited. In particular, bias is becoming an increasingly prevalent issue for AI systems and is increasingly being introduced into risk management frameworks like the NIST AI Risk Management Framework, and there are several pushes towards addressing AI bias through government legislature. Bias can be introduced through biased training data, such as historic data that perpetuated discrimination and is now being used to train an AI system. Data in a reinforcement learning system that is biased may also affect the model during training. An AI system may also learn incorrect features during training. For example, a computer vision classifier that is given the task of differentiating polar bears and black bears. But rather than learning features about the bears, it classifies images based on patterns in the backgrounds of the images. When it is provided an image of a polar bear in a zoo after training, it classifies the image as a black bear based off of the background. Biases in AI systems can be significant and can negatively impact individuals and groups and lead to incorrect or unethical decisions by the AI system. Furthermore, data can change over time, especially in historical models, which can cause the model to drift and became biased over time. There is a need for AI systems to be trained fairly and according to specific standards, and to account for data that may be missing or unbalanced during training.

Determining the fairness of a model and its data is often subjective and depends on the context and objective of the model being trained. What is considered to be fair in one situation may not be fair in another situation. There is no one-size-fits-all solution to approaching bias in AI, making it difficult to ensure that a model is fair and meets compliance standards. If the data available for training contains biases (e.g., data that was created with human bias, such as racial bias), then those same biases will likely be present and amplified in the resulting model.

### Privacy

Conventional AI systems raise privacy concerns. With the rapid adoption of AI, large amounts of data are being collected and used for training (and inference), resulting in privacy concerns. In particular, AI systems may be fed sensitive personal data about users. This data is at risk of being obtained by an attacker trying to obtain the original data (e.g., through data breaches, inversion attacks, etc.). Use of this data may also affect the original user's privacy, such as leaking private information about users or defaming users if the information is untrue. Ensuring privacy can help minimize these risks to prevent sensitive information from being leaked or users at all in AI. There are many challenges that exist with ensuring privacy of personal and confidential information such as the sheer volume of data being used, difficulties with anonymizing data, models memorizing training data, and access to the model granted to users.

### Embedded Environments

AI is increasingly becoming present in embedded environments, while conventional approaches to identifying, analyzing and/or hardening AI systems in embedded environments are very limited. Conventional approaches are not flexible, are limited in framework, model, and data types, and are not scalable. At the same time, the attack surface in embedded environments is often much larger and the impacts can be much more damaging. Embedded environments that comprise AI systems include, but are not limited to, headsets, mobile devices, smart homes, smart bulbs, smart refrigerators, voice-controlled audio speakers, edge devices, fog devices, augmented reality systems, virtual reality systems, gaming systems, quantum systems, mobile devices, tablets, vehicles, spacecraft, smart implants, network systems, cameras, sensors, smart watches, computing devices, etc. These systems are being increasingly adopted across a wide variety of sectors, partly due to advancements to hardware (e.g., FPGAs, GPUs, TPUs, memory, storage, etc.) and software technology (e.g., cloud computing, AI/ML compression and compiling, etc.) that have enabled more efficient and scalable computing. These devices are being used across a variety of sectors, such as for example in defense, aerospace, transportation, energy, oil and gas, manufacturing, water treatment plants, healthcare etc.

AI systems can be deployed directly to embedded devices. This is partly due to improvements in model efficiency and accuracy, and advancements to AI technology such as generative AI. Since these systems may have the potential to impact the physical environment, the impacts, risks, and potential for cyber/physical damage of AI systems is often much greater than in traditional non-embedded information systems. This also makes the impact of biases and adversarial attacks significantly greater as well.

Securing AI systems in embedded environments comes with many unique risks and challenges. They are more prone to physical attacks and physical damage (incl. injury and loss of life), since they are often interacting with the physical world (e.g., autonomous vehicles, robots etc.). Embedded systems are often operating autonomously and often do not have direct monitoring capabilities (e.g., with humans in the loop), especially for AI systems and for systems that run in an offline environment. These devices can be connected to potentially many (e.g., thousands) sensors, and a single sensor affected by an attack could lead to a domino effect of errors and incorrect decisions downstream by the AI model. These models may also be difficult to monitor, since they are currently often provided in either binary or low-level language format. They may be hard to obtain, and even if they are obtained, it may be challenging to run the AI model independently to be able to test it. Again, even if the model is able to be run independently, some knowledge of the data formats the model requires and any preprocessing steps needed to be taken likely need to be known. End-users may not even be aware that their system contains AI components and would therefore be unaware of the potential attack surface. There are many other challenges with analyzing AI in embedded environments, such as transparency, safety, security, fairness, etc., which are described in further detail in other sections.

As AI is currently being rapidly adopted across many industries, it is crucial that models are accurate, reliable, explainable, transparent, fair, safe, and secure. This is especially the case (but not limited to) in embedded environments where the attack surface is much larger and the impacts can be much more damaging. There are many gaps in conventional approaches, such as AI systems not being flexible, being limited in framework, model, and data types, and not being scalable. Conventional adversarial attacks and defenses typically only work on a subset of models and are generally not scalable to more complex models. Conventional AutoML tools do not include explainability, do not have a reinforcement learning mechanism, do not consider metrics beyond accuracy like robustness, safety, security, privacy, biases, and transparency, and are limited in the frameworks, model, and data they support. There is a need for better mechanisms and tools for accurate automated analysis, defense, and hardening of machine learning models and their components, ensuring AI systems are accurate, reliable, explainable, robust, transparent, non-biased, fair, flexible, scalable, safe, and secure.

### SUMMARY OF THE INVENTION

Herein are some examples of how the invention may be implemented. Note this list is not exhaustive, and the invention may be created in some other manner similar in function, but not within the example's exact specification. It is therefore an object of the invention to provide:
proactively ensuring trust in computing systems and their components, such as (but not limited to) using surrogate model analysis and explainability techniques to determine weaknesses, vulnerabilities, anomalies, and errors with the system and, for example, to automatically harden the system to mitigate them;
reactively protecting and hardening one or more computing system. For example, this may be accomplished by using surrogate model analysis to analyze the inputs and outputs of the system and detect adversarial attacks on the system;
one or more surrogate models may be automatically generated by the analysis system to analyze models and their data. The surrogate models may be trained using one or more mechanisms, including but not limited to, polynomial regressions, decision trees, sparse identification of nonlinear dynamics (SINDy), dynamic mode decomposition with control (DMDc), support vector machines, neural networks, forward stepwise regression, least absolute shrinkage and selection operator (LASSO), sequentially thresholded Ridge regression (STLSQ), sparse relaxed regularized regression (SR3), stepwise sparse regression (SSR), forward regression orthogonal least-squares (FROLS), mixed-integer optimized sparse regression (MIOSR), etc.;
reverse engineering of computing system files and components. This many include, but is not limited to, reverse engineering firmware source code, JIT, binaries, bytecode, images, serialized data, configuration files, etc. Files may be detected and extracted from a system, analyzed for their file types, mime types, and underlying components (e.g., the type of models and algorithms used), and imported into the analysis system for further analysis;
a technique referred to as “automated training” may be performed for automatically training, fine-tuning, and/or hardening one or more models. This may include, but is not limited to, training one or more models for one or more systems by selecting the most optimal features, hyperparameters, configurations, frameworks, architectures, etc. The result may be one or more trained models that may be automatically configured for deployment;
using for example explainability, interpretability, and transparency approaches to provide explanations of (but not limited to) the underlying behavior of an AI system, its decision-making, and outputs to allow end-users to have more trust in their systems. Explanations may be assessed by properties such as, but not limited to, accuracy, fidelity, comprehensibility, certainty, representativeness, etc., and a reinforcement mechanism may be used to continually improve explanations;
computing system(s) may be automatically or semi-automatically monitored and analyzed before, during, and after training and deployment. For example, the analysis system can use surrogate model analysis to generate surrogate models based on data during runtime and ensure the inputs and outputs are free of adversarial attacks and boundary violations. The monitoring system can track the performance of the system over time and ensure that the model accuracy, robustness, and/or security remains trustworthy and up to required standards;
the analysis system may automatically or semi-automatically generate adversarial attacks to test the computing systems against. For example, it may calculate the gradient descent of the model and perturb data along the gradient descent. In another example, for an NLP model, the analysis system may iteratively swap words for synonyms until predictions are changed;
the analysis system may lift computing systems and their components into an intermediate representation, for example, to normalize/standardize the systems under analysis. For example, machine learning models may be lifted to an intermediate representation wherein their training information, as well as their data for inference, are lifted into a common proprietary format. Models may be analyzed in a consistent manner;
detecting and/or analyzing AI components in virtual machines and containerized and virtual environments;
one or more hardware devices may be connected to the analysis system, and one or more systems may be used for the tasks performed by the analysis system. For example, distributed computing techniques may be used with one or more high-performance computing (HPC) devices for training multiple surrogate models in parallel, which could significantly increase the speed and efficiency of analyses;
AI and/or characteristics of AI, may be detected in computing systems by analyzing for example inputs and outputs;
one or more corpuses of AI code segments may be generated and/or aggregated. These corpuses may include, but are not limited to, source code, binary code, JIT code, assembly code, etc.;
an AI system may be translated into one or more intermediate representations;
the analysis system may be used for attacking AI systems to, for example, determine how secure the system is against attacks;
data sources may be analyzed to determine, for example, if they contain any anomalies and if they are susceptible to model drift; and/or
binaries may be reverse engineered to determine, for example, if they contain any AI components, to generate an abstract representation, if they contain any known AI frameworks, to import the model, etc.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description. For example, singular or plural use of terms are illustrative only and may include zero, one, or multiple; the use of “may” signifies options; modules, steps and stages can be reordered, present/absent, single or multiple etc.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 depicts a high-level example of an analysis system including inputs, outputs, and/or purposes;

FIG. 2 depicts an example UI/UX for receiving AI components;

FIG. 3 depicts an example workflow through assisted surrogate;

FIG. 4 depicts an example architecture for surrogate automated training for generating one or more surrogate models;

FIG. 5 depicts a function of the invention for a human-in-the-loop reinforcement mechanism for surrogate automated training;

FIG. 6 depicts a function of the invention for using surrogate model analysis for analyzing attacks;

FIG. 7 depicts a function of the invention for reinforcing layer(s) of a model with surrogate automated training;

FIG. 8 depicts a function of the invention for discovering and interpreting bias in arbitrary model training datasets;

FIG. 9 depicts a function of the invention determining the types of biases present in a model;

FIG. 10 depicts a function of the invention for generating adversarial attacks on computer vision models using synthetic data;

FIG. 11 depicts a function of the invention for generating adversarial attacks on text-based models using synthetic data;

FIG. 12 depicts a function for reverse engineering AI models from computer binaries;

FIG. 13 depicts a function of the invention for finding known common AI frameworks and storing AI models as computer binaries;

FIG. 14 depicts a function of the invention for filtering known functions from a binary file into functions that contain AI;

FIG. 15 depicts a function of the invention for importing and translating an abstract model into a known representation;

FIG. 16 depicts a function of the invention for using similarity analysis to find semantically similar models and components;

FIG. 17 depicts a function of the invention for describing known AI functions being compared to sample functions;

FIG. 18 depicts a function of the invention for automatically deploying models;

FIG. 19 depicts an example UI/UX for mapping risks to mitigations that may be automatically or semi-automatically carried out;

FIG. 20 depicts an example UI/UX for viewing and reacting to vulnerabilities;

FIG. 21 depicts an example UI/UX for viewing results of the surrogate model analysis through a graph displaying trusted boundaries;

FIG. 22 depicts an example UI/UX for viewing surrogate model analysis results through an analysis of clusters that form in a graph format;

FIG. 23 depicts a function of the invention for an automated training selection UI/UX example;

FIG. 24 depicts an example UI/UX for viewing the results of automated training in a heatmap;

FIG. 25 depicts an example UI/UX for configuring automated workers for monitoring;

FIG. 26 depicts a function of the invention for adversarial attack generation to use in adversarial defense;

FIG. 27 depicts a function of the invention for importing a machine learning model and lifting it to an intermediate representation;

FIG. 28 depicts a function of the invention for generating a corpus of AI code segments;

FIG. 29 depicts a function of the invention for source code analysis to detect and/or extract AI components;

FIG. 30 depicts a function of the invention for model drift attack and analysis;

FIG. 31 depicts a function of the invention for continuous monitoring of vulnerabilities in AI systems;

FIG. 32 depicts a function of the invention for analyzing containers for AI systems;

FIG. 33 depicts a function of the invention performing analysis on AI inputs and generating output;

FIG. 34 depicts a function of the invention performing detection of AI in computing systems; and

FIG. 35 depicts a function of the invention for detecting anomalous data and model drift in computing systems.

### DETAILED DESCRIPTION

The words “exemplary” and/or “example” are used herein to mean “serving as an example, instance, or illustration.” Any embodiment described herein as “exemplary” and/or “example” is not necessarily to be construed as preferred or advantageous over other embodiments. Likewise, the term “embodiments of the invention” does not require that all embodiments of the invention include the discussed feature, advantage or mode of operation.

Further, many examples are described in terms of sequences of actions to be performed by, for example, elements of a computing device. It will be recognized that various actions described herein can be performed by specific circuits (e.g., Application Specific Integrated Circuits (ASICs), Field Programmable Gate Arrays (FPGA), Graphics Processing Units (GPU)), by program instructions being executed by one or more processors, or by a combination of both. Additionally, these sequences of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

### Terminology

For this specification, terms may be defined as follows:

Adversarial Attack—A malicious attempt which tries to perturb data to affect a model's predictions and (typically) evade detection.

AI Components—Any component that may be used as input into the trust analysis system, including but not limited to Informational Technology (IT) systems, such as machine learning, artificial intelligence, and data science systems, as well as simulations, control systems, robotics systems, and any other component or process that has inputs or outputs that can be analyzed. AI components can also include input data and output data into a machine learning system/model. AI components can also include internals such as for example model weights.

Analysis metrics—Any metric used to assess the trust of a system and its AI components, such as (but not limited to) the accuracy, reliability, privacy, fairness, bias transparency, robustness, interpretability, explainability, safety, and security of the system and its inputs and outputs.

Automated training—Mechanism that optimally configures the models for training using AI (e.g., ML) and rules-based model selection criteria, analyzing the training datasets, and learning from past results of training.

Black-box—A mechanism of attacking where the device being attacked is inaccessible, and the attacker is only able to access the input and output of a device.

Central Processing Unit (CPU)—The most important processor in a digital computer system that is generally comprised of several components to act as the control center of a computer.

CI/CD (Continuous Improvement/Continuous Development/Delivery)—It is a technique of creating software in smaller, more continuous increments, instead of the more traditional technique of developing software by introducing many changes in larger patches.

CI/CD Pipeline—A flow of technologies a software development team uses to ensure easy deployment of software that is being developed using the CI/CD methodology.

Computing system—A system of one or more electronic devices that can accept input; store data; and/or retrieve, process, and/or output information.

Command Line Interface (CLI)—A type of user interface that allows users to interact with a computer program or operating system by entering commands in the form of text.

Continual Learning—The process of training an AI model on new data samples over time and adapting to changing data and changing conditions.

Decompiler—A programming tool that converts an executable program or low-level/machine language into high-level source code.

DevSecOps—Stands for development, security, and operations. An approach to automation and platform design that integrates security as a shared responsibility throughout the entire computing system lifecycle.

Disassembler—A programming tool that converts machine code into a low-level symbolic language.

Explainability—The concept that an AI model and its inputs and outputs (e.g., preliminary, intermediate, concluding outputs), can be explained in a manner that is understandable to a human.

Fairness—A metric of whether a model contains biases and determining if features learned are unfair, or if variables may be considered sensitive.

Graphical User Interface (GUI)—A type of user interface that displays information graphically to users (e.g., modals, buttons, menus, etc.).

Graphics Processing Unit (GPU)—A specialized processor that has accelerated mathematical calculation capability, which is ideal for AI/ML.

Hardening—Improving an AI model, such as by making it more secure through security measures, introducing data to improve robustness and/or accuracy, limiting biases in the dataset, etc.

Hyperparameter Optimization—Also referred to as hyperparameter tuning. The process of selecting the best set of hyperparameters for a model to achieve optimal performance.

Industrial Control Systems—An information system used to control industrial processes such as manufacturing, product handling, production, and distribution, such as but not limited to of sensors, SCADA, PLCs, and other software and hardware components.

Inference—Using a trained AI model to make predictions on new data or generate new data.

Intermediate representation (IR)—In the context of software, the term is a data structure used to represent a program or computation in a way that may be transformed, analyzed, or optimized by other programs and/or tools. In the context of AI, it is an approach to representing an AI model that can easily be translated between more common representations for the sake of easy internal use.

IT system—Information Technology (IT) system, a term used broadly in this specification to comprise any computing system. Unless specifically stated otherwise, the use of this term throughout the present specification is not used to distinguish Information Technology (IT) from Operational Technology (OT), or embedded vs. non-embedded devices vs. IoT etc. In the narrower use, if mentioned in the context of OT, the term is used to differentiate IT environments from OT environments.

Machine Learning (ML)—Subfield of AI that deals with systems that are able to acquire knowledge by extracting patterns from data and drawing inferences from those patterns.

Model—A specialized program or file that can find patterns or make decisions from a previously unseen dataset.

Natural Language Processing (NLP)—A class of AI that concerned with the interactions between computers and human language.

Out of Distribution (OOD)—in ML, OOD is an uncertainty that arises when an AI model sees an input that differs (potentially substantially) from its training data, leading to potentially incorrect predictions.

Operational Technology (OT)—Programmable systems or devices that interact with the physical environment, such as PLCs, SCADA, HMIs, etc., for managing and monitoring industrial equipment, assets, and processes.

Pipeline—A process that drives software development through a path of building, testing, and deploying code, including, but not limited to, CI/CD, MLOps, DevOps, SecDevOps, and other pipelines.

Robustness—The degree that a model's performance changes when using new data versus training data. Also sometimes referred to in the same manner as “adversarial robustness”, which is a model's ability to resist being fooled.

Semantic representation—Representation of function and input/output, instead of exact implementation.

Surrogate model—A mechanism, program, function, or other representation of an AI model that is capable of representing and/or simulating the behavior and/or the characteristics of a given AI model. In some instances, surrogate models may be less complex than the AI model they are representing/simulating; less complex may include being smaller in size (e.g., fewer layers, inputs, outputs of a neural net, less complex formulas), more performant (produces same/similar result with less processing resources required), etc. Being smaller in size and more performant may make a surrogate model more efficient, but there may be accuracy trade-offs.

Synthetic data—Data that is artificially manufactured rather than generated by real-world events, such as image, video, text, numerical, and other data.

User Interface (UI)—The point of human-computer interaction and communication in a device, which may include a command-line interface (CLI), a graphical user interface (GUI), or other types of interfaces.

White-box (attacks)—A mechanism of attacking a model wherein everything is known about the deployed model, including but not limited to, the inputs, model architecture, and specific model internals like weights or coefficient values.

The following sections describe examples corresponding to the figures presented in this patent.

### 1) Analysis System

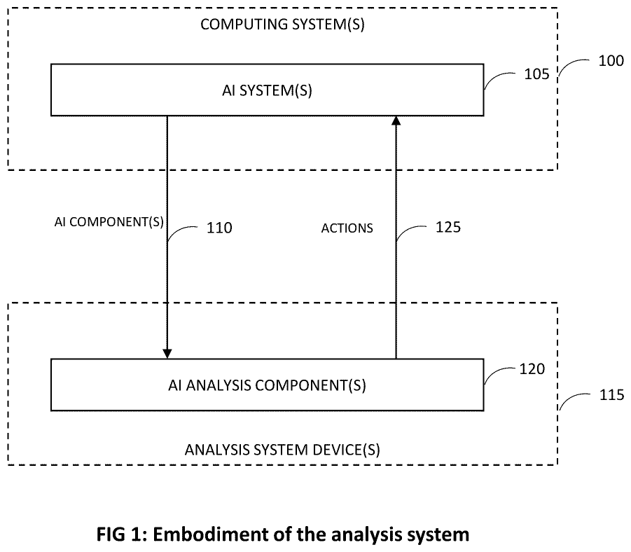

FIG. 1 presents a high-level diagram of an example analysis system. Here, one or more computing systems are analyzed that contain one or more AI systems. For example, computing systems may include, but are not limited to, Information Technology (IT) and/or Operational Technology (OT) systems. Computing systems may be connected to one or more analysis system devices that carry out some operation, task, and/or action on the AI system components. Modules, microservices, objectives, tasks, and/or actions, etc., may be stored in one or more AI analysis components. They may be carried out on one analysis system device and/or across multiple devices. An analysis system device may be the same device as the computing system.

One or more computing system 100 may provide inputs. For example, computing systems include, but are not limited to, laptops, desktops, cloud computing, edge device, fog device, server, transport systems, solar/energy systems, transport systems, defense systems, databases, database management systems, networks, space systems, weapons systems, cellular devices, and/or tablets, etc. For example, OT systems may include, but are not limited to, programmable logic controllers (PLCs), internet of things (IOT), Extended Internet of Things (XIOT), industrial internet of things (IIoT), industrial control systems (ICS), supervisory control and data acquisition system (SCADA), and/or human machine interfaces (HMIs), etc. Input may come from a singular device and/or it may come from multiple devices. Multiple devices being used as input may include, but is not limited to, IT and/or OT systems. Inputs may be provided via a network and/or storage.

In computing systems, there may be AI systems 105 contained on the devices that are options for analysis. AI systems include, but are not limited to, machine learning (ML), data science (DS), natural language processing (NLP), deep learning (DL), expert systems, robotics systems, modeling, and/or simulation, etc. These AI systems may be performing a variety of tasks, including but not limited to, computer vision, natural language processing, signal processing, object detection, classifying images, generating images, generating video, generating audio, generating text, speech recognition, face detection, anomaly detection, and/or decision making etc.

AI components 110 may be provided to one or more analysis system devices 115 in full and/or in parts. They may contain a variety of components, including but not limited to, binaries, assembly code, source code, machine code, JIT, data (including but not limited to images, videos, audio, text, numerical data, categorical data, time-series data, raw data, and/or real-time data, etc.), model files, weights files, configuration files, pipeline files (including but not limited to MLaaS, MLOps, AIOps, CI/CD, and/or others), labels, and/or documentation, etc. If multiple computing systems are being analyzed, and/or multiple AI systems 105, in some cases the same components may be required across systems, while in other cases the requirements may be different. Depending on the task and/or action being performed by the analysis system, different AI components 110 may be required by the system.

The AI systems 105 and their AI components 110 may be provided to the analysis system through many different mechanisms. AI components include, but are not limited to, a web interface, API, command line interface (CLI), a graphical user interface (GUI), over various protocols (including but not limited to FTP, HTTP, HTTPS, TCP, SSH, and/or SCP etc.), and/or storage device (e.g., flash drive), etc. One, some, or all components of AI systems may be provided (but not limited to) at once, on a continual basis, periodic basis, and/or contextual basis (e.g., during CI/CD and/or during compliance audits, etc.) etc. Data may be provided in many formats. AI components may come passively from data passively connected to and/or collected from other devices. For example, images may be provided in formats, such as but not limited to ZIP, JPEG, PNG, BMP, GIF, AI, EPS, PDF, RAW, PSD, INDD, EPS, HEIF, A VIF, and/or other formats. Audio data may be provided in formats such as but not limited to MP3, WAV, Opus, Vorbis, AIFF, Musepack, AAC, M4A, AAX, and/or other formats. Video formats provided may include, but are not limited to, FLV, MP4, AVI, MPEG-4, VOB, and/or MOV, etc. Tabular formats include, but are not limited to CSV, DAT, XLS, XLSX, ODS, SXC, DIF, TSV, and/or XPORT, etc. Text formats include, but are not limited to, DOC, DOCX, ODT, PDF, RTF, TEX, and/or TXT, etc. Compressed file formats include, but are not limited to 7-ZIP, AJR, Debian software package file, RAR, RPM, tarball, and/or Z compressed files, etc. Code files may include, but are not limited to, C, Python, C++, C #, Java, JavaScript, PHP, bash, Perl, Go, binary files, bytecode files, application models, and/or no/low-code models etc. Machine learning file formats include, but are not limited to, TFRecords, JSON, CSV, XML, Avro, serialized formats (e.g., pickle), Numpy, Petastorm, ONNX, HDF5, netCDF, MLleap model, YAML, and/or protobuf, etc. Machine learning frameworks may include, but are not limited to, TensorFlow, PyTorch, Keras, Caffe, Spark, scikit-learn, Huggingface, PyTorch, MXNet, and/or H2O, etc. AI components may come (but not limited to) from a CI/CD pipeline, such as Jenkins, GitLab, Bamboo, Travis CI, CircleCI, TeamCity, and/or Buddy, etc. AI components may come from a MLaaS pipeline, including but not limited to, Amazon Sagemaker, Azure, Google Cloud Machine Learning, Google AI Platform, Google Cloud AutoML, Microsoft Azure MLOps, IBMWatson, BigML, and/or WhizzML, etc. AI components and/or their data may come from a database, including but not limited to, relational databases, graph databases, IBM Db2, SQL, NoSQL, cloud database, distributed database, centralized database, MySQL, Apache CloudDB, PostgreSQL, MongoDB, MariaDB, Oracle DB, and/or redis, etc. Data may be provided on-premises, and/or in the cloud, etc.

The analysis system may contain a variety of AI analysis components 120 that carry out tasks and/or perform a variety of actions 125. Actions may include, but are not limited to, training, configuring, monitoring, defending, hardening, deploying, testing, analyzing, storing, designing, validating, reverse engineering, and/or orchestrating, etc. Under each action, a variety of analyses may be relevant, and/or some analyses may be relevant to more than one action. Some or all actions may be relevant to the AI systems 105 being analyzed. Each action may result in its own outputs, different outputs and/or a combination of outputs. For example, the analysis action may provide a variety of analyses and/or provide a variety of results. This may include, but is not limited to, analyzing the accuracy of models, detecting poisoning in data, binary analysis, source code analysis, detecting adversarial attacks, assessing adversarial robustness, analyzing reliability, finding privacy violations, analyzing safety and/or security of the system, analyzing the system against compliance controls, detecting vulnerabilities and/or risks, evaluating the models against OOD data, analyzing explainability (and transparency) aspects of the model, analyzing bias, analyzing fairness, analyzing flexibility, and/or testing the security of endpoints, etc. A variety of analyses may be used for each of these. For example, under analyzing adversarial robustness, analysis may include, but is not limited to, synthetic data being generated to test the model, the model may be tested against adversarial samples, including physical-based attacks, and/or surrogate model analysis may be used to assess the model. The result of an analysis action, for example, may be (but not limited to), a (e.g., detailed) report of vulnerabilities, adversarial samples that successfully attacked the model, and/or a software bill of materials, etc. Resulting actions of analysis may affect the physical environment, such as a light that blinks if the analysis returns negative results, and/or a siren being triggered, etc. Analysis may occur at any stage of the AI development pipeline, including but not limited to before, during, and/or after planning, training, deployment, and/or inference, etc. It may result in specific scores and/or visualizations that notify the user of the results of the results of their analysis (e.g., explainability, bias, and/or compliance, etc.). Nothing may be directly returned from an action, and/or actions may work alongside other actions. For example, the analysis action may work alongside other actions. Analyses might pair with hardening, wherein the model may be automatically hardened to protect it from vulnerabilities discovered during analysis. Then, it may be analyzed again to assess a hardened model's vulnerabilities.

Hardening actions may be a semi-automated and/or automated process, and/or may be hardening steps and/or feedback provided to the user to perform manually, etc. For example, if it is found that a model is vulnerable to a specific adversarial attack, the model may be fine-tuned to make it more robust against that attack. Data may be introduced to the model during fine-tuning, such as (but not limited to) from online sources, synthetic data, transformed data, and/or adversarial samples, etc. A human in the loop may provide feedback on whether a specific hardening mechanism should be utilized based on analysis results. Users may control what hardening mechanisms take place by configuring the types of vulnerabilities they would like their model hardened against. Hardening mechanisms may be provided by a user, such as a script and/or specific data provided by a user. Hardening may include improving aspects of explainability, interpretability, and/or transparency, wherein various mechanisms can add and/or enhance the explainability of the models.

Analysis and/or hardening may work closely with one or more monitoring actions. For example, monitoring may include continuously analyzing the AI systems 105 for vulnerabilities. If vulnerabilities are discovered, then a hardening action may be used to harden the system against those vulnerabilities. Monitoring may include continuously assessing logs, inputs, and/or outputs, etc., of the model. It may include reporting on any issues, and/or it may include making mitigations. Mitigations may include, but are not limited to, blocking access to specific components of the systems, shutting down entire systems, blocking access by a specific user, blocking specific types of inputs, emailing users, texting users, alert users, and/or trigger a siren, etc. An analysis system may for example monitor for specific boundary violations in inputs and/or outputs of the model, detect model drift, etc. It may track usage of the system over time and/or how the system performs under various circumstances. Monitoring may include, but is not limited to: generating explanations on data continuously, and/or may include improving those explanations over time; ensuring compliance with various frameworks and/or controls and/or alerting if there are any violations; and/or acting as a reinforcement mechanism to continuously improve the model through hardening and/or defense; etc. It may include monitoring a single system, and/or may include monitoring multiple systems that may or may not be interconnected.

Defense actions are related to hardening, but differ in that defense includes (but is not limited to) taking actions to protect the system during runtime. For example, this may include detecting and/or preventing adversarial samples from reaching inference, denoising data, and/or blocking access to the system, etc. Defense may occur for a single system and/or across multiple systems. Defenses may be automated, semi-automated, and/or may require some human-in-the-loop response before, during, and/or after there is a need for defense. Specific defenses may be mapped in the system to specific risks, vulnerabilities, and/or compliance requirements, laws, guidance, controls etc. Mappings may be provided by the user and/or semi-automatically and/or automatically generated. Defense actions may continuously improve through a reinforcement learning mechanism, wherein the analysis system looks at past results and/or improves defense actions based on how successful and/or unsuccessful past defensive actions performed.

Training actions may include (but are not limited to) automatically training one or more machine learning models, generating one or more models, generating one or more simulations, and/or generating the code for a robotics system, etc. Training actions may accept a variety of inputs and fidelity of inputs. For example, training actions may include training a model using just input data. Training actions may include taking an existing model that was trained and train one or more models and/or training models in a parallel or distributed manner. Models may be optimized during automated training for a variety of metrics, including but not limited to accuracy, robustness, security, explainability, safety, and/or fairness, etc. Training actions may include one, some, or all of the example metrics listed, as well as others not listed here. Training actions may work hand-in-hand with monitoring actions, wherein the models generated are analyzed and/or may be re-trained if vulnerabilities, risks, and/or limitations are discovered. An automated training mechanism may learn from its own prior models trained, wherein it can improve the quality of the model currently being trained and/or may apply that knowledge to new AI components received by a system. A training action may lead into a deployment action, wherein models may be deployed and/or optimized for a production system. For example, the trained AI systems may be deployed in several environments, including but not limited to, the Cloud, edge devices, a pipeline (e.g., a MLaaS pipeline, a MLOps pipeline, and/or CI/CD pipeline, etc.), an embedded device, a container (e.g., Docker), and/or a cluster (e.g., Kubernetes cluster), etc.

A variety of actions may be taken on a variety of AI system types. For example, analysis may take place on a machine learning model by analyzing the source code of the model. For a data science system, hardening may for example include introducing synthetic data into a data repository. For a robotics system, defense may for example include detecting and/or preventing adversarial inputs. For a simulation system, the inputs and/or outputs may for example be analyzed using surrogate model analysis for explainability and/or to detect deviations from a baseline. A deployment action may for example include automatically deploying code to a control system, deploying a model to an OT device, and/or deploying a model to a mobile device, etc. A monitor action may for example monitor the usage of a headset system. One action or a combination of multiple actions may be taken on one or more computing systems.

Similarly, surrogate model analysis may be used on a variety of AI system types and in a variety of ways. For example, one or more surrogate models may be generated for a simulation and/or model, wherein the inputs and/or outputs may be analyzed to determine if there is abnormal behavior that deviates from a baseline. Surrogate model analysis may be used to analyze biases in a data science dataset. Surrogate model analysis may be used to generate surrogate models that contain adversarial attacks on machine learning models, then be used during inference to continually assess the model and/or its data. Surrogate model analysis may be used to analyze consistency across data for example used in a robotics system. The examples above are just some of the many possible ways in which surrogate model analysis may be used in an example of the analysis system.

The analysis system may be used as an attack system. It may attack one or more AI systems 105 and their AI components 110 to, for example (but not limited to), determine how secure the systems are, assess the AI for model drift, exploit vulnerabilities, find legal, compliance, privacy, and/or ethical violations, etc.

The outputs of the system may vary based on actions performed, AI systems and/or AI components under analysis. Outputs may for example include, but are not limited to, a trained model, a configured deployment, a (e.g., detailed) report, results on a GUI (e.g., dashboard), new data, and/or an enhanced model, etc. Outputs may for example be returned in several ways, including but not limited to, through a GUI, application interface, web interface, through social media, API, CLI, desktop notifications, through augmented reality or virtual reality, on an embedded device screen, text message, email, instant message, and/or textual output (e.g., produced using generative AI, for example using large language model approaches), etc. It may be provided through multiple of the mechanisms listed. Data may not be returned but may need to be retrieved by the system afterwards. There may be no output provided to the user. For example, changes may be made to the AI system on the backend but not be returned to the user. Results may be provided on a continual basis. For example, results of monitoring and/or defense may be continuous, while a one-time analysis may only provide results each time the AI systems are received by the analysis system for analysis.

### 2) Function of the Invention: User Interface/User Experience (AI Components Upload)

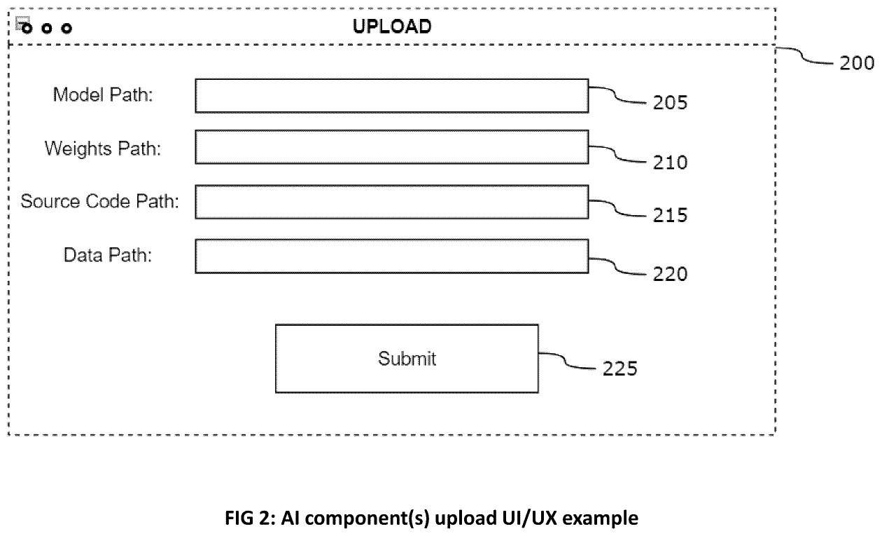

As depicted in FIG. 2, a UI/UX may be used for uploading and/or connecting one or more AI system to the analysis system. A UI/UX page 200 depicted in the diagram may be presented on (but not limited to) a mobile device, augmented reality or virtual reality system, embedded system, HMI, low-code or no-code interface, pipeline plugin, IDE plugin, web interface, and/or application interface, etc. Users may provide their model by dragging and dropping AI system files, defining a file or directory path, and/or retrieving and/or fetching data from an API, etc. Data provided includes, but is not limited to, a model path 205, weights path 210, source code path 215, and/or data path 220, etc. Each item may contain a single path, and/or it may contain multiple paths for a single component type (e.g., multiple weights files). There may be other options for configurations, such as setting the one or more objectives and/or actions of the analysis system. Each combination of UI/UX components may be optionally be present and/or absent. In the example diagram, there is a submit 225 button on the UI/UX to provide data to the analysis system. Data may be submitted using other mechanisms, such as, but not limited to, through an API, pressing a physical button, through a CLI, voice control, pressing a key on the keyboard, connecting a storage device, augmented reality, virtual reality, timer, drag-and-drop, and/or sensor, etc.

### 3) Function of the Invention: Surrogate Model Analysis

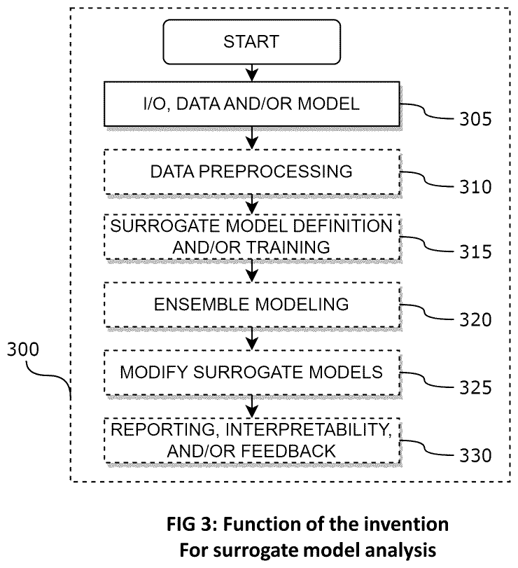

An example of the analysis system, 300 depicted in FIG. 3 may include analysis using surrogate model analysis. A surrogate model (in the context of AI) is a mechanism/approach, program, function, or other representation of one or more AI systems, that is capable of representing and/or simulating the behavior and/or the characteristics of given AI systems. Surrogate modeling (and analysis) is typically done by providing the inputs and/or outputs of a model. Intermediate inputs and/or outputs may be used, such as the inputs and/or outputs of specific layers of a model.

Surrogate model analysis may be used for a variety of tasks. Tasks may include, but are not limited to, generating explanations about how specific features affect the output, adversarial attack analysis, bias analysis, verification that a model is acting within expected bounds, analyzing feature sensitivity, generating metrics to score the model's robustness, accuracy, develop a normal baseline, etc., and/or other analyses. Data used for the analysis may include, but is not limited to, a combination of data, source code, binaries, models, and/or data, etc. Files such as (but not limited to) source code and/or configuration files etc. may for example be used to utilize and/or deploy the model in order to analyze it. External devices may be connected to a computing system to monitor the inbound and/or outbound network traffic for use in surrogate model analysis. Surrogate models may be generated at any point in the AI development and/or deployment pipeline. For example, surrogate models may be generated prior to deployment and/or after training. For example, other surrogate models may be trained after inference and/or compared to the original surrogate models. For example, the original surrogate models are modified after deployment to analyze specific features of the model during runtime. In the section below, an example workflow is described for surrogate model analysis. Different steps may be present, and/or steps may be removed and/or reordered.

3.1) I/O or Data and/or Model

Analysis taking place by the analysis system may be surrogate model analysis. This may be conducted with techniques including, but not limited to, analyzing the input and/or outputs of an AI system, characterizing the internal mechanisms of the AI system via mathematical, programmatic, and/or other ways known to one skilled in the art via the processor, calculating similarities between AI system and potential surrogate models, and/or storing the calculated surrogate model on a storage medium. The AI system components and/or their data used as input may come from multiple computing systems and/or multiple AI systems. While inputs outputs (I/O)) or data and or models 305 are listed as inputs, other components may be included, such as those that may be used to analyze the model (e.g., model architecture, weights, source code, and/or binaries, etc.).

### 3.2) Data Preprocessing

In a data preprocessing 310 step, the data may be initially preprocessed, sanitized, and/or normalized. For example, this may include, but is not limited to, making all images the same size, shrinking images to the same size, truncating audio clips, truncating video clips, removing rows of tabular data, autocorrecting text-based data, predicting missing data, subsampling data, and/or isolating features, etc. It may include actions taken on the model itself, such as (but not limited to) breaking down the model into individual layers, translating the model to a different framework, making adjustments to the model, and/or making adjustments to the weights, etc.

3.3) Surrogate Model Definition and/or Training

During a surrogate model definition and or training 315 stage, optimal surrogate model techniques may be selected. These may be defined in several manners, including but not limited to, through user input, through a dropdown, semi-automatically through suggestions by the analysis system, automatically based on the data and/or model under analysis, via APIs, and/or files etc. Each surrogate model may be defined with one or more objective it is trying to achieve, such as (but not limited to) explainability, scoring, adversarial attack analysis, feature analysis, and/or bias analysis, etc. Surrogate model types may include, but are not limited to, polynomial regressions, decision trees, dynamic mode decomposition with control (DMDc), sparse relaxed regularized regression (SR3), support vector machines, neural networks, forward stepwise regression, least absolute shrinkage and selection operator (LASSO), sequentially thresholded Ridge regression (STLSQ), sparse identification of nonlinear dynamics (SINDy), stepwise sparse regression (SSR), forward regression orthogonal least-squares (FROLS), and/or mixed-integer optimized sparse regression (MIOSR), etc. For a specific analysis task, one or more models may be trained, for example (but not limited to): a single task may be trained with different surrogate model approaches to compare and/or select the best approach after training; multiple surrogate models may be trained on different subsets of data for the same analysis task; multiple surrogate models may be trained for multiple analysis tasks, and/or a single surrogate model may be trained for multiple analysis tasks; and/or multiple surrogate models may be trained for a single task that can then be combined using ensemble modeling etc.

### 3.4) Ensemble Modeling

Ensemble modeling 320 may be used to combine multiple models and/or output a unified result. For example, training a surrogate model on full data samples may be very time and/or resource intensive in some scenarios. However, multiple surrogate models may be trained (e.g., sequentially, in parallel, and/or continuously, etc.), they may be combined, and/or another model may be trained to analyze the results of some or all of the surrogate models. Mechanisms for ensemble modeling may include, but are not limited to, bagging, boosting, stacking, SVM, averaging results, taking the maximum of results, taking the minimum of results, and/or taking the standard deviation of results, etc.

### 3.5) Modify Surrogate Models

During a modify surrogate models 325 step, one or more surrogate models may be modified for a specific analysis task. This may include, but is not limited to, retraining one or more surrogate model, making changes to the surrogate model configurations, changing the type of surrogate model, modifying analysis tasks, and/or modifying the input data, etc. This may include making modifications to surrogate models but then comparing them to the original data. This may be for example used for new inference data and/or when a model is fine-tuned to analyze how specific features were affected.

3.6) Reporting, Interpretability, and/or Feedback

The results of surrogate model analyses may be assessed and/or reported on, which may include reporting, interpretability, and or feedback 330. This may include, but is not limited to, generating a detailed report, generating explanations about how specific features affect specific outputs, generating explanations for specific inference inputs and/or outputs, returning the likelihood samples contain adversarial attacks, a scorecard, and/or an analysis of biases, etc. Feedback may be returned with information on what modifications may be made to the original model to harden and/or defend it. This may include feedback for the defense and/or hardening actions on what modifications and/or mitigations to make to the original computing systems.

### 4) Function of the Invention: Surrogate Automated Training

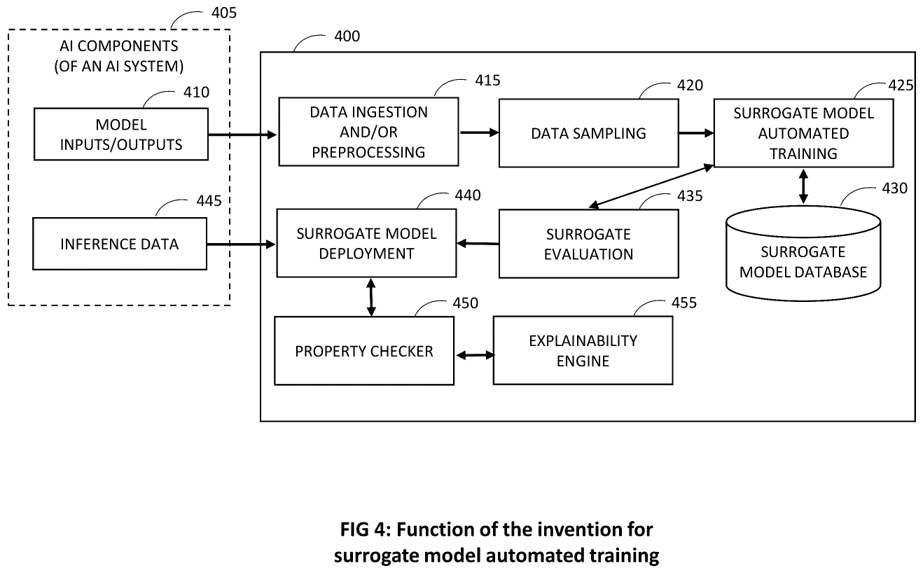

FIG. 4 depicts an example of surrogate automated training 400 in the analysis system, wherein an approach related to automated training may be utilized for automatically training one or more surrogate models. Examples of surrogate models include, but are not limited to, polynomial regressions, decision trees, dynamic mode decomposition with control (DMDc), support vector machines, neural networks, forward stepwise regression, least absolute shrinkage and selection operator (LASSO), sequentially thresholded Ridge regression (STLSQ), sparse identification of nonlinear dynamics (SINDy), sparse relaxed regularized regression (SR3), stepwise sparse regression (SSR), forward regression orthogonal least-squares (FROLS), and/or mixed-integer optimized sparse regression (MIOSR), etc. Surrogate models may be trained for a variety of objectives, including to analyze biases, adversarial attacks, boundary violations, safety measures, security analysis, and/or hardening analysis etc. Surrogate models may be used for (but not limited to) the generation of explanations about the original model's behavior, decision-making, confidence level, algorithm transparency, and/or model interpretability, etc. Surrogate models may be trained on a subset of data, while in other instances, they may be trained on the full data set. Only the inputs or only the outputs of the model under analysis may be used for surrogate model analysis, or both. One or more surrogate models may be trained using surrogate automated training.

### 4.1) AI Components (of an AI System)

AI components (of an AI system) 405 (including for example, model inputs and or outputs 410, model weights, model code, and/or inference data etc.) may be used to analyze an AI system using surrogate model analysis. Model inputs and/or outputs may include, but are not limited to: model internals; model weights; training, testing, validation, and/or inference data, etc. Users may include specific properties with their input that they would like to have evaluated using surrogate models. This may include defining subsets or parameters to generate explanations for. For example, if a user is analyzing a financial model, they may provide a tabular dataset that was used for training the model, containing several parameters, such as organization, stock price, and/or quarterly earnings, etc. Users may include results of the model's inference results and/or want to understand how quarterly earnings affected the model's output. A user may be able to define the specific parameter they would like to have analyzed and/or have explainable output generated for.

4.2) Data Ingestion and/or Preprocessing

AI components may be analyzed by the system and/or prepared for further analysis by a data ingestion and or preprocessing 415 module. For example, this may include, but is not limited to, normalizing data, removing missing and/or duplicative data, replacing data, and/or performing fusion techniques, etc. Additionally or alternatively, this module may include loading a machine learning model and/or obtaining inference results using the full data and/or a subset of data received by the analysis system. Results of this module may be sent to a data sampling 420 module that selects samples of data to use in one or more surrogate model.

### 4.3) Data Sampling

Data sampling 420 techniques may be used to select the most optimal data for surrogate models. This module may consider aspects that will optimize explainability analysis downstream. It may optimize analysis metrics, such as data that would be most optimal for analyzing biases using surrogate models. Modifications may be made to one or more data sample and/or duplicated into multiple tracks for surrogate automated training. Results of these samples of data may be provided to a surrogate model automated training 425 module to train one or more models from each subset of data.

### 4.4) Surrogate Model Automated Training

Similar to automated training, surrogate model automated training 420 may generate one or more optimal surrogate models (for example that best describe a model under analysis by representing a model in a more measurable manner). For example, an approximate mathematical model may be generated to understand the underlying dynamics of a digital twin system. It may include using for example the SINDy approach to generate equations that may be used to gain a deeper understanding of how specific inputs of a system affect the output. Various surrogate model generation mechanisms/techniques may be obtained from a surrogate model database 425. One approach may be used, such as linear regression, or a variety of approaches may be used and/or compared to determine the most optimal surrogate model and/or combination of surrogate models. Surrogate models may be optimized based on a variety of factors, including but not limited to, analysis metrics, feature importance, explainability, feature interaction, security, and/or safety, etc.

### 4.5) Surrogate Model Generation Database

A data store of surrogate model techniques—surrogate model generation database 430—may be stored and/or categorized. For example, surrogate models may be categorized based on the frameworks, data types, trust metrics, explanations and/or other factors that they are most useful for and/or have had the most previous success on. Surrogate models may include, but are not limited to, linear regression, decision trees, DMDc, LASSO, SINDy, RuleFit algorithm, and/or others. A surrogate automated training 425 module may obtain for example surrogate models, their configurations, and/or other related data to train surrogate models.

### 4.6) Surrogate Evaluation

Surrogate models may be analyzed against properties during surrogate evaluation 435. While these may include analysis metrics, they may include other metrics. For example, metrics describing the outcomes of surrogate models may be referred to as “surrogate metrics”. Surrogate metrics may include, but are not limited to: how accurate the surrogate model is; how consistent predictions made between one or more models are; how well the surrogate model describes the real world; how consistent outcomes are of the surrogate model between similar inputs; how detailed results of surrogate models are; how important the results of the surrogate model are; how representative the surrogate models are of the original data and/or model; and/or how confident the surrogate models are; etc. Surrogate evaluation may be used as feedback to surrogate automated training, for example to generate new surrogate models and/or for future improvements. A surrogate evaluation 435 module may provide the evaluation and/or surrogate models to a surrogate model deployment 440 module.

### 4.7) Surrogate Model Deployment

Surrogate models may be automatically deployed—surrogate model deployment 440—after surrogate models may have been trained. For example, they may be available from a GUI, CLI, web interface, API, and/or CI/CD pipeline, etc. They may be used for continuous monitoring of the system, wherein source code is for example automatically injected into the original deployment source code to analyze the data using surrogate models before and/or after inference. If issues are detected during surrogate model analysis, it may for example halt inference or downstream decisions. These surrogate models are readily available for inference and/or can ingest AI components, such as (but not limited to) a model and/or inference data. Surrogate models may evaluate inference data using surrogate models. Results may be output to a property checker 450 module.

### 4.8) Inference Data

AI components, in this case inference data 440, may be provided to the deployed models. This may include, but is not limited to, images, structured and/or unstructured text, images, PDFs, audio, video, numerical, and/or other types of data. It may include (but is not limited to) nominal, ordinal, discrete, and/or continuous data. This data may be sent through a variety of approaches, including but not limited to, from an application, smart watch, camera, sensor, augmented reality, virtual reality system, spacecraft, and/or automotive vehicle, etc.

### 4.9) Property Checker

Specific properties, such as (but not limited to), analysis metrics, surrogate metrics, and/or features, etc., may be evaluated by a property checker 445 based on the defined objectives of the surrogate models. For example, if a model is determining if there is OOD data, the property checker could analyze the output of the surrogate models on the new inference data to determine if the new data is not similar to the baseline determined by the surrogate model. Property checking may be done through, for example, verification and/or certification of specific properties, generating new or modified surrogate models with inference data and/or comparing the resulting models to the models trained before inference, and/or analyzing and/or scoring the resulting equations of surrogate models, etc. Results may be returned to the user (e.g., through a user interface, plugin, API, CLI, etc.). Results may be provided to an explainability engine 455 to generate explanations about the result.

### 4.10) Explainability Engine

Explanations may be generated by the explainability engine 455 based on the results of the surrogate model analysis. For example, these may include, but are not limited to, local and/or global explanations, explanations about the model internals, and/or feature importance, etc. For example, they may rely on understanding the model's internals, while in other cases, they may have no reliance on a model's internals. Explanations may be in several forms, including but not limited to text-based explanations, graphical explanations, tabular explanations, explanations in machine readable formats (JSON, XML, etc.), audio explanations, video explanations, AR/VR explanations, and/or visual-based explanations, etc. They may summarize the most important features the model used to make its decision. This module results in explanations that improve a human's understanding of the results and/or decisions made by the system. It may assist (current and/or future) compliance, legal defense, and/or implementation, by producing supporting evidence. It may utilize a system such as AI (e.g., ML), for example, to generate explanations, such as using a Large Language Model (LLM), stable diffusion, Variational Autoencoders (VAEs), GAN (e.g., CycleGAN, DCGAN, etc.), and/or speech synthesis, etc. Users may be able to select the level of detail in which explanations are returned. Users may be able to choose the type of explanation, analysis metrics, surrogate metrics, and/or other properties they want to have explained.

### 5) Function of the Invention: Surrogate Model Human-In-the-Loop Feedback

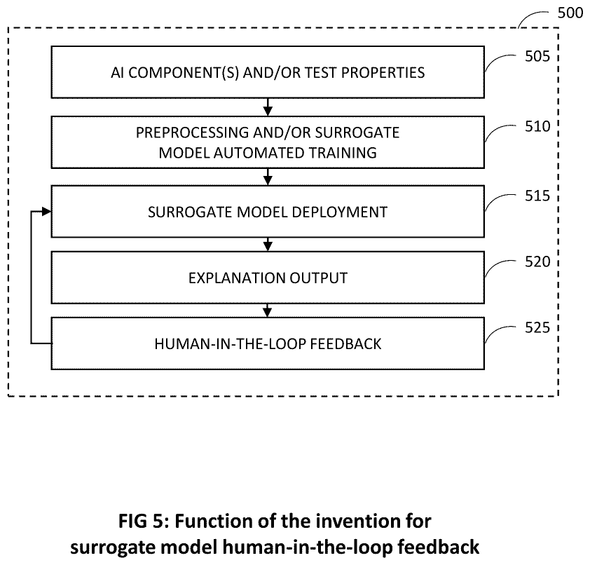

FIG. 5 describes a human-in-the-loop feedback mechanism 500 that may be used for improving surrogate models, for example to continually improve surrogate models based on specific analysis metrics and/or surrogate metrics, to improve surrogate models as well as their explanations over time etc.

5.1) AI Components and/or Test Properties

AI components and or test properties 505 may be used as input, which includes, but is not limited to, training, testing, validation, and/or inference data, models, weights, and/or simulations, etc. It may or may not include test properties 505, such as (but not limited to) features, analysis metrics, surrogate metrics, and/or invariants etc. It may include one model or multiple models, one data set or multiple data sets etc.

5.2) Preprocessing and/or Surrogate Model Automated Training

A preprocessing and or surrogate model automated training 510 module may process and/or may sample preprocessing and/or surrogate model training data and/or their models, and/or may perform surrogate model analysis, resulting (if successful) in one or more surrogate models for one or more test properties. The analysis system may be designed to be model-agnostic, wherein any type of model may be analyzed.

### 5.3) Surrogate Model Deployment

One or more surrogate models that may have been evaluated may be deployed in a surrogate model deployment 515 module and/or are available for inference to analyze a system under analysis, such as (but not limited to) a machine learning model, AI system, simulation, robotics system, vehicles, and/or sensors etc.

### 5.4) Explanation Output

Explanation output 520 may be provided (e.g., to a user) that may explain the underlying behavior and/or decision-making of the system. It may take into account one surrogate model or multiple, or one feature or multiple features. It may include auditable results. It may include supporting evidence. Explanations may be “global” concerning the overall model behavior, and/or may be “local” concerning an instance or feature of data. Explanations may include information about how one or more feature affected the results. Explanations may be generated using several approaches, including but not limited to, layer-wise relevance propagation (LRP), SHapley Additive explanations (SHAP), and/or Local Interpretable Model-Agnostic Explanations (LIME), etc. Explanations outputs may include (but are not limited to) document, API, file, textual, graphical, screen output, audio, video, API, file, alarm, alert, and/or email etc.

### 5.5) Human-In-the-Loop Feedback

Human users may have the ability to view the results (e.g., explanations) and/or provide human-in-the-loop feedback 525, such as but not limited to, providing feedback on the quality of surrogate metrics. For example, human users can provide feedback using (but not limited to), a numerical value, a slider along a bar, a selector popup, pushing a physical button, text-based feedback, audio-based feedback, movement tracking, video-based feedback, and/or AR/VR, etc. For example, (expert) human users can provide feedback using (but not limited to) using Domain Specific Languages (DSLs), No/Low-Code (NLC) interfaces, development tools, spreadsheets and/or other documents, and/or data science tools etc. Feedback may be sent back to a preprocessing and or surrogate model automated training 510 module and/or explanation output 520 module for continuous improvements.

### 6) Function of the Invention: Surrogate Model Attack Analysis

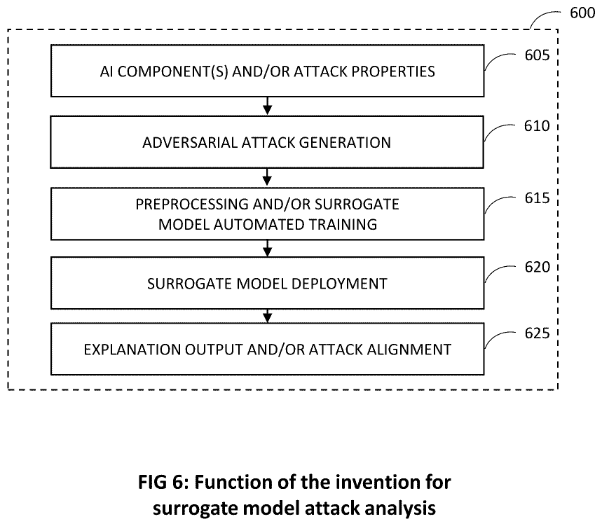

FIG. 6 depicted an example (e.g., in the analysis system) where surrogate models may be used to analyze models for adversarial attacks 600. For example, multiple surrogate models may be generated on the training data with various adversarial attacks, variations and/or attack severity/impact. Surrogate models may for example be clustered into groups, may be used to determine how likely a data point is to being an adversarial attack, and/or may be used to determine which type of attack it may be etc. AI components may be related to machine learning models, and/or may be related to other components of various kinds of computing systems.

6.1) AI Components and/or Attack Properties

AI components and or attack properties 605 are ingested into the system for attack analysis using surrogate model analysis. Optionally, users may define attack properties 605 that the system will use to attack the given data, such as (but not limited to) defining the type of attack, attack severity/impact, target of the attack, and/or portion of the data to attack, etc. There may be an attack generator option where users can build their own attacks by modifying any aspect of a potential attack on a model.

### 6.2) Adversarial Attack Generation

An adversarial attack generation 610 module may generate adversarial samples of one or more types. Types may be separated from the original data or included. Types may be grouped together or separated. This module may result in one or more groups of “attacked data” (incl. adversarial examples). Results may include the parts of input that were attacked, such as the specific features that were modified. Results of this step may be used for further preprocessing and or surrogate automated training 615.

6.3) Preprocessing and/or Surrogate Model Automated Training

This step may preprocess not only the original data, but the new attacked data—in a preprocessing and or surrogate model training 615 module. Preprocessing may include normalizing data and/or further subsampling. Surrogate automated training may be performed on either/or, or both, the original data and/or attacked data, potentially resulting in multiple surrogate models for further analysis and/or for attack monitoring and/or detection.

### 6.4) Surrogate Model Deployment

New surrogate models trained through surrogate model automated training 615 may be deployed by a surrogate model deployment 620 module and/or are available to analyze data samples. For example, an image in an inference pipeline for a computer vision machine learning model may be used in surrogate model analysis to determine if the sample is likely to contain an attack and/or the type of attack it may be.

6.5) Explanation Output and/or Attack Alignment

Explanation output and or attack alignment 625 may analyze (potentially all) surrogate models generated for adversarial attacks and/or generates equations and/or metrics to differentiate and/or group them. Explanations generated by the explainability engine may relate to the underlying causes of why the data was determined to contain an attack and/or what features contributed most. Explanations may include what may be done to mitigate and/or to harden the system against detected attacks.

### 7) Function of the Invention: Surrogate Model Layer Reinforcement

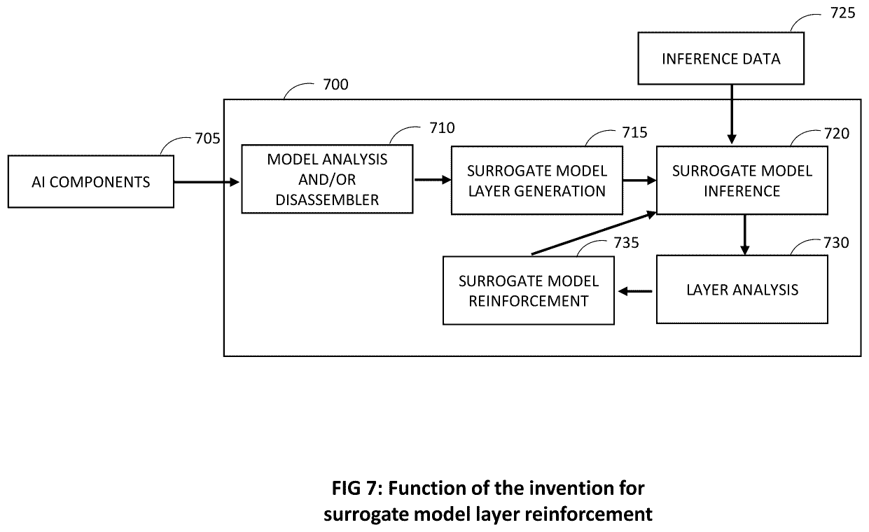

FIG. 7 depicts an example (e.g., in the analysis system) 700 for reinforcing, hardening, and/or replacing layers of a model. It may include reinforcing, hardening, and/or replacing other components of an AI system. Actions may include, but are not limited to, using surrogate model analysis to reinforce segments of source code, components of a simulation, and/or select or generate security features, etc.

### 7.1) AI Components (Model Input)

AI components 705 may include inputs from a model and/or data to assess models under analysis. This may include, but is not limited to, models trained by the user, models trained by automated training, and/or models trained by surrogate automated training, etc.

7.2) Model Analysis and/or Disassembler

In a model analysis and or disassembler 710 module models may be analyzed, for example by their layers and/or disassembled into their individual layers, where knowledge may be extracted and/or explanations are generated for each layer. Inputs and/or outputs may be analyzed and/or used as a dataset for surrogate model layer generation 715.

### 7.3) Surrogate Model Layer Generation

One or more surrogate models may be generated by the surrogate layer generation 715 module using surrogate automated training for one or more layers of a model. A goal of these surrogate models may be to understand the underlying behavior of each layer and/or how it weighs various features. Results of surrogate models may be used for inference of new data.

### 7.4) Surrogate Model Inference

Surrogate models may be available for surrogate model inference 720, where inference data 725 ingested by the system may be analyzed (e.g., per layer) using the trained surrogate models. They may be used on other computing systems and/or analyze individual components of these systems.

### 7.5) Layer Analysis

Each layer may be analyzed for analysis metrics (e.g., robustness, accuracy, security, and/or fairness, etc.) and/or surrogate metrics during layer analysis 730. Individual layers may be analyzed against analysis metrics and/or surrogate metrics, and/or for example vulnerabilities, weaknesses, and/or anomalies of individual layers and/or groups of layers are discovered. Results of layer analysis may be used in surrogate model reinforcement 735 to improve the layers of a model.

### 7.6) Surrogate Model Reinforcement

Surrogate model reinforcement 735 may be used to make continuous improvements to surrogate models that represent layers of the model. For example, if an output of a layer is deemed to be unsafe due to boundary violations, rather than re-training and/or fine-tuning the model itself, adjustments may be made to the surrogate model that describe the layers of a model. Results of this module may be adjustments made and/or new surrogate models trained that may be re-deployed and/or ready for inference. Adjustments made to surrogate models (e.g., additional data included in training to make the model more accurate, and/or robust, etc.), may then be made to the actual AI system and/or its data. For example, if results of trained surrogate models on adjusted data show that the model is more robust, that same data may be introduced to the original AI system. In an example, if surrogate models show that the original AI system is more sensitive toward a specific feature, the original AI system may be adjusted, such as selecting a different model and/or architecture, adding and/or removing data to make the model less sensitive toward that feature, modifying configurations of the model like the learning rate, loss function, and/or others, etc.

8) Function of the Invention: Discovering and/or Interpreting Bias in Arbitrary Model Training Datasets

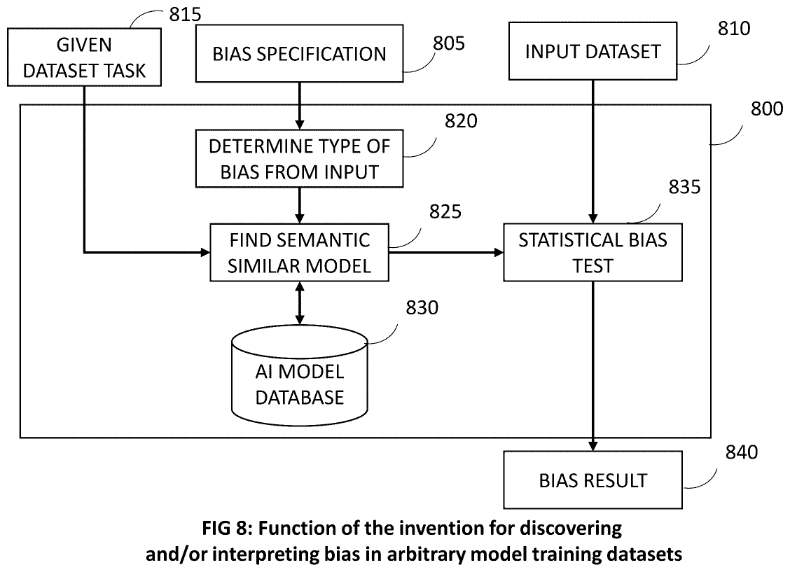

FIG. 8 describes an example (e.g., used in the analysis system) 800 that may determine if a given dataset is biased. Bias may for example (but not limited to) take the form of racial, sex/gender, class, national, and/or other forms of bias for a dataset. It may for example also take forms such as data being skewed for a specific problem, such as disproportionately considering information about different groups or demographics of people, places, things, and/or other information that may be bias and/or important to determine its biases. Inputted datasets may be tested against analyses that detect specific biases in the AI systems and/or their data, such as using a given natural language query, as well as a categorizing the type of dataset being given, and/or outputting a result if the dataset is biased, according to the natural language query.

### 8.1) Bias Specification

A bias specification 805 module may allow specifying bias, for example, described in a natural language, natural-language-like specification, programming-language-like specification, textual or graphical domain specific language (DSL), and/or GUI, etc. This input may be processed to determine the type of bias that a user wants to analyze for, and/or may also include characteristics/specifications about what constitutes bias (for example, specifying expected statistical properties of outputs). This may for example be sentences in the form of text, speech information, and/or other forms of natural language, provided and/or selected by a user. This may for example be provided physically such as storing the information on a physical drive, and/or by a network and/or stored on web servers, databases such as PostgreSQL, MySQL, and/or AWS DynamoDB, etc. This input may be provided to a determine type of bias from input 820 module.

### 8.2) Input Dataset

An input dataset 810 module may be a dataset used for the analysis. This may take many forms, such as data files containing video, photo, audio, text, tabular, and/or other forms of structured, and/or unstructured data. An input dataset 810 module may for example be written on physical drives such as hard drives and/or solid-state drives, and/or may for example be transmitted to the analysis system via Internet and/or other networking devices, such as Ethernet, and/or Wi-Fi, etc. An input dataset may be provided to a statistical bias test 835 module for further analysis by the analysis system.

### 8.3) Given Dataset Task

A given dataset task 815 input may describe an inputted task that describes the general task and form of an input dataset 810. Given dataset tasks may for example include forms such as a set of check boxes denoting what type of data the input dataset is, such as video, image, text, tabular, and/or other forms of unstructured and/or structured data. It may for example contain information related to what type of task an AI model using the input dataset would be trained to do, such as sentence similarity, text classification, object detection, image/video classification, speech recognition, and/or other types of AI tasks. This given dataset task input may be provided to a find semantically similar model 825 module for analysis. The semantically similar model may be a representation that may provide what the model is doing (e.g., how it behaves and/or what it performs, rather than just the specific implementation).

8.4) Determine Type of Bias from Input

A determine type of bias from input 820 module may describe a program, function, and/or general approach for determining what type of bias a user wants to be determined. For example, this may include processes such as reading the natural language provided as a bias specification 805, processing it, and/or using a Natural-Language-Processing module, such as a Large Language Model (LLM) to classify what type of category the provided natural language is trying to convey. If specifications about what constitutes bias (e.g., statistical distributions and/or other characteristics of one, some, or all of the features of the input dataset) are specified as part of the bias specification, these may be determined using analogous approaches. This may be differentiating types of bias, such as race, sex, class, gender, nationality, and/or any other form of bias in a dataset. Depending on the nature of the provided bias specification, a determine type of bias from input 820 module for example parses a (textual and/or graphical) Domain Specific Language (DSL). This module may output a specification (precise or most-probable representation) of what type of bias is attempted to be analyzed (and what constitutes bias), and/or may pass this information to a find semantic similar model 825 module.

### 8.5) Find Semantic Similar Model

A find semantic similar model 825 module may describe a program, function, and/or general approach for finding AI models that are related to the inputted type of bias from an AI model database. This may involve receiving input of what type of bias is attempted to be analyzed, such as (but not limited to) racial, sex, gender, class, and/or other forms of bias in a dataset etc., and/or may query a database holding many different AI models for models related to this form of bias. This may include querying a database for both known biased and/or unbiased AI models trained on data similar to the type given to the module, and/or then outputting the models for further analysis. This module may receive what type of bias (and/or optionally a characterization of what constitutes bias) is being testing for from a determine type of bias from input 820 module and/or receives what form the analyzed dataset takes from a given dataset task 815 module. It may query an AI model database 830 module for an unbiased AI model and/or a known biased AI model, following the given dataset task and/or the given type of bias. AI models may be provided to a statistical bias test 835 module for further testing.

### 8.6) AI Model Database

An AI model database 830 module may describe a data storage, database, database server, file, mechanism and/or device containing and/or capable of containing data that holds various AI models that are related to particular forms of bias and/or particular known AI, dataset tasks and/or dataset types, etc. For example, a database may include AI models that are biased and/or unbiased in certain ways, such as racially, gendered, classist, and/or other forms of biased and/or unbiased etc. This may for example be implemented in various ways, such as a physical database server running database software such as MySQL, PostgreSQL, and/or other database software, and/or as a cloud instance on a cloud machine, such as AWS DynamoDB, as a file on a physical hard drive, and/or any other mechanism that can store data. An AI model database 830 module may be queried by a find semantically similar model 825 module, and/or may return potential models that are related to the type of bias and/or dataset task being given.

### 8.7) Statistical Bias Test

A statistical bias test 835 module may include, but is not limited to one or more program, function, and/or general mechanism that receives AI model(s) and/or dataset(s), and/or uses statistical mechanisms to determine if the dataset contains a bias found or not found in the AI models. This module may take in the input dataset from an input dataset 810 module and/or one or more AI models from a find semantic similar model module 825, and/or may output whether the dataset is biased to a bias result 840 module. This may be implemented using techniques such as (but not limited to) p-value tests, chi-squared tests, and/or other types of statistical tests by running the given AI models using the inputted dataset and/or analyzing if the data is biased. This may involve tests such as testing data representation vs. real life representation of groups, using techniques to discover what sections are being used to categorize, classify, or otherwise test the data, running both a biased and unbiased AI model and/or comparing results from the models, and/or other techniques.

### 8.8) Bias Result

A bias result 840 module may include, but is not limited to, determined bias, for example if the given input dataset is biased or unbiased. Bias results may be generated through a statistical bias test 835 module, and/or gives whether or not the dataset is biased. Bias results may include (but not limited to) a simple yes/no, percentage chance that the dataset contains bias, and/or what type of bias the dataset may/may not contain, etc.

9) Function of the Invention: Determining Type of Bias from Natural Language Input

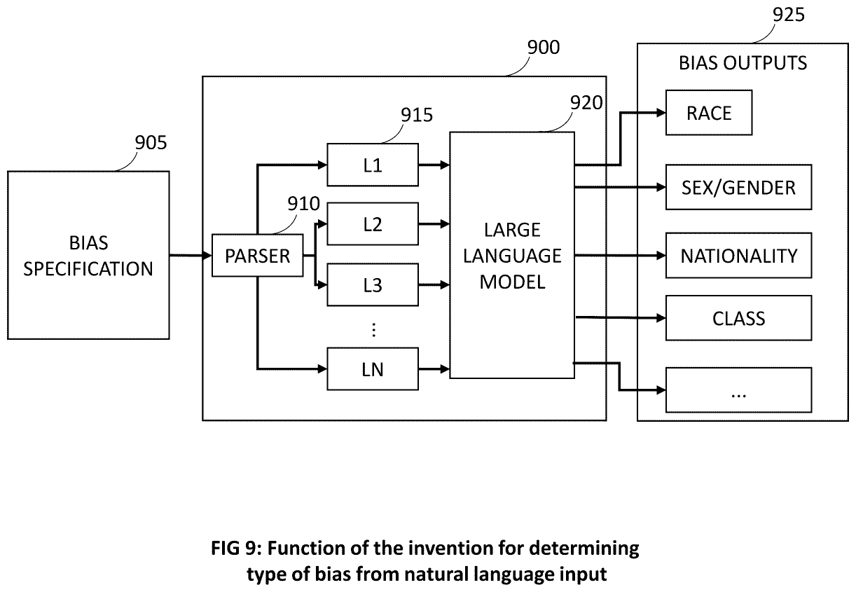

FIG. 9 describes an example that may determine what type of bias a natural language input may be asking for 900, and/or may output type of biases to be tested. Types of bias may include, but are not limited to, race, nationality, class, representation in datasets vs other datasets, misrepresentation of certain characteristics and/or traits present in a dataset, and/or other types of bias potentially found in data, etc. A natural language input may be given, and/or potential types of bias is output.

### 9.1) Bias Specification

A bias specification 905 input may be provided in natural language that may be analyzed for potential forms of natural language. This input may for example take the form of written, spoken, typed, and/or other forms of natural language in the form of a question, statement, and/or other type of input that generally asks if data is biased in a particular manner, etc. Natural language input may be provided to a language parser 910 module for processing.

### 9.2) Parser

A parser 910 module may describe a language parsing module that may split up natural language into tokens for usage in an NLP AI model. A parser 910 may take in a bias specification 905 input, may split up data into segmented tokens 915, and/or may give them to an NLP AI model, such as an LIM 920, etc. Parsing may for example be performed by reading the natural language input from a text file on a disk, reading bits from the disc, segmenting data into a computer's memory, and/or then producing each token to token representations, etc.

### 9.3) Token Modules

Token modules L1, L2, L3, . . . LN 915 may describe individual tokens from a parser 910 module used as input to a large language model 920 module. Token modules may be segmented portions of a bias specification 905 input to allow for easier parsing and/or testing of the language for potential forms of bias. They may be provided to a large language model (LLM) 920 module.

### 9.4) Large Language Model (LLM)

A Large Language Model 920 (LLM) module may describe an LLM that is capable of taking in tokenized natural language and/or outputting one or multiple types of bias the natural language is asking to be described. A LLM may for example include mechanisms such as: reading tokenized input, running inference of input, determining types of biases being described, summing or doing some other operation on potential types of bias from each inputted language token, and/or outputting probabilities of each type of bias being detected, etc. It may receive in natural language input from their tokenized representations 915, and/or outputs bias outputs 925 (e.g., weights for potential types of bias, such as race, sex/gender, nationality, and/or class, etc.)

### 9.5) Bias Outputs

Bias outputs 925 may describe potential types of bias analysis detected, for example from natural language input. For example, outputs may include many types of bias, including human-centric bias such as race, nationality, and/or class, etc., and/or many other types of bias, such as bias in tabular data, image data, and/or any other form of data, etc. Bias outputs may be the output of a large language model module 920.

### 10) Function of the Invention: Synthetic Data Generation for Computer Vision Based Adversarial Attacks

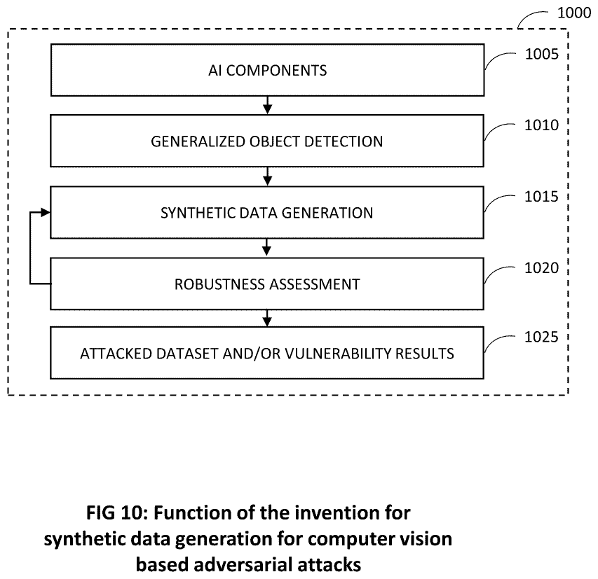

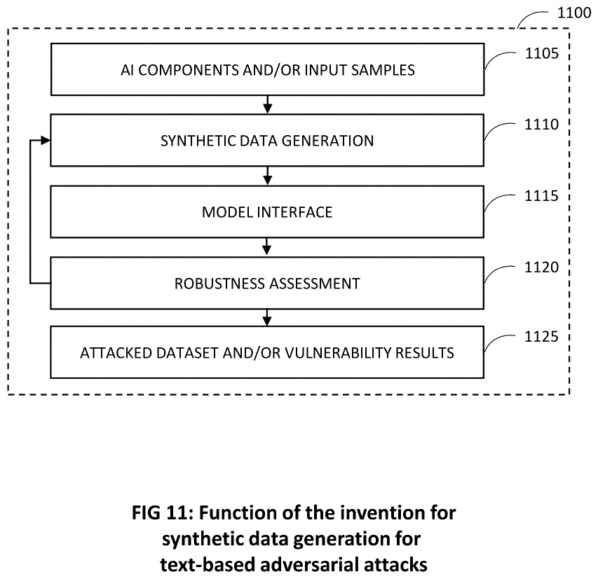

FIG. 10 illustrates an example (e.g., used in the analysis system) for synthetic data generation for computer vision based adversarial attacks 1000, in which synthetic data may be used to attack computer vision models, which may include, but are not limited to, video-based models, classifiers, object detection, image segmentation, edge detection, pattern detection, and/or facial recognition, etc. Similar synthetic data generation may be used, including (but not limited to) for signal processing, audio analysis, text (e.g., see FIG. 11), etc. For example, speech synthesis may be used to generate an adversarial attack against a speech recognition model. Synthetic data may be generated by combining multiple models to create an adversarial attack that can go undetected by multiple models. This may be useful for systems that take into account the output of multiple machine learning models to make a decision. If only one model is successfully attacked, it may not have much leverage in affecting the final decision of the system. However, if multiple or all models are successfully attacked, then it may be likely that the decision-making of the full system would also be impacted.

### 10.1) AI Components

AI components 1005 may be imported into the system. AI components may include, but are not limited to, images, videos, serialized data formats (e.g., XML, JSON, BSON, YAML, MessagePack, and/or protobuf, etc.), AI models, simulations, configuration files, and/or inference results, etc. These inputs may be provided to a generalized object detection 1010 module. AI components may include data from computer vision based tasks, including but not limited to, classification, object detection, object segmentation, and/or semantic segmentation, etc.

### 10.2) Generalized Object Detection

Generalized object detection 1010 may be (potentially optionally) used, wherein a pre-trained model on general objects may be utilized to locate objects in computer vision data and/or to target segments to attack. This module may seek out data from other sources, such as Google images, Shutterstock, Bing images, and/or others, to train additional generalized object detection models. The result of this module may be labels with coordinates of objects and/or new images and/or videos containing a cropped version of the objects.

### 10.3) Synthetic Data Generation

Synthetic data generation 1015 may generate adversarial attacks on a computer vision model. For example: it may use a GAN to generate new, synthetic instances of data; it may replace segments of an existing image with synthetic data, for example modifying an image containing a red light to contain a green light; and/or it may generate new images entirely that are optimal for adversarial attacks; etc.

### 10.4) Robustness Assessment

A robustness assessment 1020 may analyze newly generated data against analysis metrics, including (but not limited to) robustness. An assessment may determine how robust the model is against synthetic adversarial attacks. An assessment may provide feedback to a synthetic data generation 1015 module to generate more powerful and/or subtle attacks. It may provide feedback to an attacked dataset and or vulnerability results 1025 module on what steps may be taken to harden the system against the successful attacks.

10.5) Attacked Dataset and/or Vulnerability Analysis Results

An attacked dataset and or vulnerability analysis results 1025 may be potential outputs of synthetic data generation for computer vision. The results of the analysis system are a new dataset of attacked data, which may be used in fine-tuning and/or training to improve robustness of the model. Additionally or alternatively, results may include vulnerability analysis results, which may include, but is not limited to, explanations of what features are vulnerable, which types of attacks were most successful, and/or which objects were more prone to attacks, etc.

### 11) Function of the Invention: Synthetic Data Generation for Text-Based Adversarial Attacks

FIG. 11 illustrates an example (e.g., used in the analysis system) (similar to FIG. 10) that may be used for attacking text-based models using synthetic data 1100, such as NLP models, other types of models, such as (but not limited to) those trained on numerical and/or sequential data, etc. This may result in an assessment of the model's vulnerabilities and/or a dataset of successful attacks that may be used to assess the system or used for training and/or fine-tuning.

11.1) AI Components and/or Input Samples

AI components and or input samples 1105 may include, but are not limited to, structured and/or unstructured text, a text-based model (e.g., sentiment analysis, LLMs, natural language classifiers, text encoders, autoregressive models, and/or deep bidirectional transformers, etc.), weights, source code, and/or binaries, etc.

### 11.2) Synthetic Data Generation

Synthetic data generation 1110 may create text-based data to attack a model. For example, LLM may be used to generate several variations of a sentence to attempt to evade a phishing detection model. Variations may contain synonyms and/or variations of ways to word a sentence that has the same and/or a similar meaning. An objective of this module may be to generate samples that will change the outcome of the model but are covert to a human.

### 11.3) Model Interface

The analysis system may connect to available model interfaces 1115 for models. This may include, but is not limited to, an API, CLI, and/or a webpage where inference data is entered, etc. The model itself may be loaded into the system. In this module, synthetic data may be used as input to attack the system.

### 11.4) Robustness Assessment

The analysis system may assess the AI system for analysis metrics, including (but not limited to) a robustness assessment 1120, against the attacked data. It may determine if the model meets required metrics in order to be considered safe to deploy. It may determine the types of words and/or synonyms an NLP model is vulnerable to.

11.5) Attacked Dataset and/or Vulnerability Analysis Results

Outputs of the synthetic data generation may include an attacked data set and or vulnerability results 1125. A dataset of synthetic data may be provided to a user to assess for example the robustness of their text-based models and/or to use during training and/or fine-tuning. Vulnerability analysis results may be provided to a user, for example including the types of attacks that were successful against the model.

12) Function of the Invention: Detecting and/or Reversing AI Models from Computer Binaries

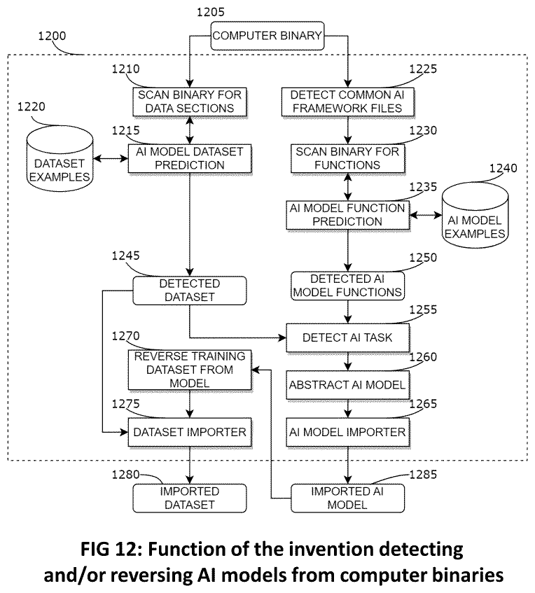

FIG. 12 illustrates how AI models may be detected, understood and/or reversed 1200, etc. An AI model may be reversed from (but not limited to) JIT, bytecode, assembly code, a computer binary, source code, full syntax trees, and/or abstract syntax trees, etc. In the example below, the process is described for reversing an AI model from a computer binary. AI components (e.g., computer binary) 1205 may be arbitrarily giving computer instructions on various tasks, and/or may or may not contain an AI model, training, testing, validation, and/or inference dataset, configuration specifications, and/or other types of data related to AI and/or datasets. A scan the binary for data sections 1210 module detects sections of a computer binary that contain data, of which may or may not be data related to AI model(s) and/or system(s). These data sections may include, but are not limited to, weights for the AI model, a dataset for the model, and/or a file that designates the file's dataset configuration, etc. This dataset may be provided to an AI model dataset prediction 1215 module that detects if those data sections are, in fact, types of data that would be used for an AI model. This detection may for example be implemented using discrete functions, algorithmically, statistical, probabilistic approaches, and/or using an AI model that was trained to detect other AI model data in computer binaries, etc. This feature may utilize a data store that stores different dataset examples 1220 of AI model data for comparison, training, and/or other computation that enables the analysis system to detect AI model data. This data store may include, but is not limited to, a SQL database, NoSQL database, relational database, and/or graph database, etc. Output may include a detected dataset 1245, wherein the format may be flexible, and/or may for example be in the form of JPEG, PNG, GIF, BMP, MP3, WAV, DOC, PDF, CSV, JSON, AVI, TXT, and/or other data formats, etc.

There may be a module to detect common AI framework files 1225 that detects if a computer binary comprises commonly-used file system(s)/format(s) to store AI model libraries. This may include but is not limited to: TensorFlow Lite files (TFLite), TensorFlow Serving Models, and/or any other known sorted AI model format, etc. A scan the binary for functions 1230 may scan the binary for functions, for example if no known library, module, and/or storage type is found, etc. The results may be used by AI function prediction 1235, which determines if a given function is related to execution of an AI model, including but not limited to: an inference function, a training function, an optimization function, and/or a fitness function, etc. This function may communicate with a data storage that has (potentially many) different AI model examples 1240 of known functions that may be used for AI, which may or may not be used to increase the accuracy of determining the relation of a given function to AI. The results may include any detected AI model functions 1250 that were detected in the computer binary.

A detect AI task 1255 module may detect the task the model is designed to carry out, such as natural language processing, computer vision, tabular data, and/or other types of general AI model tasks. It may, for example, abstract the AI model(s) into semantic representations, which are used to import an abstract AI model 1260 into a known structure in an AI model importer 1265. This may result in an imported AI model 1285 that may for example be used for further analysis. Using the imported AI model, the analysis system may determine if it can reverse a training dataset from the model 1270, such as the weights and/or functions. Reversing techniques include, but are not limited to: reverse poisoning attacks, model data extraction, and/or other techniques that may withdraw datasets from a trained model, etc. A potentially reversed training dataset, along with the previously detected dataset, may be imported to a known format in a dataset importer 1275, which may be stored as a known imported dataset 1280 in a suitable and/or specified format.

### 12.1) AI Components (e.g., Computer Binary File)

One or more computer binary 1205 may be an input to the analysis system. The computer binary is used to detect and/or import any present AI libraries, functions, data, datasets, model weights, and/or other characteristics pertaining to AI models, etc. The computer binary may take forms including, but not limited to: Computer binaries designed to run on computing systems, standard Personal Computers (PCs) stored on physical hard drives, solid-state drives, other forms of physical storage or memory medium, data being delivered through physical medium via networking and/or networking protocols such as Ethernet, Wi-Fi, Bluetooth, and/or other physical mediums, and/or through web protocols including HTTP, HTTPS, and/or TCP, etc.

A computer binary may take other forms such as for example binaries designed to run on other types of computing systems including but not limited to: binaries designed to run on mobile phones, smart phones, tablets, gaming consoles, infrastructure devices including routers, switches, modems, OT/ICS infrastructure systems such as SCADA units, sensor devices, HMI systems, FPGAs, and/or any other form of computing system, etc. AI components may form the input to a mechanism that scans the binary for data sections 1210 and/or detects common AI framework files 1225

### 12.2) Scan Binary for Data Sections

A scan binary for data sections 1210 module may be a feature that scans a computer binary 1205 for sections that contain data that may be used as input and/or output data for an AI model. This may for example be implemented using disassembler programs, such as (but not limited to) IDA, Ghidra, Binary Analysis Platform (BAP), and/or any other disassembly program, computational programs that may determine data sections in binary file architectures etc. A scan binary for data sections 1210 module may scan for data segments in the binary, and/or output the detected data sections within the given computer binary. Detected data sections may be provided to an AI model dataset prediction 1215 module.

### 12.3) AI Model Dataset Prediction

An AI model dataset prediction 1215 module may be a feature that detects for one or more detected data sections in a computer binary if it contains a dataset being used for an AI model. Examples of datasets being used for an AI model include, but are not limited to: Photo data, video data, natural language data, tabular structured data, and/or other forms of structured (and/or semi-structured and/or unstructured) data, etc. An AI model dataset prediction 1215 module may interact with a AI dataset examples 1220 storage, which includes, but is not limited to, examples (and/or specifications, algorithms, and/or models, etc.) of data pertaining to an AI system. AI model dataset prediction on data sections (e.g., read from storage or via a network) may for example be implemented by, but not limited to: transforming the data to replicate similar functions/features to the dataset in the detected data sections; using an AI model to detect whether or not the data belongs to an AI dataset or AI model; comparison approaches; transformation mechanisms; specification-based approaches; model-based approaches; algorithmic approaches; statistical approaches, probabilistic approaches, AI training based approaches; and/or other mechanism of providing classification of said binary data segments into potential AI model datasets; etc.

### 12.4) Data Store

A dataset examples 1220 module may include example datasets which an AI model dataset prediction 1215 module may use to determine if detected data sections contain AI model datasets. Data stores for the dataset examples may include, but is not limited to, file(s), SQL database, NoSQL database, relational database, and/or graph database, etc. Data stores may be implemented for example as a database server performing requests and/or providing data requested by other modules, a file stored on a storage device, and/or through other mechanisms that allow for data to be transferred to the other module, etc.

### 12.5) Detect Common AI Framework Files

A detect common AI framework files 1225 module may be a feature that analyzes one or more computer binaries 1205 to detect whether a model comes from a commonly known AI framework (and/or potentially which AI framework). Commonly known AI frameworks include, but are not limited to: TensorFlow Lite files (TFLite), TensorFlow Serving Models, and/or other stored AI model formats. Mechanisms to implemented common AI framework detection include but are not limited to: checking for headers inside of a file; and/or checking for known structures that describe a known AI framework; etc. If this module detects framework file(s) or known framework information, it produces an output, including (but not limited to): collecting identified files; tagging identified files with metadata; and/or produces a suitable description of the identified files and/or AI frameworks; etc. This output may be made available to a scan binary for functions 1230 module. If no known frameworks or framework data may be detected, it may (for example) still provide a computer binary 1205 to a scan binary for functions 1230 module.

### 12.6) Scan Binary for Functions

A scan binary for functions 1230 module is a feature that may scan the computer binary (e.g., loaded from a storage or network) for all potential function calls in a computer binary 1205 (e.g., analyzes a binary for functions that are used for any computation inside of the binary), and/or may separate out the functions for further analysis, etc. This may be implemented using techniques such as for example decompiling the binary using decompiling tools such as (but not limited to) IDA, Ghidra, and/or BAP, etc., and/or designate individual functions from the binaries. This module may execute after the computer binary has been filtered by a detect common AI framework files 1225 module. This module may communicate any detected functions to an AI model function prediction 1235 module for further analysis.

### 12.7) AI Model Function Prediction

An AI model function prediction 1235 module may be a feature that determines (or predicts) if functions detected by a scan binary for functions 1230 module implement/contain one or more AI models and/or any of its potential functions. This may be implemented using binary scanning and/or analysis tools such as (but not limited to) IDA, Ghidra, and/or BAP, etc. This may be implemented using AI models that classify functions as including AI (functionality, and/or models, etc.) or not, using techniques such as linear regression models, classifier models, neural networks, decision trees, and/or any other mechanism that may detect the parameters and/or operation of a computer function. Functions in which AI is detected may be collected as detected AI model functions 1250 and/or may be used in further analysis.

### 12.8) AI Model Examples

An AI model examples 1240 module may include potential examples of functions for AI models. AI models may for example include (but not limited to) model files, model specifications, source code, and/or binaries, etc. Data stores to store model examples may be implemented as a database (such as NoSQL database, SQL database, MySQL, PostgreSQL, Microsoft SQL Server, MongoDB etc.), file(s), and/or other information storage, for example stored on a physical storage, on temporary storage such as RAM, accessed directly (file system, and/or database, etc.), via API, via Wi-Fi, and/or Ethernet, etc. An AI model examples 1240 module may communicate examples of functions that are or are not AI related with an AI model function prediction 1235 module.

### 12.9) Dataset Detected

A detected dataset 1245 module may include one or more datasets that contain AI-related data as determined by an AI model dataset prediction 1215 module. Datasets may be stored and/or represented in the computer binary's native storage approach and/or another suitable representation. Datasets may be provided to a detect AI task 1255 module and/or a dataset importer 1275 module.

### 12.10) Detected AI Model Functions

A detected AI model functions 1250 module may include a set of detected AI model functions detected in a computer binary 1205 that define or implement a partial or complete AI model, including but not limited to functions such as: inference functions, fitness functions, optimization functions, and/or other AI related functions that are used to operate known AI models. This module may be created by an AI model function prediction 1235 module, and/or may be passed to a detect AI task 1255 module.

### 12.11) Detect AI Task

A detect AI task 1255 module may determine the type of task an AI function in the computer binary 1205 may perform, including for example (but not limited to) Natural Language Processing (NLP), computer vision, and/or tabular data regression, etc. Inputs into a detect AI task 1255 module may include (but not limited to) AI related functions from a detected AI model functions 1250 module, and/or detected datasets related to running an AI model from the detected dataset 1245 module, etc. Detecting the AI task may be implemented using approaches such as (but not limited to) running the computer binary's AI functions to extrapolate I/O shape data from the model, determining the shape and/or design of the dataset, and/or using AI models to determine the task and/or functionality of said functions and/or datasets, etc. The detected AI task(s), the detected dataset, AI functions, and/or task, etc., may be written to a storage, such as a storage device, and/or networking device etc. The detected AI task(s) may be provided to an abstract AI model 1260 module.

### 12.12) Abstract AI Model

An abstract AI model 1260 module may process and/or abstract AI model functions into semantical representations for example to allow for easier import into a system. Inputs into an abstract AI model 1260 module may include one or more of a detected dataset 1245, detected AI model functions 1250, and/or known task from a detect AI task 1255 module, etc.

Abstracting AI model functions into semantical representations may be implemented using approaches such as (but not limited to): semantic reasoning about detected AI tasks, mathematical comparison between the run binaries and/or abstracted functions, comparison to known and/or common AI model designs and/or formats such as neural network architectures, and/or other approaches to create an abstract representation of the AI model. If abstraction is successful, the output of an abstract AI model 1260 module may include an abstracted AI model, which may be written to a storage such as a storage device, and/or networking device, etc. An abstracted AI model may be provided to an AI model importer 1265 module.

### 12.13) AI Model Importer

An AI model importer 1265 may import and/or transform an abstracted AI model and/or its functions into a known structure for later usage. One or more abstracted AI model inputs may be provided by an abstract AI model 1260 module. An AI model importer 1265 may be implemented using various approaches to import the model into a known format, including (but not limited to) approaches such as: using a dataset that matches mathematical (or other functional, and/or structural, algorithmic etc.) representations of functions to known code implementations in a known programming language and/or framework; and/or importing the known weights and/or structures of an abstracted AI model into a known framework and/or model, etc. The imported AI model with known weights, functions, and/or other features/data required to execute an AI model may be written to a storage (e.g., physical media, and/or network location, etc.). The imported AI model may be provided to an imported AI model 1285 module for further analysis and/or other actions.

12.14) Reverse Training Dataset from Model

A reverse training dataset from model 1270 module may determine (create) a potential dataset from an AI model (which may be provided by an imported AI model 1285 module), using techniques that can reverse a potential training and/or testing dataset from an imported AI model. This may be implemented using techniques such as (but not limited to): AI reverse poisoning attacks, model data extraction, statistical techniques, probabilistic techniques, algorithmic techniques, and/or generative AI techniques, etc. If extra dataset information was extracted from the imported AI model, a reverse training dataset from model 1270 module may output AI dataset information in a known format such as (but not limited) to file(s) containing dataset information (e.g., JSON, XML, text, and/or CSV etc.), other file(s) (e.g., saved on a storage) that describe the dataset, API, database, and/or any other suitable approach of saving the output data. A reverse training dataset from model 1270 module may provide its outputs to a dataset importer 1275 module.

### 12.15) Dataset Importer

A dataset importer 1275 module may transform a given detected dataset 1245 in an unknown format (and/or a known format but not one usable by an internal system), potentially with additional data from a reverse training dataset from model 1270 module, into a known, usable format. This transformation and/or importing may be implementing using approaches such as (but not limited to): scanning the known dataset for known shapes and/or designs, segmenting the dataset into different samples, and/or rewriting the dataset into a known format for later usage etc. The produced dataset may be in many different forms/formats, such as (but not limited to): file(s) (JSON, XML, and/or CSV, etc.), and/or database file(s) etc., and/or may be saved to a storage (e.g., physical media) or a database (e.g., MongoDB, Postgres, MySQL, NoSQL, and/or graph database, etc.), and/or communicated via a network (e.g., API), etc. A dataset importer 1275 module may provide its output dataset to an imported dataset 1280 module for further analysis and/or other actions.

### 12.16) Imported Dataset

An imported dataset 1280 module may include any imported dataset(s) produced by the analysis system, and/or may be usable by the analysis system (or elsewhere). This may for example be a file stored on a hard drive (e.g., accessed by a database server) in a suitable format, including for example a JSON file, XML file, text file, a folder containing many parts of the training/testing dataset, and/or other suitable mechanism for storing data, etc. An imported dataset 1280 may be provided by a dataset importer 1275 module, and/or may be used for further analysis and/or other actions.

### 12.17) Imported AI Model

An imported AI model 1285 module may include any AI models produced (e.g., by the analysis system), and/or is/are usable by the analysis system (or elsewhere). This may for example be a file stored on a hard drive (e.g., accessed by a database server) in a suitable format, incl. for example a JSON file, XML file, text file, a folder containing many parts of the training/testing dataset, and/or other suitable mechanism of storing data, etc. An imported AI model 1285 (incl. AI model, and/or imported functions etc.) may be provided by an AI model importer 1265 module, may be used for further analysis or other actions, and/or may constitute an input into the into a reversing training dataset from model 1270 module.

### 13) Function of the Invention: Detecting Known Frameworks in a File

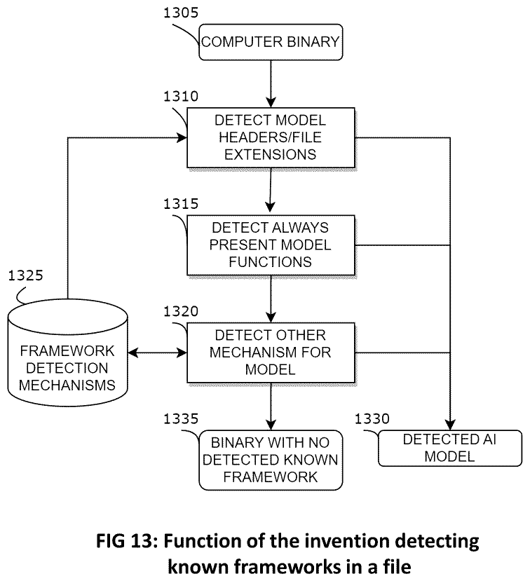

FIG. 13 illustrates an example (e.g., used in the analysis system) for detecting frameworks for storing AI models as a computer binary. While FIG. 13 illustrates detecting frameworks in a computer binary, the analysis system may include, but is not limited to, detecting known frameworks for storing AI models in JIT code, source code, machine code, and/or assembly code, etc. Files such as a computer binary 1305 form an input into a detect model headers and or file extensions 1310 module, which scans the file for headers, file extensions, and/or other metadata (such as debug information, strings etc.). A detect model headers and or file extensions 1310 module may detect known headers and/or other binary content by applying one or more framework detection mechanisms stored in a framework detection mechanisms 1325 module. If any matches are found, it may provide a detected AI model 1340 file type and/or the binary as an output for further use in the analysis system (and/or elsewhere).

The analysis system may detect always present model functions 1315 for a framework in a binary (e.g., if no matches are found). This may include (but is not limited to) finding functions such as (but not limited to) known library configurations, known setup functions, and/or other known information about the binary, etc.

The analysis system may be able to detect other mechanisms for models 1320 that may indicate a known structure for a model file (e.g., if no matches are found). This may include (but is not limited to) file extensions checked against structures known by the analysis system (e.g., an h5 file with known internal structure designating the model weights), and/or comparing against other previously seen binaries (e.g., stored within the analysis system), etc.

If no mechanism detects a known model, the analysis system may use a binary with no detected known framework 1335 may be returned for further use/analysis.

Formats to analyze include, but are not limited to, binary, assembly, bytecode, JIT, source code, and/or FPGA IP, etc. Tasks (of the AI model) that may be discovered include, but are not limited to, specific image classification tasks, semantic segmentation, object detection, voice recognition, speech synthesis, signal processing, and/or other tasks. Examples of tasks that may be discovered include, for example, that a model is detecting objects (e.g., part recognition, defect detection, and/or anomaly detection, etc.) for a specific use case, such as in an automotive assembly pipeline, and/or using computer vision, etc.

FIG. 13 illustrates the analysis system as it may be used for detecting frameworks in a computer binary. This may use approaches such as (but not limited to) reading a computer binary file, such as .exe, .bin, and/or any other runnable computer binary designed for computing systems, loaded from storage (e.g., physical media) or via networking devices, and/or transferred data from internet services and/or other media, etc. The analysis system may determine and/or predict that there is an AI framework (e.g., by detecting common patterns and/or operations), but it may not be able to characterize/identify the framework (e.g., new frameworks that have not yet been included in the system), and/or may not have a high enough confidence in the framework selected, etc. In this case, it may still be able to group binaries from different runs through the analysis system that contain a framework that it is either uncertain about and/or does not know. If the analysis system is later updated with more context about the framework (such as a new framework detection mechanism being included in the analysis system), the analysis system may backpropagate and/or update past analysis results, for example (but not limited to), determine the type of framework on a previously analyzed binary, and/or increase the confidence in a detected framework in a binary, etc.

The analysis system may accept computer binary file(s), using the modules described in FIG. 13 to detect if the binary contains known framework data for an AI model, and/or outputs either a detected AI model with a known framework, and/or the computer binary with no known framework (note that the module order could be different, not all modules need to be present, and/or modules could be combined), and/or other related tasks, etc.

### 13.1) Computer Binary

A computer binary 1305 may be a computing system binary file that may be provided as input into the analysis system. A computer binary may be a compiled binary compiled from various programming languages, such as (but not limited to) C, C++, Java, Python, Scala, and/or Kotlin, etc., and/or may be compiled for various computer architectures, such as (but not limited to) x86, ARM32, ARM64, Blackfin, MIPS, MMIX, RISC, Mico32, PowerPC, RISC-V, and/or SPARC, etc. A computer binary file may be read (but is not limited to) from a storage (e.g., physical media such as storage devices) and/or via a network, etc. It may form input(s) into a detect model headers and or file extensions 1310 module.

13.2) Detect Model Headers and/or File Extensions

A detect model headers and or file extensions 1310 module may scan an inputted computer binary file and/or check the file for common, known elements, such as (but not limited to) headers and/or sample data at the beginning and/or end of the file, that may indicate that the file is a known format, etc. A detect model headers and or file extensions 1310 module may include scanning, which may include mechanisms such as (but not limited to) scanning for headers in the beginning of the binary file, such as a TF3 header in the first several bytes of the file for TF-Lite models, a .h5 file extension in addition to a file header describing a TensorFlow data format, and/or other types of headers that describe AI model information, etc. A detect model headers and or file extensions 1310 module may use a framework detection mechanisms 1325 module that may contain scanning mechanisms related to headers, and/or file extensions, etc. A detect model headers and or file extensions 1310 module may check if model information (data, and/or file, etc.) may be detected. If so, the detected AI model data may be (but not limited to) written to a storage (e.g., physical media), may be transferred via a network (e.g., API), and/or may form a detected AI model 1330 output of the analysis system, etc. If nothing is detected, a detect always present model functions 1315 module may be triggered (and/or the computer binary may be transferred to that module)

### 13.3) Detect Always Present Model Functions

A detect always present model functions 1315 module may scan an input computer binary 1305 (potentially received from a detect model headers and or file extensions 1310 module) for other data and/or functions that are always present in known AI formats. Such scanning may for example (but not limited to) include scanning for known preprocessing functions that allow the binary to set up, known importing functions such as library imports that describe known AI libraries such as SciKit Learn, TensorFlow, PyTorch, Caffe, CNTK, MXNet, H20, Core ML, Shogun, etc., and/or other known AI frameworks, and/or otherwise known functions that are always present for known AI frameworks, etc. If a known framework and/or other data is detected by a detect always present model functions 1315 module, a detected AI model data may be written to a storage (e.g., physical media), may be transferred via a network (e.g., API), and/or may form a detected AI model 1330 output of the analysis system. If nothing is detected, a detect other mechanism for model 1320 module may be triggered (and/or the computer binary may be transferred to that module).

### 13.4) Detect Other Mechanism for Model

A detect other mechanism for model 1320 module may scan an input computer binary 1305 (potentially received from a detect always present model functions 1315 module) and/or determine if there are other potential mechanisms for scanning for known AI model data. It may do this by reading the computer binary from physical media, obtain one or more known mechanisms for detecting known frameworks from a framework detection mechanisms 1325 module, and/or run the mechanism(s) to determine if there is a known framework in the computer binary, etc. Scanning may include (but is not limited to) checking file extensions against internal structures (e.g., an h5 file with known internal structure designating the model weights) and/or other internal data (e.g., stored within the analysis system). If a known framework or other data is detected by a detect other mechanism for model 1320 module, the detected AI model data may be written to a storage (e.g., physical media), may be transferred via a network (e.g., API), and/or may form a detected AI model 1330 output of the analysis system. If nothing is detected and/or the confidence of the frameworks detected are too low, a binary with no known detected framework 1335 module may be triggered (and/or the computer binary may be transferred to that module).

### 13.5) Framework Detection Mechanisms

A framework detection mechanisms 1325 module may include, but is not limited to, other mechanisms and/or techniques for detecting known frameworks and/or AI data that may be scanned from a computer binary. This may for example (but not limited to) be implemented as a physical database server such as a MySQL server, a PostgreSQL server, a MongoDB server, and/or implemented as a file such as a JSON file, XML file, a TXT file, a code or executable file, and/or as a networked device (e.g., API server), etc. A framework detection mechanisms 1325 module may interact with a detect other mechanism for model 1320 module and/or the detect model headers and or file extensions 1310 module, and/or may return mechanisms for detecting known AI model frameworks.

### 13.6) Detected AI Model

A detected AI model 1330 module may include the output where an AI model was detected from a known framework, which may be used for further analysis by the analysis system (and/or elsewhere). This output may only be produced if either of a detect model headers and or file extensions 1310 module, a detect always present model functions 1315 module, and/or a detect other mechanism for model 1320 module detect at least one known framework for an AI module.

13.7) Binary with No Detected Known Framework

A binary with no detected known framework 1335 module may include a computer binary for which the analysis system did not detect any known detected AI framework data inside the computer binary. This output may be written from a detect other mechanism for model 1320 module, and/or may be used by the analysis system (and/or elsewhere). This may be implemented in ways including, but not limited to, being written as a binary file stored on a storage (e.g., physical media such as a storage disk), and/or transmitted (e.g., via API) over a network (e.g., Wi-Fi, Ethernet, cell, or any other networking approach), and/or other physical means, etc.

14) Function of the Invention: Sorting Known Binary Functions into AI Functions and/or Non-AI Functions

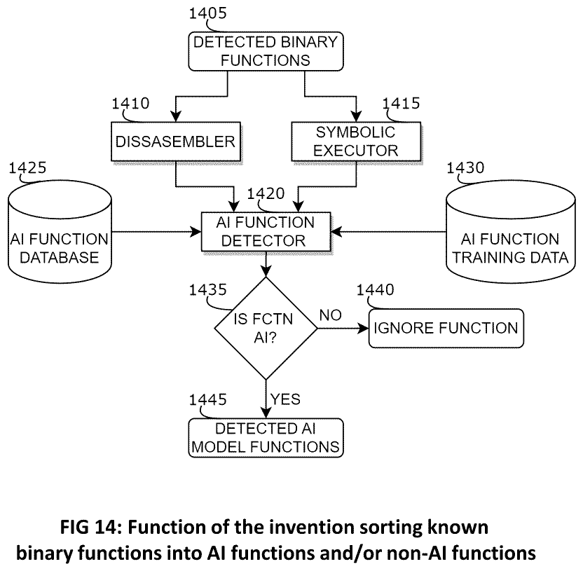

FIG. 14 depicts an example (e.g., used in the analysis system) for sorting known functions from a binary file into functions that either contain AI and/or do not contain AI. The input may be one or more detected binary functions 1405 (detected for example as described above). The disassembler 1410 module may apply a disassembler to a detected binary functions 1405 so they may be represented easier for other types of execution. A symbolic executor 1415 module may then apply a symbolic executor (which may transform code to a mathematical representation of the code), and/or transforms a detected binary functions 1405 into a symbolic representation of the code, etc. One or both of a disassembler 1410 output and/or the symbolic executor 1415 output may form the input into an AI function detector 1420. An AI function detector 1420 may be implemented as an AI model that may be built and/or trained to determine if function contain AI, based on given arbitrary binary functions. To train this AI model, a set of AI function training data 1430 may be applied to an AI function detector 1420's AI model, with the goal to create a high level of accuracy. An AI function detector 1420 may be implemented without AI, but instead by other types of AI and/or non-AI algorithms that can create comparisons between the given function and/or other functions, and/or find symbolic similarity. To support this, an AI function detector 1420 may draw on an AI function database 1425 of functions containing both AI and/or not containing AI, using it to create symbolic comparisons between the data functions and/or the provided function, so an AI function detector 1420 may detect if the function does indeed contain AI. If the output 1435 of an AI function detector 1420 is “yes”, the model function may be stored for later use in the analysis system, labeled and/or included in a set of detected AI model functions 1445. If the output is “no”, the function may be labeled as an ignored function 1440 and/or is ignored in future computation.

FIG. 14 describes the analysis system as it may be used for sorting known binary functions into AI functions and/or non-AI functions. From input functions from a binary file (and/or other functions from a compiled computer binary) the analysis system may determine if any functions in the detected binary functions 1405 are used in the context of AI. This may be implemented by reading a set of functions from a storage (e.g., physical device) and/or over a network (e.g., API), in a suitable format (e.g., file), analyzing those functions on computing devices (e.g., CPUs, GPUs, and/or TPUs, etc.), and/or writing the detected AI model functions, for example to a storage (e.g., data file, physical device) and/or network (e.g., via API, over Ethernet, and/or Wi-Fi, etc.)

### 14.1) Detected Binary Functions

A detected binary functions 1405 module may include, but is not limited to, a set of detected binary functions. This may form the input into a disassembler 1410 module and/or a symbolic executor 1415 module. This may be a physical file such as a file (e.g., JSON, XML, and/or CSV, etc.) containing all of the binary functions provided to the other modules to be used (for example) for sorting.

### 14.2) Disassembler

A disassembler 1410 module may disassemble a detected binary functions 1405 input and transforms it into a disassembled representation for easier and/or further analysis, such as an assembly language and/or intermediate representation. This may be implemented using for example (but not limited to) programs such as Ghidra, IDA, BAP, and/or other disassembler programs. The disassembled representation may be provided to an AI function detector 1420 module.

### 14.3) Symbolic Executor

A symbolic executor 1415 module may, for a given arbitrary computer binary, find representations of the functions on a “semantic level”, meaning defining the function as its actual function and/or input/output, instead of its exact implementation. A symbolic executor 1415 module may transform a detected binary functions 1405 input into semantic representations, and/or output the semantic representations of the functions to an AI function detector 1420 module. This may be implemented using tools such as (but not limited to) BAP, S2E, and/or crab, etc. The symbolic executor 1415 module may be implemented as programs stored on a storage, processed as a processor, and/or may be accessible locally and/or via a network.

### 14.4) AI Function Detector

An AI function detector 1420 module may receive disassembled (from a disassembler 1410 module) and/or symbolic representations (from a symbolic executor 1415 module) of one or more binary functions, as well as data from other systems of potential binary functions and/or other representation. An AI function detector 1420 module may categorize the binary functions into whether or not the binary function is related to any AI functions. It may then determines if a given function is an AI-related function or not, using the additional resources in an AI function database 1425 module and/or an AI function training data 1430 module. It then may decide (“Is function AI?” 1435) whether or not a given function is an AI model function. This may be implemented by using various approaches, including for example (but not limited to): using a categorization AI model trained on data from an AI function training data 1430 module; using a decision tree function; using the AI function database module to determine if the model is semantically similar to any known AI or non-AI function; determining if the binary function is already known and/or stored in the AI function database. Detected AI model functions 1445 may be used within the analysis system (or elsewhere). Any previously unknown detected AI model functions 1445 may be stored in an AI function database 1425 (e.g., to optimize future detection/analysis).

### 14.5) AI Function Database

An AI function database 1425 module may contain functions that either do or do not contain AI, with labels for each function as to whether or not the function is an AI function or not. An AI function detector 1420 may obtain stored samples of functions from an AI function database 1425. This may be implemented as a database server that provides one or more samples of data containing a function and/or whether or not the function is an AI function in a suitable format, such as a file (e.g., JSON, XML, and/or CSV, etc.), a SQL database return value, and/or other type of data sent back to any module when being queried, etc. Queries may be implemented via API, and/or network/internet access (e.g., Ethernet, Wi-Fi, and/or Bluetooth, etc.), etc. Storing the data may be implemented as a file on a storage (e.g., physical media such as a hard drive, and/or solid-state drive, etc.), and/or in a database, etc. An AI function training data 1430 may be collocated with an AI function database 1425, and/or may be the same.

### 14.6) AI Function Training Data

An AI function training data 1430 module may include more functions that either do or do not contain AI functions. This may be for the purpose of being potentially used as training data for any AI system in an AI function detector 1420 module. AI systems in an AI function detector 1420 module may be used to categorize functions into being AI related or not being AI related. This may be implemented as a database server that provides one or more samples of data containing a function and/or whether or not the function is an AI function in a suitable format, such as a file (e.g., JSON, XML, and/or CSV, etc.), a SQL database return value, and/or other type of data sent back to any module when being queried. Queries may be implemented via API, network/internet access (e.g., Ethernet, Wi-Fi, and/or Bluetooth, etc.), etc. Storing the data may be implemented as a file on a storage (e.g., physical media such as a hard drive, solid-state drive, and/or other similar storage media), and/or in a database, etc.

### 14.7) Is Function AI?

An Is function AI? 1435 module may receive one or more function(s) and/or whether the function is related to AI or not (from an AI function detector 1420 module). It may output the function to an ignore function 1440 module if the function is not AI related, and/or may output the function to a detected AI model functions 1445 module if the function is related to AI. This may for example be implemented as a decision tree computer program that—if the function is AI function—stores and/or transmits them (one or more of binary, disassembled, semantic representations, metadata, and/or reports etc.), to for example one or more of an AI function database 1425, an AI function training data 1430, and/or for further analysis by the analysis system (or elsewhere). If the function is not an AI function, this may for example be implemented by ignoring the function, and/or storing the function in a library of ignored functions, etc.

### 14.8) Ignore Function

An ignore function 1440 module may be triggered for a given function if the function is determined to not be AI related by an Is function AI? 1435 decision module. This may be implemented by not storing the function, and/or by storing the function in a library of ignored functions (e.g., to optimize further and/or for future analysis), etc.

### 14.9) Detected AI Model Functions

A detected AI model functions 1445 module may include functions related to AI, including for example aggregated functions of all functions from a computer binary related to AI (incl. e.g., AI processes, and/or tasks, etc.), etc. This may include one or more of binary, disassembled, semantic representations, metadata, and/or reports etc., and/or may be a file such as a file (e.g., JSON, CSV, XML file, binary file, and/or code file etc.), which may be stored on a storage (e.g., physical media) and/or communicated over a network (e.g., via API).

15) Function of the Invention: Importing an Abstract AI Model into a Known Representation

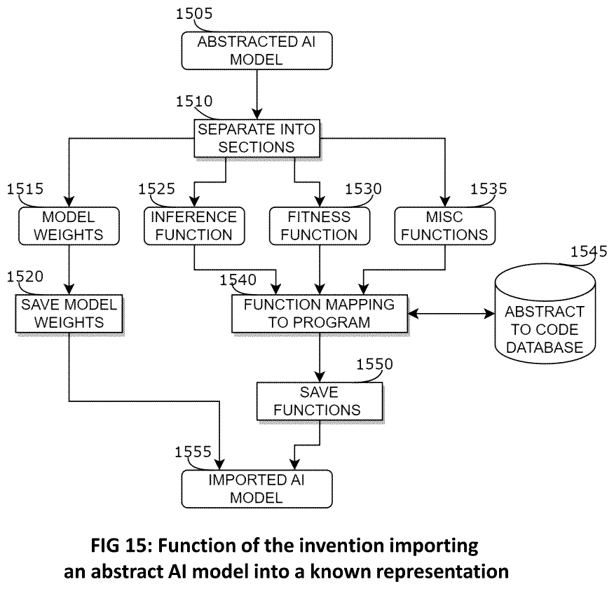

FIG. 15 depicts an example (e.g., used in the analysis system) for importing an abstracted AI model into a known AI model representation. This may include importing an abstracted model into a known machine learning framework (e.g., TensorFlow, PyTorch, Keras, Caffe, MXNet, Theano, WEKA, and/or MLLib, etc.). An abstracted AI model may include, but is not limited to, model weight files, architectures, functions such as optimization, inference, fitting, training, and/or forward/backward, etc. It may output different forms of imported AI model functions such as outputting a model in a known format, architecture, and/or framework, etc.

### 15.1) Abstracted Model

An abstracted model 1505 module may represent an abstracted AI model and/or its AI components. this may be a mathematical representation of an AI model stored in various mechanisms, such as mathematical representations of the model architecture, a decision tree, and/or model weights etc. This may be sent to a separate into sections 1510 module. The model may include, but is not limited to, a convolutional neural network (CNN), a deep neural network (DNN), a recurrent neural network (RNN), a decision tree, a support vector machine (SVM), a logistic regression model, a random forest, a gradient boosting model, a k-nearest neighbor (k-NN) algorithm, and/or a Naive Bayes classifier, etc.

15.2) Separate into Sections

A separate into sections 1510 module may separate an inputted abstracted model 1505 into smaller segments. It may separate the model into various functions and/or characterize them, such as weights 1515, inference functions 1525, fitness functions 1530, and/or miscellaneous functions 1535, etc. This may for example include decompiling and/or disassembling the abstracted model, and/or source code analysis to isolate functions and/or their higher dependencies in the abstracted model, etc.

### 15.3) Model Weights

Model weights 1515 may be isolated and/or available for analysis. Model weights may be represented for example as a file that contains weights for a given AI model, a serialized data format containing weights, and/or checkpoint files, etc. For example, this may include, but is not limited to, an ONNX model, a Caffe model, and/or a Keras H5 file, etc.

### 15.4) Save Model Weights

A save model weights 1520 module may be provided model weights from an abstracted AI model and/or saves the weights into a different known format. It may translate the model into other formats, which may be automatically selected by the analysis system and/or selected by a user prior to translation. Formats it may translate weights to may include, but are not limited to, ONNX files, HDF5 files, JSON files, and/or XML files, etc. These weights may be used to import the abstracted model into one or more of these formats, for example for inference, analysis, and/or fine-tuning, etc.

### 15.5) Inference Functions

An inference function 1525 may include one or more abstracted functions for inferencing an AI model. Inference functions may be bucketed together and/or available for mapping and/or translation. Inference functions may include, but are not limited to, various equations for calculating inference results, batch inference, and/or online inference, etc. Inference functions may be provided to a function mapping to program 1540 module.

### 15.6) Fitness Function

A fitness function 1530 may include one or more abstracted function used to carry out fitness scoring of an AI model. This may be provided by a separate into sections 1510 module, and/or forms an input into a function mapping to program 1540 module. Fitness functions may include, but are not limited to, a fitness function in source code, an instance of a fitness function class, multiple fitness functions for a single model, and/or a built fitness function, etc.

### 15.7) Miscellaneous Functions

Miscellaneous functions 1535 may include any other functions that may pertain to an AI model. This may include functions such as loss functions (e.g., mean absolute error loss, mean squared error loss, cross-entropy loss, hinge loss, margin ranking loss, Kullback-Liebler divergence, cosine similarity, categorical hinge loss, Poisson loss, and/or squared hinge loss, etc.), optimizer functions (e.g., Adam, SGD, Nadam, Adagrad, Adadelta, and/or SparseAdam, etc.), and/or backpropagation functions, etc.

### 15.8) Function Mapping to Program

A function mapping to program 1540 module may be provided abstracted functions, such as an inference function 1525, fitness function 1530, and/or miscellaneous function 1535 modules. The module may use an abstract to code database 1545 module to map the mathematical abstracted functions to code that may be stored for later use, and/or may be exported to a save functions 1550 module. This may be done by finding (e.g., using mathematical, statistical, probabilistic, and/or AI-based techniques, etc.) semantic similarities between the inputted abstracted function and/or the stored abstract representations from an abstract to code database 1540 module, and/or using a suitable (e.g., corresponding) abstract to code mapping to generate the functions corresponding to the abstracted functions in a new format (e.g., code).

### 15.9) Abstract to Code Database

An abstract to code database 1545 may be a data store that may contain mappings from abstract representations of AI model functions to real code implementations of those functions. This may be connected to a function mapping to program 1540 module, and/or may be queried for abstract representations of different code segments, and/or responds with one or more corresponding implemented code representations of the function. It may contain (but is not limited to) categorized code segments and/or may contain metadata, logs, and/or access controls, etc. The database may be implemented in several ways, including but not limited to, a database server, file containing data, file system, relational database, hierarchical database, non-relational database, distributed database, centralized database, and/or graph database, etc.

### 15.10) Save Functions

A save functions 1550 module may save any function into a known format. It may be provided with categorized functions from prior modules, and/or outputs saved functions as an imported AI model 1555. This may take the form of files stored in known formats such as (but not limited to) ONNX files, Python program files, binary files, source code representations in programming languages such as C, and/or any other known file representation, etc.

### 15.11) Imported AI Model

An imported AI model 1555 may be an output in the form of an imported AI model. This may for example (but not limited to) contain an AI model, weights, source code, and/or binaries, etc. It may be generated from save model weights 1520 and/or save function 1550 modules. Outputs may be used in the analysis system (or elsewhere). This may be stored for example (but not limited to) as a binary, source code, model file, weights file, compiled model, and/or intermediate representation, etc.

### 16) Function of the Invention: Describing a Mechanism to Find Semantically Similar AI Models

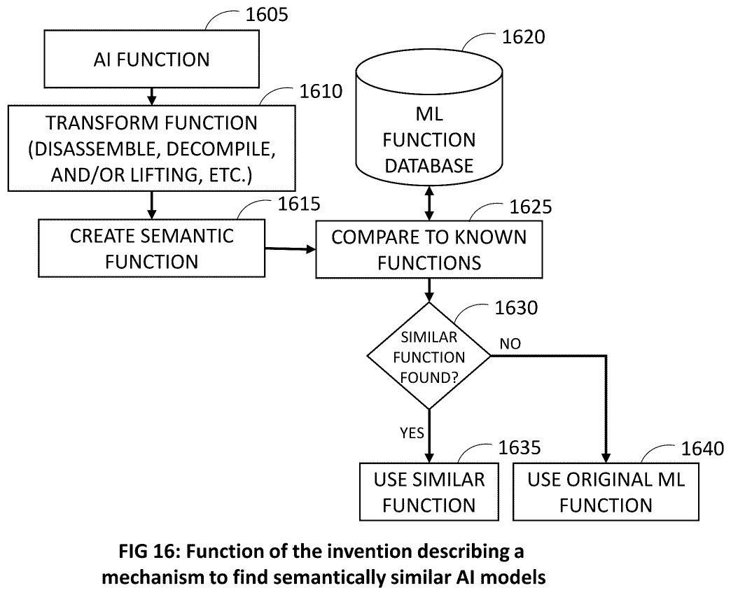

FIG. 16 depicts an example (e.g., used in the analysis system) for detecting semantically similar segments of code. Code may be at many different layers of abstraction, including but not limited to, source code, compiled code, assembly code, binary code, and/or bitstream, etc. This may for example take the form of a program running on a cloud or offline computing system. The analysis system may ingest one or more AI functions. It may output for example (but not limited to) similar functions containing AI components, a report of similar AI functions, dashboard, document, GUI, a report of similar vulnerable AI functions, and/or a scorecard, etc. FIG. 16 depicts an example that may be used for analyzing and/or comparing AI components, which may be used by the analysis system (or elsewhere).

### 16.1) AI Functions

AI functions 1605 may be an input comprising functions that may contain AI-related tasks. This may include, but is not limited to, AI-related tasks such as inference, fitting, training, forward/backward, optimization functions, model weights, and/or model architectures, etc. This may be represented as source code, text files, intermediate representations, binaries, JIT code, and/or bitstream etc. This module may be connected to a transform function 1610 module for further analysis.

16.2) Transform Function (Disassemble, Decompile, and/or Lifting, Etc.)

A transform function 1610 module may transform input into another form. For example, this may include, but is not limited to, disassembling, decompiling, and/or lifting the code. The analysis system may disassemble the input from its base binary representation into an intermediate language, such as an assembly language and/or other intermediate representation. Tools such as disassemblers may be used, such as (but not limited to) Ghidra, IDA, radare2, OllyDbg, WinHex, CFF Explorer, Scylla, Binary Ninja, Hopper, x64dbg, and/or Relyze, etc. The analysis system may decompile the input. This may use one or more tools such as, but not limited to, IDA Pro, Ghidra, radare2, Hex Rays, C4Decompiler, Boomerang, RetDec, Angr, Hopper, JustDecompile, Cutter, jadx, and/or Recaf, etc. The analysis system may lift the input. This may use one or more tools such as, but not limited to, LLVM, McSema, BinRec, Dagger, RetDec, Fracture, Reopt, RevGen, Bin2LLVM, Fcd, Egalito, Zipr, DDisasm, multiverse, and/or retrowrite, etc.

A transform function 1610 may disassemble known AI functions from a given computer binary, and/or may pass disassembled functions to a create semantic function 1615 module. Functions may already in disassembled form and/or may be passed along to the next steps without the need for disassembly. A transform function 1610 may decompile a function into a source code language, such as (but not limited to) C, Java, Python, JavaScript, and/or C++, etc. A transform function 1610 may lift a function into an intermediate representation, such as (but not limited to) LLVM IR, BAP IR, PNaCl IR, SPIR-V, MLIR, GCC IR, SPIR, and/or BNIL, etc.

### 16.3) Create Semantic Function

A create semantic function 1615 module may transform a disassembled program into a symbolic function. Symbolic functions may describe, for example (but not limited to), the input and/or output pairs of the function, how the function transforms all known pointers, data, and/or other program information etc. This may be achieved in a variety of ways, including but not limited to, capturing input and/or output pairs and/or other data by transforming the disassembled function into a semantic representation, using AI to transform the functions, breaking down the function into individual blocks, transforming them, and/or rebuilding the function as a semantic function representation, etc. Semantic functions may be passed to a compare to known functions 1625 module to determine if the functions are similar to past functions in the analysis system.

### 16.4) AI Function Database

An AI function database 1620 may contain data pertaining to AI functions. AI functions may be stored in a semantic form. The database may be implemented in several ways, including but not limited to, a database server, file containing data, file system, relational database, hierarchical database, non-relational database, distributed database, centralized database, and/or graph database etc. The database may be used to store many different semantic representations of AI models. Representations may be clustered into groups of similar functions, and/or may contain one or more similarity scores between functions. An AI function database 1620 may be queried by a compare to known functions 1625 module, and/or may return functions, relationships, and/or clusters, etc., from the query.

### 16.5) Compare to Known Functions

A compare to known functions 1625 module may find functions that are semantically similar to one or more AI functions 1605 that are under analysis. One or more techniques may be used to determine the similarity of functions to past functions in an AI function database 1620. Techniques for similarity analysis may include, but are not limited to, AI approaches (e.g., using an LSTM model to analyze similar sequences of code, creating an image representation and/or using computer vision to classify visual sequences of code, etc.), calculating similarity metrics (e.g., Jaccard index, Sørensen-Dice coefficient, cosine coefficient, Soergel distance, Euclidean distance, and/or Hamming distance, etc.), statistical approaches, and/or rules-based approaches, etc. It may include using decision trees and/or other AI mechanisms to compare how similar two functions are. It may output for example (but not limited to) a similarity score between functions, a similarity score between binaries, a report of semantically similar or identical operations or lines of code, the most similar functions previously analyzed to the new functions under analysis, and/or a list of vulnerabilities discovered in prior similar functions, etc. Functions may be compared regardless of the programming language, compiler optimizations, architecture, operating system, and/or AI framework, etc.

### 16.6) Similar Function Found?

A similar function found? 1630 module may be a decision-making mechanism for determining if a function is similar to another function. This module may ingest similarity scores between functions from a compare to known functions 1625 module. Similarity scores may have been generated using multiple metrics, approaches, and/or tools, etc. This module may make a determination if the similarity scores are high enough to be considered similar. Decision-making may be guided through user input, for example of what thresholds need to be met to consider two functions similar. If one or more similar functions are found, then the analysis system may output the semantically similar function in a use similar function 1635 module and/or the original AI function in a use original AI function 1640 module.

### 16.7) Use Similar Function

A similar function 1635 may be an outputted function that is semantically similar to the provided AI function. It may include, but is not limited to, results from prior analysis results from similar AI functions, a software bill of materials (SBOM), denoted segments of similar code, and/or similarity scores between the most similar functions, etc.

### 16.8) Use Original AI Function

A use original AI function 1640 module may be an outputted AI function. This may be an exact copy of the inputted AI function if no similar matches were found. Outputs may include a report, that for example (but not limited to) provides further information and/or documentation, and/or proof that the functions most similar to the AI function provided scores that were too low to be deemed similar by the analysis system, etc. The original AI function being returned may indicate that no prior analysis results that are cached are applicable.

17) Function of the Invention: Describing Known AI Functions being Compared to Sample Functions

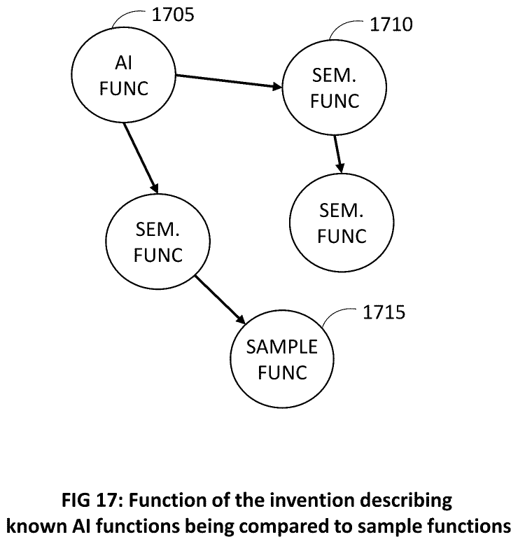

FIG. 17 depicts an example (e.g., used in the analysis system) for comparing one or more AI functions under analysis to other semantic representations of functions. The diagram represents an example of how functions may be represented as nodes with edges in a data storage (e.g., database). The output may be a known sample function being found to be semantically similar to the function under analysis. An AI function may be used as input is compared to previously seen functions stored in the analysis system. It may use a variety of mechanisms, including, but not limited to, statistical comparison between input/output pairs of the functions, comparison of all pointers and/or data changes from the AI function and/or other semantically represented functions, using a deep learning model to find similarities between functions, and/or any other mechanism that may calculate the similarity between two functions, etc. The analysis system may include syntax similarity between multiple functions.

### 17.1) AI Function

An AI function 1705 may include an ingested AI function. This may take many forms, including but not limited to source code, compiled code, and/or assembly code, etc., and/or may include various AI components such as inference, optimization, training, and/or any other function related to AI, etc. If a connection is found between the AI function and/or a semantically represented function 1710, a link and/or relationship may be formed between the functions. An AI function may be connected directly to a sample function 1715 and/or one or more semantically represented functions 1710.

### 17.2) Semantically Represented Functions

Semantically represented functions 1710 may include functions used for similarity analysis in relation to an inputted AI function 1705 under analysis. Semantically represented functions may be used to more efficiently discover similar functions and/or prior analysis results. Semantically represented functions may already be connected to other semantically represented functions, such as through a relational database, a graph database, a linked list, and/or a decision tree, etc.

### 17.3) Sample Functions

A sample AI function 1715 may include known AI sample functions in their original form. These may be linked to their semantic representations, for example to make similarity analysis more flexible and/or more accurate. These may be in their original unchanged form, which may then be used for other analyses in the analysis system (and/or elsewhere). These may be found through connections with semantically represented functions 1710, and/or directly with the AI function 1705, using similarity analysis mechanisms.

### 18) Function of the Invention: Auto-Deployment of AI Model

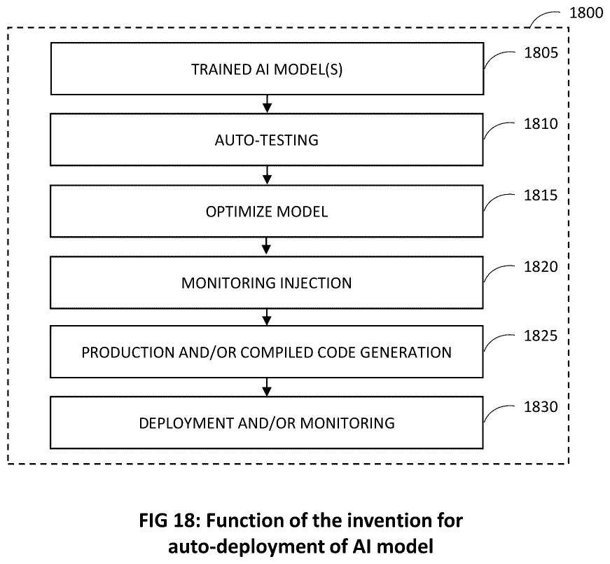

FIG. 18 depicts an example (e.g., used in the analysis system) for automated or semi-automated deployment of one or more AI systems 1800. For example, this may include, but is not limited to, automated configuration of a pipeline, such as a MLaaS, MLOps, CI/CD, and/or other type of pipeline. It may include deployment directly into production environments. This may include, but is not limited to, deployment to an embedded device, to one or more containers (e.g., Docker containers), cluster (e.g., Kubernetes), and/or to a service with endpoints, etc. It may include deployment of multiple AI systems that may or may not work together or work together across multiple systems. For example, for the case of an embedded device, it may translate the model to a different framework (e.g., TFServing, and/or ONNX, etc.), optimize it for embedded architectures, compile and/or compress the model, etc. It may include optimizations for batch, real-time, and/or streaming inference. It may include optimizations for online and/or batch predictions. The auto-deployment mechanism may handle the data flowing in and/or out of the model. For example, this may include, but is not limited to, data type handling, data storage, data-related vulnerability handling, preprocessing data, and/or sanitizing data, etc. While several stages in the auto-deployment diagram are included, not all stages are required, as the order of the stages may be different, and/or other stages not present may be included.

### 18.1) Trained AI Model(s)

An auto-deployment mechanism may ingest one or more trained AI models 1805. Trained AI models may come from an automated training engine in the analysis system, wherein the best model(s) are made available for deployment, and/or any other mechanism such as being imported to the mechanism manually by a user, a program, and/or any other input mechanism. These may include multiple models that work together in some way. These models may come in several formats, including but not limited to, a zipped file, a directory, source code, compiled code, a model file, weights, a compiled file, serialized data formats, and/or a combination of the one or more of the above, etc. This may be ingested through, for example (but not limited to), a CI/CD pipeline, API, MLaaS plugin, application, CLI, IDE, GUI, SDK, and/or by pushing a physical button, etc. It may include, but is not limited to, configuration files, version numbers, and/or provenance information, etc. These trained models may be provided to following step auto-testing 1810 for further usage.

### 18.2) Auto-Testing

Auto-testing 1810 may be performed on models to analyze and/or assess them before deployment. For example, this may include analyzing the performance of the model, testing it against out-of-distribution samples, assessing its robustness against adversarial attacks, and/or analyzing explainability aspects, etc. This may include aspects of robustness and/or defense, wherein the analysis system may inject new data, perform fine-tuning, add preprocessing and/or postprocessing, etc. It may detect vulnerabilities and/or attacks, such as poisoning attacks, and/or other characteristics such as bias. If it determines that a model is not ready to be deployed to a production environment, it may stop the auto-deployment process. This may include, but is not limited to, shutting down the build process, automatically retraining the model, making changes to the original models, providing feedback to users, sounding an alarm, flashing a light in the physical environment, providing a notification via text, and/or email, etc. The analysis system may track version numbers and/or changes made before, during, and/or after each deployment etc. It may log and/or archive this information for later usage, such as for compliance or legal reasons. It may test the model and/or return a report on if or how the model and/or its data are compliant.

### 18.3) Optimize Model

The analysis system may optimize models 1815 for deployment. For example, this may include, but is not limited to, optimizing a model for adversarial robustness, translating a model to a supported framework for the production system(s), making modifications to a model, making modifications to the preprocessing steps, and/or making modifications to the postprocessing steps, etc. It may optimize multiple models for a specific framework, compiled format, and/or fused model.

### 18.4) Monitoring Injection

The monitoring injection 1820 step may insert monitoring mechanism(s) into AI systems before deployment. This may include (but is not limited to) monitoring mechanisms that operate on top of an existing system, and/or inserted into the underlying model, etc. For example, this may include, but is not limited to, modifying the source code of the system to include logging of operations, introducing explainability mechanisms, defining monitoring components specific to AI systems being deployed, and/or latching the execution of the model to monitoring software, etc. Once this step is completed, models may be provided to a production and or compiled code generation 1825 module for further usage.

18.5) Production and/or Compiled Code Generation

The analysis system may generate production and or compiled code 1825 that may be introduced to the production system. For example, it may generate production code in source code format, such as (but not limited to) Python, Java, Go, and/or JavaScript, etc. It may generate low-level code, such as (but not limited to) bytecode, machine code, binary, executables, FPGA IP, FPGA bitstream, assembly language, and/or intermediate representation (IR), etc. Production and/or compiled code generation may include, but is not limited to, data preprocessing, sanitization, postprocessing steps, defining endpoints, optimizing code for a MLaaS, creating a CI/CD plugin, modifying a CI/CD plugin, and/or compiling etc. It may include implementing options for batched and/or online inference. Models may be provided to a deployment and or monitoring 1830 module, and/or any other module for further usage.

18.6) Deployment and/or Monitoring

One or more AI systems may be deployed and or monitored 1830 using the injected monitoring mechanisms. This step may deploy the model to (but not limited to) a GUI, web interface, embedded device, MLaaS, MLOps pipeline, CI/CD pipeline, mobile device, server, desktop, embedded device, augmented reality system, virtual reality system, automobile, robot (e.g., a robot that performs surgery), spacecraft, and/or edge device, etc. An auto-deployment mechanism handles data storage, storage of the model, and/or other related components. Before, during and/or after deployment, it may check the system for cybersecurity risks, vulnerabilities, endpoint vulnerabilities (if applicable), and/or network vulnerabilities, etc. It may handle updates to AI systems, including but not limited to, reinforcement learning updates, new versions, new updates, modifications that account for model drift, and/or deprecating the system, etc. An auto-deployment mechanism may handle the generation of a GUI, and/or API, etc., that may be used for inference. It may for example include deployment of one or more Docker containers, virtual machines, and/or Kubernetes clusters, etc. Deployment and/or monitoring may include monitoring aspects, such as (but not limited to) logging, compliance, metrics, reporting, continuous analysis, and/or continuous monitoring. If vulnerabilities are discovered, it may automatically and/or semi-automatically (using a human-in-the-loop mechanism) mitigate and/or defend the AI system(s). This may include, but is not limited to: blocking access by specific users, locations, roles, and/or IP addresses, etc.; blocking specific inputs (e.g., adversarial attacks, OOD data, etc.); shutting down one more systems; blocking access to one or more endpoints entirely; stopping a Docker container, shutting down a virtual machine; provide notifications such as email, text, alarm, instant message; provide recommendations and/or instructions; power off a device; and/or trigger an actuator (e.g., safety switch) etc.

### 19) Function of the Invention: User Interface/User Experience (Mitigation Mapping)

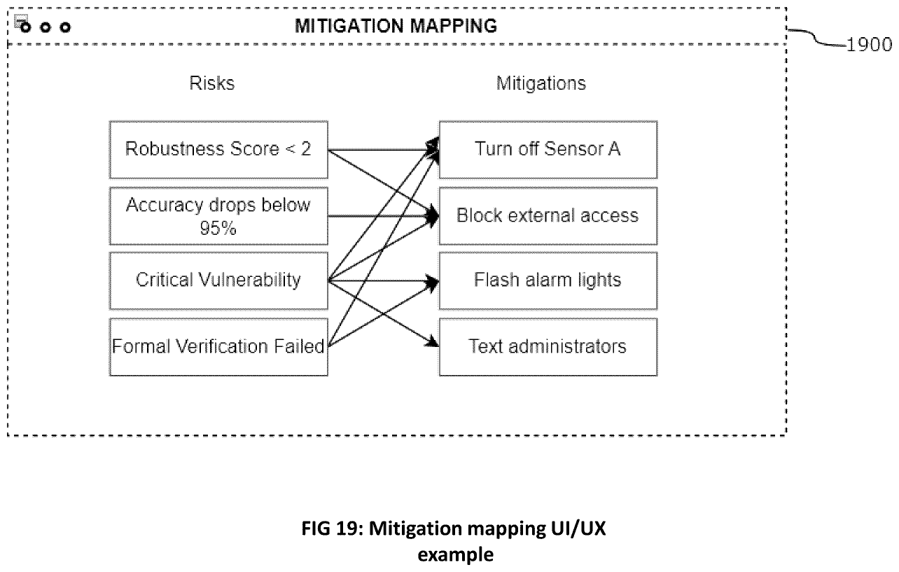

FIG. 19 illustrates an example (e.g., used in the analysis system) for a mitigation mapping UI/UX 1900. This UI/UX may be presented in several forms, such as (but not limited to) on a web interface, application interface, IDE, and/or plugin in a pipeline, etc. Risks and/or mitigations are presented to the user that may be manually, automatically, and/or semi-automatically inputted. Specific risks may be connected to one or more mitigations. This screen may show mitigations that were taken after risks and/or vulnerabilities were detected, and/or defended against.

### 20) Function of the Invention: User Interface/User Experience (Vulnerability View)

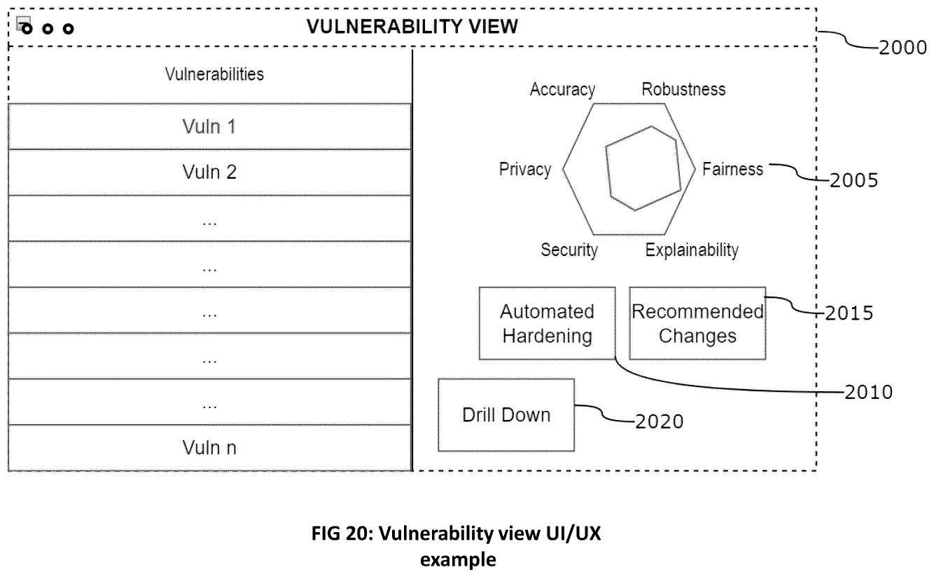

FIG. 20 illustrates an example (e.g., used in the analysis system) for viewing vulnerability results on a user interface 2000. Vulnerabilities discovered may be listed in tabular format on the left side of the page. Vulnerabilities may be selected on the left side to display deeper analysis results. For example, the diagram shows a visualization of metrics like accuracy, robustness, privacy, fairness, security, and/or explainability, with larger hexagon lines for better metric results 2005. Different metrics may be present, and/or any currently present metrics may not be displayed. There may be a button to perform automated hardening 2010 on the system to mitigate any vulnerabilities discovered. The recommended changes 2015 button may lead to, for example, a popup window, and/or a different page, etc. There it may show recommended changes that may be made to computing systems and/or AI systems to improve the model. A drill down 2020 button may be displayed which may allow users to drill down into the vulnerability results. For example, it may highlight specific weaknesses in the data and/or specific vulnerabilities etc. in the source code.

### 21) Function of the Invention: User Interface/User Experience (Surrogate Baseline)

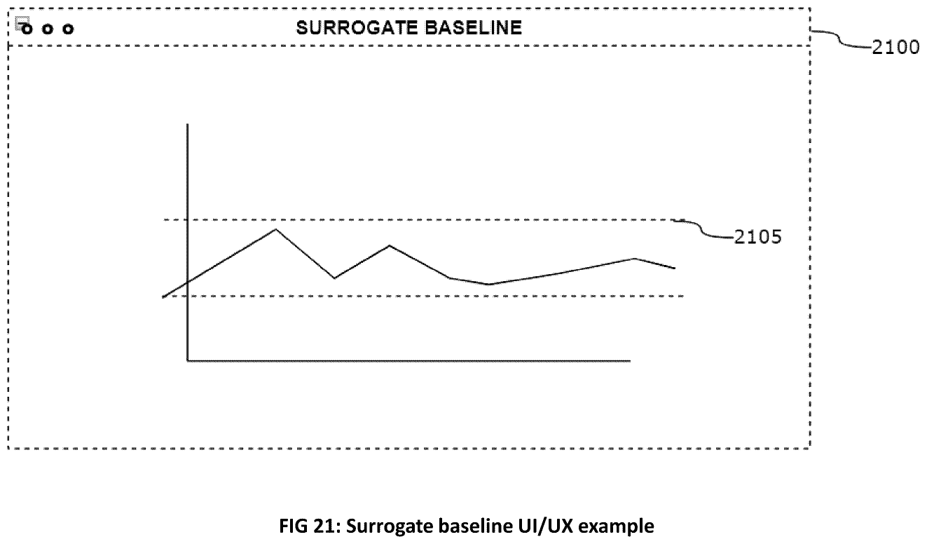

FIG. 21 illustrates an example (e.g., used in the analysis system) for a surrogate baseline UI/UX example 2100. This may be presented on a web interface, application interface, mobile device, screen, document, pipeline plugin, and/or another interface. This may be presented by graphing the results of surrogate modeling and/or changes in a surrogate model or models (e.g., over time) 2105. In the depicted UI/UX example, there are two dotted lines which represent the normal expected behavior bounds, and/or may for example illustrate deviations that go above or below those boundaries. Other graphs, charts, visualizations, and/or descriptions, etc., may be additionally and/or alternatively used to display the results of surrogate model analysis. The dotted lines may be representative of other factors, such as used for a single limit and/or to demonstrate the regions in which the data went out of bounds or contained anomalous data.

### 22) Function of the Invention: User Interface/User Experience (Surrogate Model Clustering)

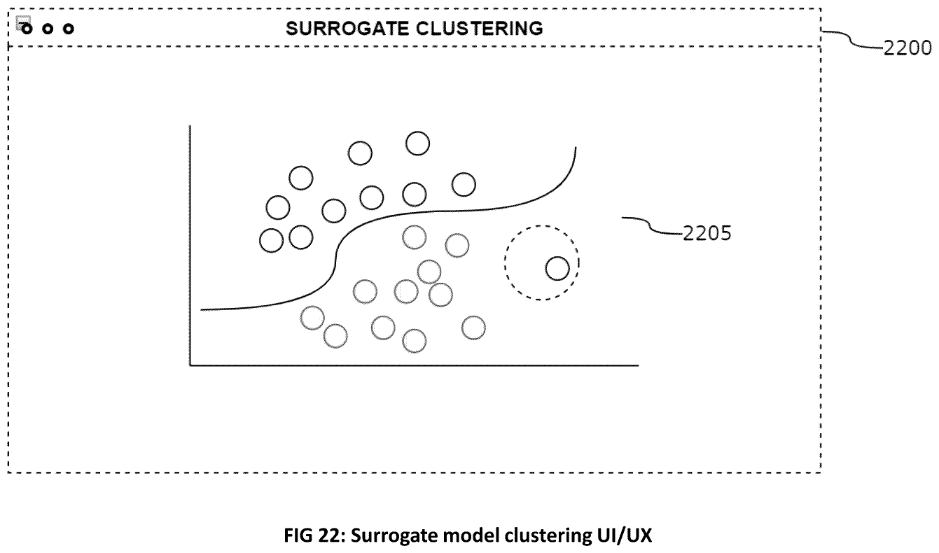

FIG. 22 illustrates an example (e.g., used in the analysis system) for surrogate model clustering in a UI/UX 2200. This may be presented on, for example, a web interface, pipeline plugin, application interface, mobile device, screen, document, tablet, and/or another interface. A graph is presented plotting out points from the surrogate model analysis. In the depicted example in FIG. 22, there is a clear distinction between different points. One set of points is denoted in white, while the other set of points is demoted in gray. This may represent two different classes in a model, such as benign vs. adversarial examples, robust vs non-robust examples, and/or following a compliance framework vs. not following a compliance framework, etc. In the depicted UI/UX example, there may be a single point that deviates from the clusters, which may be highlighted and/or presented to the user 2205. Other approaches and/or mechanisms may be used to demonstrate the results of surrogate modeling to a user, to maximize explainability and/or transparency.

### 23) Function of the Invention: User Interface/User Experience (Automated Training Selection)

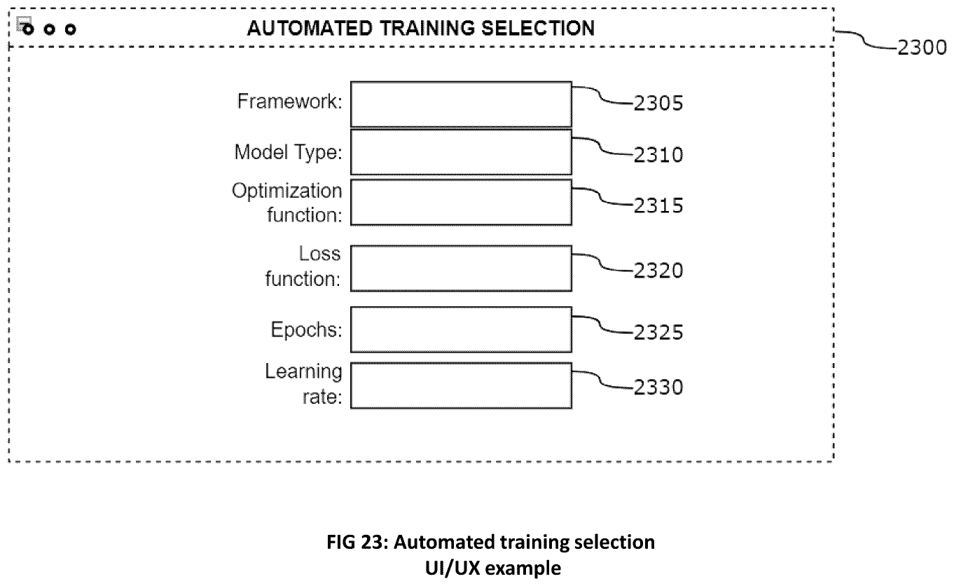

FIG. 23 illustrates an example (e.g., used in the analysis system) for an automated training selection UI/UX 2300. The diagram illustrates potential items that may be selected as targets or configurations by a user, by an automated training system, and/or through a human-in-the-loop mechanism. A human-in-the-loop mechanism may include feedback from a user on the automated training selections, and/or may provide feedback to the system prior to automated training. In the depicted example in FIG. 23, these items may include framework 2305, model type 2310, optimization function 2315, loss function 2320, epochs 2325, and/or learning rate 2330 selections. There may be other items presented on this screen, including but not limited to, batch size, optimizations, and/or model architecture evaluation metrics, etc.

### 24) Function of the Invention: User Interface/User Experience (Automated Training Heat Map)

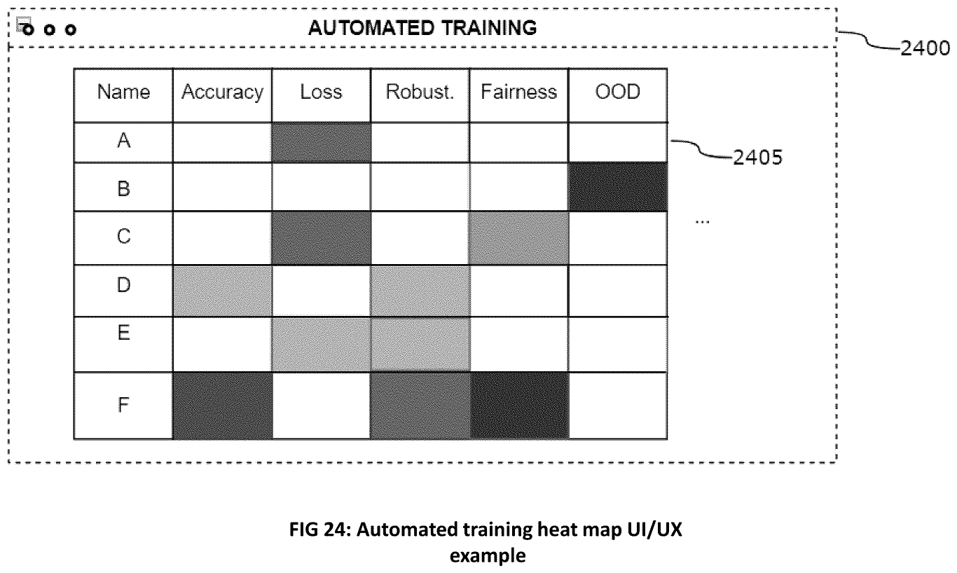

FIG. 24 illustrates the analysis system for automated training results UI/UX in a heatmap format 2400. This may be presented on, for example, a web interface, application interface, mobile device, screen, document, pipeline plugin, and/or another interface. In the depicted example in FIG. 24, this provides simple and easy-to-view results to determine the most optimal model or the rationale behind the automated training decision-making 2405. The leftmost column contains names of the models that are going to be or were developed and trained. The other columns contain a color, shade, and/or other visual indicator that may be accompanied by scoring or drilldowns into more information about the trust metric underneath each header. A sample of analysis metrics may be present. Additional columns, including for example analysis metrics, may be present, or a combination of columns, and/or others. Data may be presented in other manners than a heatmap. Heatmaps may be used for other purposes other than displaying results of automated training.

### 25) Function of the Invention: User Interface/User Experience (AI Components Monitoring)

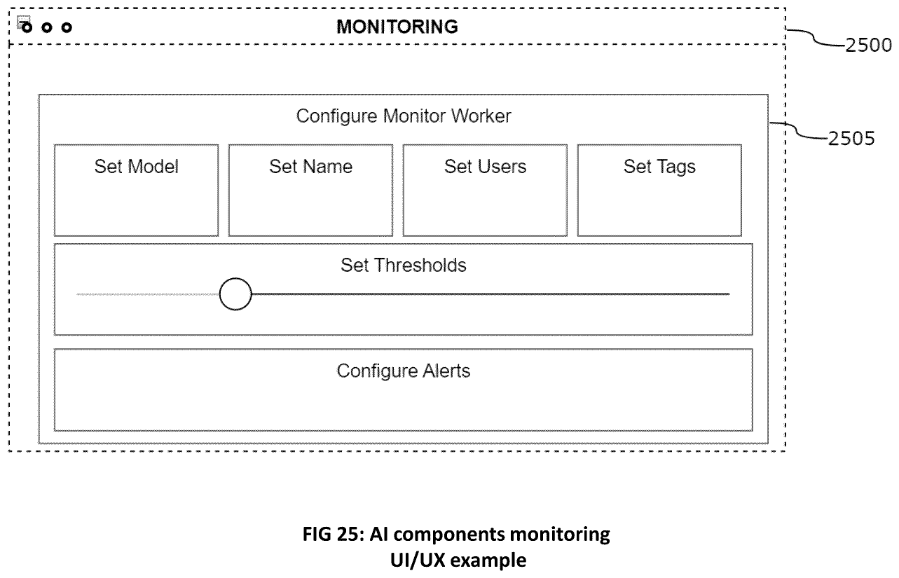

FIG. 25 illustrates an example for monitoring AI components in a UI/UX 2500 in the analysis system. This may be presented for example on a web interface, application interface, mobile device, screen, document, pipeline plugin, and/or another interface. In the depicted example, there are one or more modules for configuring monitor workers/processes 2505, wherein (e.g., automated) tasks may be configured to (e.g., continually) monitor AI components from AI systems. In the depicted example in FIG. 25, this includes, but is not limited to, determining models to analyze, naming monitor workers, defining who or what has access to a worker's results and notifications, determining user types with access to the results and notifications, adding tags associated with workers, setting thresholds that may trigger an alert or warning, such as, but not limited to, providing a notification (e.g., text message, email, and/or instant message), setting of a flashing light, emailing users, producing a report, API call, and/or a dashboard update, etc. Other options may be present. There may be different combinations of items presented to configure monitoring workers. While the depicted example shows one slider for setting thresholds, there may be multiple and/or or other ways of configuring thresholds and/or additional components to be set, such as (but not limited to) training or testing datasets, various scorings or metrics, and/or other information useful for the end user.

### 26) Function of the Invention: Adversarial Attack Generation for Adversarial Defense

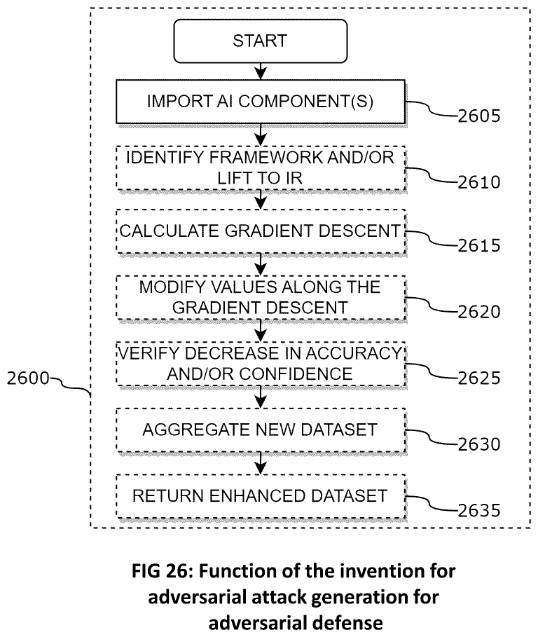

FIG. 26 illustrates analysis and mitigation 2600 in the analysis system, by generating data that contains adversarial attacks that may be used for defense and/or hardening of AI systems. Attacks may be used to attack AI systems to determine if the AI systems are susceptible to adversarial attacks. Generated adversarial samples may be used in several ways, such as (but not limited to) analysis, hardening, defense, and/or monitoring, etc. For example: adversarial attacks may be used to analyze the robustness of the AI systems; they may be used to harden existing models by injecting adversarial data for retraining or fine-tuning; they may be used (e.g., for defense) to train a surrogate model and/or train another model that detects and prevents adversarial inputs; and/or they may be generated for monitoring, wherein they are used to assess the robustness of the system over time; etc. While FIG. 26 depicts the analysis system for adversarial defense, it could be used for other purposes such as (but not limited to) attacks, and/or red teaming, etc.

### 26.1) Import AI Components

The analysis system may import AI components 2605 from one or more AI systems. If the analysis system is used for attack generation, it may include, but is not limited to, original model, weights, metadata about the internal mechanisms such as the architecture of the model, model task, source code, binaries, and/or training data, etc.

26.2) Identify Framework and/or Lift to IR

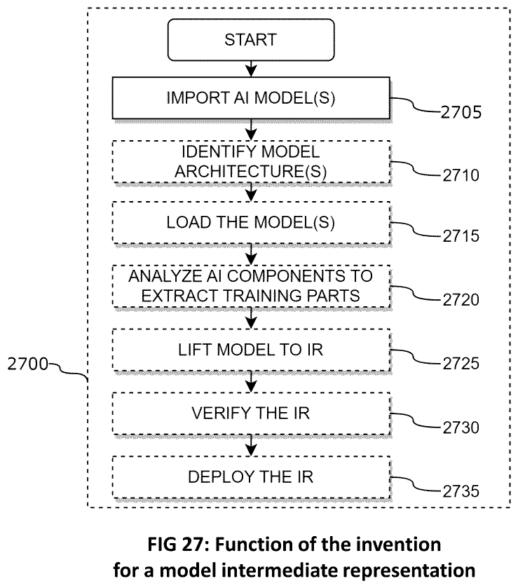

The analysis system may use an original AI framework that may be identified using a similar process to that described in FIG. 27 below, wherein the analysis system may identify the framework and or lift it to an intermediate representation (IR) 2610. In the backend of the analysis system, one or more mechanisms may be able to handle the identified framework, such as (but not limited to), mechanisms for TensorFlow, PyTorch, Keras, Caffe, Scikit-learn, and/or a combination of mechanisms (e.g., PyTorch and Keras, and/or PyTorch and Scikit-learn, etc.), etc.

### 26.3) Calculate Gradient Descent

The analysis system may calculate the gradient descent 2615 based on one or more given data points. This may involve using several different mechanisms and may depend for example on the framework (e.g., TensorFlow, Keras, and/or PyTorch, etc.), on the IR (e.g., ONNX, MLIR, DLIR, OpenVINO, and/or DistIR, etc.) etc. It may include but is not limited to mechanisms for generating the gradient descent for TensorFlow tensors, calculating the PyTorch gradient descent by calculating the loss with respect to independent variables after each iteration, and/or calculating the gradient descent in IR form, etc. Other mechanisms may be used for attack generation that may or may not involve calculating the gradient descent.

### 26.4) Modify Values Along the Gradient Descent

To modify values along the gradient descent 2620, the most variable or least stable points of the gradient descent may be calculated by the analysis system in order to determine what points of the data are most vulnerable and/or may be attacked. For example, for computer vision, a percentage of pixels may be specified that the analysis system will modify. Modifications may include changing a single, multiple, and/or all channels of the data. It may include making small changes to the pixels, such as slightly modifying the values, or completely modifying the values, such as setting them to a predefined value. One or more other criteria may be used to determine where in the data and/or along the gradient descent to attack.

26.5) Verify Decrease in Accuracy and/or Confidence

The analysis system may verify a decrease in accuracy and or confidence 2625 using the attacked data points on the model's predictions. If no changes were found, or if there was an increase in accuracy without a risk of over-fitting from the model, then a modify values along the gradient descent 2620 module may be executed again to attempt to modify the data in different ways to decrease model performance.

### 26.6) Aggregate New Dataset

The analysis system may aggregate a new dataset(s) 2630 based on modified values that may have decreased accuracy and/or confidence. Data may be sorted into their corresponding classes (e.g., automatically and/or based on input from the user), which may be in the form of a compressed format such as ZIP, RAR, and/or 7Z, etc., or file (e.g., CSV, XML, and/or JSON, etc.), file system folders, and/or text file, etc.

### 26.7) Return Enhanced Dataset

The analysis system may return an enhanced dataset 2635 in several manners, such as (but not limited to) training, retraining, monitoring, hardening, defending, and/or fine-tuning that is optimal for improving the model, such as its accuracy and/or robustness, etc. An enhanced dataset may include removed, added, and/or modified data points.

### 27) Function of the Invention: Model Intermediate Representation

FIG. 27 illustrates converting a model into an intermediate representation 2700 in the analysis system. The intermediate representation may be used in several manners, such as (but not limited to) retraining a model in a different format, analyzing a model in a different framework, translating a model, translating the source code of a model to a different framework, deploying the model, and/or converting to a common format for standardized analysis, etc. There may be multiple intermediate representation formats that may be used. For example, the analysis system may select the most optimal IR format and/or the most optimal framework to convert to, and/or convert between multiple IR formats to allow for optimal translation. One or more of the depicted modules may not be present, for example a “deploy the IR” 2735 module may not be necessary for operation.

### 27.1) Import AI Model(s)

The analysis system may import AI model(s) 2705 to convert to an intermediate representation (IR). This may include, but is not limited to, TensorFlow, Keras, PyTorch, Caffe, and/or other types of AI frameworks, and may come in any known or unknown architecture, such as Mask R-CNN, and/or Yolov5, etc. Imported AI models may perform a variety of tasks, such as but not limited to, image classification, object detection, semantic segmentation, text classification, sentiment analysis, anomaly detection, speech-to-text, tabular classification, and/or linear regression, etc.

### 27.2) Identify Model Architecture(s)

The analysis system may identify model architecture(s) 2710, including, but not limited to, frameworks, configurations, and/or layers, etc., by analyzing one or more AI models. This may include using source code analysis to determine variables, functions, and/or classes, etc., that are used for training, inference, and/or other AI/ML related tasks. It may be used to determine information that may be used in downstream steps for the intermediate representation generation.

### 27.3) Load the Model(s)

The analysis system may load the model(s) 2715 in order to translate them into an intermediate representation. Models and their related components, such as (but not limited to), source code, binaries, configuration files, weights, logs, and/or other data, are parsed and/or managed in the analysis system.

### 27.4) Analyze AI Components to Extract Training Parts

The analysis system may analyze AI components to extract training parts 2720. Aspects related to the AI components provided may be analyzed, such as (but not limited to) training components like the loss function, optimization function, activation function, epochs, and/or other training-related data that may need to be lifted to an intermediate representation.

### 27.5) Lift Model to IR

The analysis system may lift the model to IR 2725, which involves the lifting to an intermediate representation and stores related components and information, such as for training the model. This format may standardize multiple AI frameworks and/or AI models (that may be in an unknown format) into a singular consistent format that may then be used, for example, to translate to other frameworks, other intermediate representations, deploy the model, optimize the model, compress the model, and/or retrain the model, etc.

### 27.6) Verify the IR

The analysis system may verify the IR 2730. The intermediate representation may be validated by analyzing aspects of the original model and the new IR model. For example, this may include running sample data through inference of both models and/or comparing to ensure the results are identical or nearly identical. It may include analyzing individual layers, or analyzing the model during training. It may include analyzing the behavior of different defined functions, etc.

### 27.7) Deploy the IR

The analysis system may deploy the IR 2735, for example by using a mechanism similar to auto-deployment previously described. IR models may be optimized for example for a specific production system or pipeline, and/or for a specific analysis metric (such as robustness), etc. This may include compressing the model or compiling it to run on different architectures.

### 28) Function of the Invention: Generating a Corpus of AI Code Segments

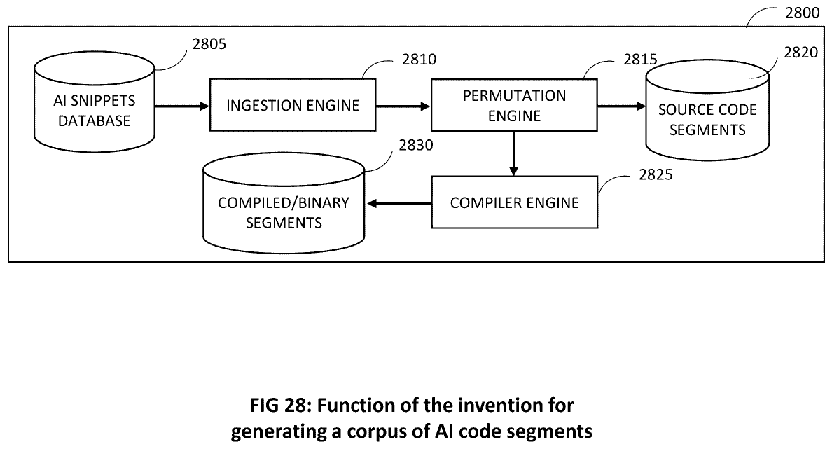

FIG. 28 illustrates generating a corpus of AI code segments 2800 in the analysis system. Code segments may be generated in many formats. For example, this may include, but is not limited to, generating code segments for a single source code language (e.g., Python, Java, C++, and/or C #, etc.), generating code segments across multiple languages, generating code segments in binary form, generating code segments in source code and binary forms, generating code segments in JIT intermediate code, and/or generating code segments with hardware acceleration, etc. For a single code segment, there may be (potentially numerous) variations generated. For example, minor modifications may be made to the architecture to generate different models and/or different binaries, potentially in compiled for different languages or machines, including but not limited to, x86, ARM, RISC-V, and/or JVM byte code, etc. While in the depicted example, corpuses generated are for source code segments and compiled and binary segments, other corpuses may be generated by the analysis system. The objectives of corpus generation may vary, including but not limited to, use in other analyses of the analysis system (e.g., rules-based analysis, and/or AI-based analyses etc.), use in source code analysis, use in similarity analysis, and/or use in reverse engineering, etc. Each corpus may be used for one and/or multiple analyses. Corpuses may be provided back to the user. Modules may be ordered differently from the ones depicted, and/or depicted modules may be present or absent.

### 28.1) AI Snippets Database

In the analysis system, there may be an AI snippets database 2805 that contains snippets, components, or parts of AI. AI snippets may be in various formats at various levels of abstraction, such as compiled formats, binary, machine code, FPGA bitstreams, assembly code, and/or source code, etc. Source code may be in several forms, such as (but not limited to) Python, Java, C, C #, C++, JavaScript, Go, and/or Verilog etc., and/or a combination of multiple languages. Data may be retrieved and/or received by the AI snippets database in many different ways. For example, these ways may include, but are not limited to, scanning open-source repositories from sources such as, but not limited to, GitHub, GitLab, and/or Bitbucket, etc., scanning for code snippets on sources such as Reddit, and/or Stack Overflow, etc., generating samples using an LLM, through a CI/CD plugin, scanning file system(s) for AI code, analyzing documentation and examples from common AI frameworks, fetching samples from an API, and/or receiving sample AI snippets from users (e.g., through an API, CLI, and/or GUI, etc.), etc. Within the database, snippets may contain metadata, such as (but not limited to) the date provided, the version of the framework, other libraries used, what function the code snippet contains, who provided them, and/or the origin, etc. They may be hashed and/or compressed for easy retrieval and storage.

### 28.2) Ingestion Engine

The analysis system may include an ingestion engine 2810 that may be used to detect the type of AI snippet code. It may load and/or execute the code snippets. It may combine multiple code snippets into a single script or pipeline. The ingestion engine may contain several modules, such as (but not limited to) loading code, executing code (e.g., in different programming languages), decompiling, and/or disassembling binaries, etc. It may include modules for converting different AI code snippets to an intermediate representation. It may contain modules for compiling and/or compressing AI code snippets.

### 28.3) Permutation Engine

The analysis system may include a permutation engine 2815 that generates permutations of code snippets. For example, this may include, but is not limited to: iterating through the source code and making minor modifications to the source code and saving each separately; lifting AI snippets to an intermediate representation and make permutations of source code in the IR version; converting the code snippets to different programming languages and/or store those modified permutations in the source code segments databases; etc. Examples of modifications include, but are not limited to, making modifications to the existing layers of a model, changing the forward and backward functions, reordering lines of code, modifying the loss function, modifying the activation function, modifying the optimization function, modifying the tensors, modifying the dimensions of tensors, modifying the inputs and outputs of one or multiple layer(s), and/or changing the architecture of the model, etc.

### 28.4) Source Code Segments

The analysis system may include original and permutated code segments that are stored in a source code segments 2820 database. This database may include metadata, such as (but not limited to) the language, version numbers of libraries used, and/or dates, etc. Source code segments may be used in a variety of analyses, for example (but not limited to), they may be used for: vulnerability analysis where each segment is assessed for vulnerabilities; similarity analysis to determine similar code segments that may be vulnerable; and/or testing the overall analysis system etc.

### 28.5) Compiler Engine

The analysis system may include a compiler engine 2825 that takes the permutations of code segments from the permutation engine and may compile them down into one or more formats and for one or more architectures. For example, formats may include, but are not limited to, serialized formats, binary formats, assembly code, machine executable code, JIT compiled byte code, compiled model formats, and/or C, etc. Example architectures include, but are not limited to, x86, ARC, ARM32, ARM64, Blackfin, MIPS, MMIX, RISC, Mico32, PowerPC, RISC-V, and/or SPARC, etc. The results of this engine may feed into one and/or more database, such as one for assembly and/or one for binary.

28.6) Compiled and/or Binary Segments

The analysis system may include compiled permutated code segments from a compiler engine 2825 that are stored in a compiled and or binary segments 2830 database. This may include, but is not limited to, a MySQL database, MongoDB database, file storage, Cloud data bucket, and/or a NoSQL database, etc., a file or directory of files containing data in suitable data format(s) such as JSON, XML, and/or CSV, etc. This database includes, but is not limited to, metadata with the compiled and/or binary segments.

### 29) Function of the Invention: AI Source Code Analysis

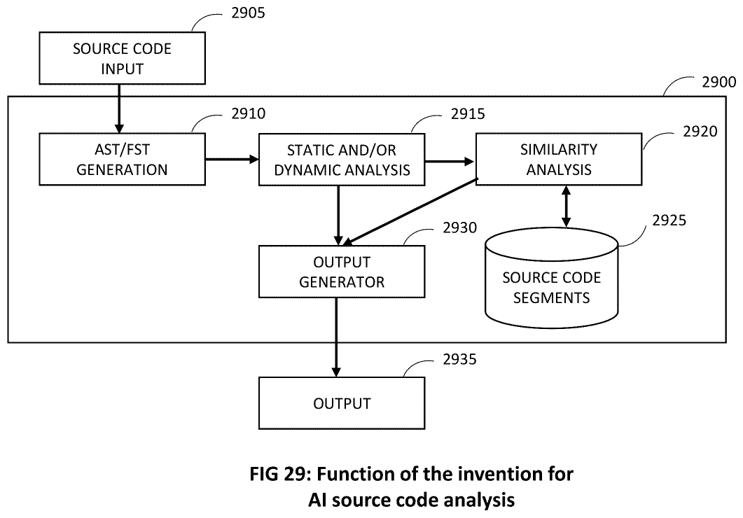

FIG. 29 illustrates source code analysis of AI systems 2900 in the analysis system. The analysis performed by the analysis system may be source code analysis. This may be used for various purposes, including but not limited to, finding vulnerabilities in AI source code, hardening aspects of source code, injecting monitoring, hardening, and/or defense mechanisms, extracting model architectures and/or other information about inner mechanisms of the model, extracting weights, extracting training information, and/or extracting the purpose of an AI model, etc. Source code analysis techniques may include, but are not limited to, static analysis, dynamic analysis, similarity analysis, semantic analysis, etc.

### 29.1) Source Code Input

The analysis system may include source code input 2905 that may be used for source code analysis. This may include source code for one or more programming languages. Programming languages may include, but are not limited to, Python, Java, JavaScript, C++, C, C #, Go, Ruby, Swift, PHP, Verilog, Rust, Scala, and/or Kotlin, etc. Source code may be paired with other AI components, such as but not limited to, data, dependencies, models, weights, and/or configurations, etc. Source code may be provided as a single script and/or multiple. It may include multiple programming languages.

### 29.2) Abstract Syntax Trees (AST)/Full Syntax Trees (FST) Generation

The source code input 2905 may be parsed by the analysis system, including for example AST/FST generation 2910 for analyzing code that may be analyzed and parsed. Other (e.g., external) mechanisms and tools may be used for breaking down the code. The analysis system may generate a control flow graph (CFG) that may be analyzed by the system.

29.3) Static and/or Dynamic Analysis

The analysis system may include analyzing source code using (one or both of) static and or dynamic analysis 2915, and/or other suitable source code analysis techniques. This may be implemented using for example, but not limited to, source code analysis tools, static analysis tools such as Ghidra, and/or IDA, etc., dynamic analysis tools such as OllyDbg, and/or Apktool, etc. It may include a pipeline of analyses that run over the code to extract AI frameworks and components used. It may include weakness and vulnerability analysis in the source code. For example, there may be vulnerabilities within the model architectures and/or in specific AI libraries used.

### 29.4) Similarity Analysis

The analysis system may include similarity analysis 2920 that may be used to determine if AI code segments are similar to past known code segments that may be (or may have been) determined to be vulnerable or not vulnerable. Various techniques may be used for similarity analysis, such as (but not limited to) rules-based, AI-based, heuristics-based, and/or index based (e.g., Sørensen-Dice coefficient, cosine coefficient, Soergel distance, Euclidean distance, and/or Hamming distance, etc.), etc. Such similarity analysis may result in similarity scores between multiple code segments and may include (if known) the likelihood that the code segment may be vulnerable (e.g., based on past results).

The analysis system may include AI-based similarity analysis may be used to detect similar AI code segments. Tools such as trex, SAFE, Genius, Gemini, Asm2Vec, and/or DeepBinDiff, etc., may be used. Code segments may be used in their source code formats, or they may be translated to other formats, such as (but not limited to), binary, assembly, JIT, machine code, and/or FPGA bitstreams, etc. They may be sed with an existing AI-based tool such as those listed above or others, retrain an existing AI-based tool by including new data from the analysis system, and/or training a new AI-based tool for similarity analysis of code segments.

### 29.5) Source Code Segments

The analysis system may include source code segments 2925 that are contained in one or more data store that may be used in similarity analysis 2920. Code segments may be from (but are not limited to) online sources (and may be already categorized in those sources), from the analysis system's database generation tool, defined by a user, and/or from past analysis results, etc.

### 29.6) Output Generator

The analysis system may include output of source code analysis that may be generated in the output generator 2930. This may include one single output or a combination of multiple outputs. Outputs may be returned to the user, to other modules within the analysis system (e.g., used to determine vulnerabilities to harden or defend against), and/or used for other purposes, etc. Outputs may include, but are not limited to, one or more of alert, text message, instant message, document, a detailed report, a scorecard, visualization of vulnerable code segment, similarity score, vulnerability score, and/or hardened source code segment, etc.

### 29.7) Output

This module represents the produced output 2935. This may include many different outputs from the output generator, or a single output. Outputs may take various forms, including but not limited to source code related to the source code input, results from the internal analysis, information about the source code input such as model task, weights, and/or architecture, etc., and/or reports or data about the analysis such as the similarity analysis, and/or how similar or related the input is to internally known source code segments, etc. Outputs may take a form that may include but is not limited to one or more alerts, alarms, text messages, instant message, a detailed report, a scorecard, visualizations of vulnerable code segments, similarity scores, vulnerability scores, and/or hardened source code segments, etc.

30) Function of the Invention: Model Drift Attack and/or Analysis

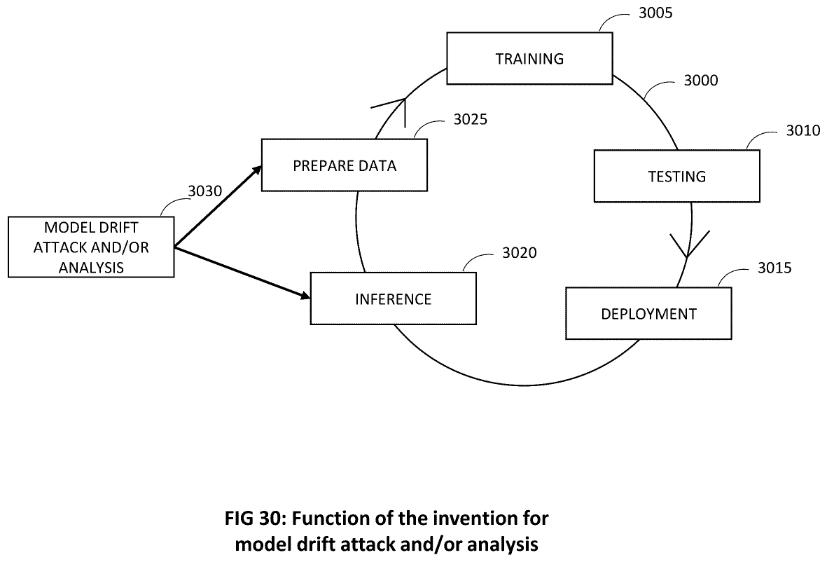

FIG. 30 illustrates the analysis system, wherein an action taken by the analysis system may for example be (in the depicted example) model drift analysis 3000. The diagram depicts potential stages of an AI lifecycle or pipeline for continuously improving a model, e.g., of systems that rely on continuous improvement and/or retraining may be more prone to adversarial attacks. For example, adversarial data may be introduced into inference data to create adversarial patterns in the data, which might then be included during retraining, and/or may be introduced during the stage where data is being prepared for training, etc. Adversarial data may be introduced at other stages. This may be done (e.g., by attackers), for example, to introduce biases, cause model drift, add backdoors, and/or lower the accuracy of the model, etc.

### 30.1) Training

This stage in an AI lifecycle may include training 3005 one or more AI systems. This may be an automated process, such as using automated training mechanism, semi-automated, and/or a manual process wherein a user for example runs a script to train a model. During this stage, data may be taken from the prepare data stage that is preprocessed, normalized, and/or optimal for training. A model may be trained based on that data or subsets of data. Trained models may be provided to testing 3010.

### 30.2) Testing

A testing stage may involve analyzing and testing 3010 trained models to ensure for example the accuracy, robustness, and/or other metrics of the model meet requirements and expectations. During testing, data used for assessing the quality of the model may be used for inference, and/or metrics may be calculated based on how well the model performs. This stage may include analysis and hardening (e.g., from the analysis system).

### 30.3) Deployment

The analysis system may include a deployment 3015 stage that may involve deploying models that have been successfully tested and are ready to be deployed. This may involve auto-deployment from the analysis system. Deployment may include generating APIs for interacting with the AI system, compiling and/or compressing the model for a specific device, etc.

### 30.4) Inference

The analysis system may include an inference 3020 stage that may involve utilizing deployed models to make predictions. Data may be fed to the model to use AI to analyze the inputs. Data used during inference may be used to improve the model over time, thus this data may make the model potentially vulnerable to being attacked with malicious data.

### 30.5) Prepare Data

The analysis system may include prepared data 3025 that may be used for training or retraining. Preparing data may be done before training, and it may come before each cycle before retraining. Data may be preprocessed, and/or normalized, etc., before training. Data may be new data added to the system and/or may come from inference for continual improvement of the system. Any new data introduced in this stage may potentially be susceptible to attacks through malicious data injection. Data may take forms such as photo, video, tabular, audio, non-tabular, and/or any other form of data that may be used to train an AI system.

30.6) Model Drift Attack and/or Analysis

The analysis performed by the analysis system may be model drift attack and or analysis 3030. This analysis may assess how susceptible the AI system is to a model drift attack. This may be achieved, for example, by injecting data into the dataset during data preparation or during inference of the model. Through this, the analysis system may analyze how much of an impact it can have on the model itself. The objectives of such analysis (incl. attacking) may vary and include for example (but not limited to): lowering the accuracy, lowering the confidence, lowering the quality of explanations, injecting biases, and/or lowering adversarial robustness, etc. In the example depicted in FIG. 30, analysis may be done on the inference and prepare data stages, but it may be performed at other stages (that may or may not be present in the depicted example).

### 31) Function of the Invention: Continuous Monitoring of Vulnerabilities in AI Systems

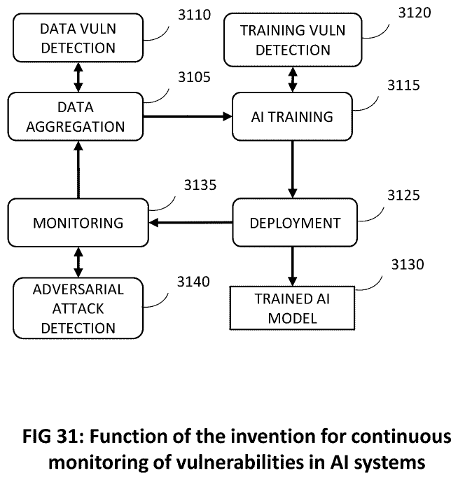

FIG. 31 depicts the analysis system for continuously monitoring and assessing an AI system for vulnerabilities during any stage of development and deployment of an AI system. In the depicted example, the analysis system operates in a circular manner, wherein the AI system may be continuously improved upon (e.g., during training, deployment, and monitoring). During each phase of the AI lifecycle, different analyses (in the analysis system) may assess the AI system and AI components. The analysis system depicted in FIG. 31 may include vulnerability analysis. Analyses may include, but are not limited to, robustness, accuracy, bias, safety, and/or privacy, etc.

Data may be aggregated from one or more sources, such as (but not limited to), computing systems, AI systems, sensors, databases, and/or Internet sources, etc. Data may be analyzed for vulnerabilities, for example to ensure the data being used for training, testing, validating, and/or inferencing, etc., is secure. The analysis system may include, but is not limited to, vulnerability analysis during training, which may detect (and potentially anticipate) potential training vulnerabilities for AI systems and/or datasets. The analysis system may include, but is not limited to, an adversarial attack module that detects during a monitoring stage if incoming data is likely to be an adversarial attack. The analysis system may test the AI model before a deployment stage of the AI lifecycle to ensure it meets requirements (e.g., is safe for deployment).

### 31.1) Data Aggregation

The analysis system may include a data aggregation 3105 module that may aggregate and combine data in an optimal way for AI training. Aggregated data may include, but is not limited to, scraping web sources, data from a file system, and/or data provided to the analysis system, etc. Data aggregation may take various forms, including but not limited to, a program or software that combines data to be used for AI training, a mechanism for acquiring samples from reinforcement training and/or any other form of training an AI system, and/or server that takes in input data, etc.

### 31.2) Data Vulnerability Detection

The analysis system may include a data vulnerability detection 3110 module that detects vulnerabilities in training data, and may provide feedback if there are any vulnerabilities, where in the data they are located etc. For example, this may include detecting a poisoning attack such as a backdoor attack. It may detect that there are not enough samples or not enough variability in the data. The data vulnerability detection 3110 module may report vulnerabilities back to the data aggregation 3105 module and/or may return vulnerability analysis results in other ways, such as but not limited to, the user, API, and/or GUI, etc.

### 31.3) AI Training

The analysis system may include an AI training 3115 module that carries out training and/or testing an AI system. The module acquires AI components and related data from a data aggregation 3105 module. The AI training 3115 module may provide the trained model to a deployment 3125 module, e.g., once training is completed. During training, data may be shared continuously with a training vulnerability detection 3120 module. This module may include, but is not limited to, functions that can train AI systems, a server that takes in a dataset and model and trains the model, a series of programs that can train an AI model on a local computer, automated training in the analysis system, and/or any other mechanism of training an AI system.

### 31.4) Training Vulnerability Detection

The analysis system may include a training vulnerability detection 3120 module that detects vulnerabilities during AI training 3115. This may include, but is not limited to, analyzing intermediate results of the model, analyzing training data as it is being read into the analysis system, detecting poisoning attacks, low quality explanations, detecting biases, analyzing the model for overfitting and/or underfitting, etc. this module may identify and/or make mitigations, such as adding noise to training data.

### 31.5) Deployment

The analysis system may include a deployment 3125 module that represents a stage in the AI lifecycle wherein one or more models from, for example, AI training 3115 may be prepared for deployment in a production environment. This module may include, but is not limited to, auto-deployment by the analysis system, a deployment stage in a pipeline (e.g., CI/CD, MLOps, and/or MLaaS, etc.), compiling models, converting models to IR, compressing models, and/or optimizing models, etc. The deployment 3125 stage may include common software used for deploying ML systems, including but not limited to Amazon SageMaker, Docker, and/or Cortex etc.

### 31.6) Trained AI Model

The analysis system may include a trained AI model 3130 that may be an output of the AI lifecycle. the AI model may include other AI components, such as (but not limited to), trained model and weights files, a compiled model, binary files, bytecode, and/or a CI/CD plugin, etc. Outputs may include, but are not limited to, compliance reports, supporting documentation for compliance and/or assurance etc., a scorecard of model performance related to various metrics, analysis results, logs of modifications made to the model and/or its data, etc.

### 31.7) Monitoring

The analysis system may include a monitoring 3135 module that analyzes the AI system, for example after deployment 3125. This may include, but is not limited to, detecting vulnerabilities, adversarial attacks, model drift, decreases in accuracy, confidence, robustness, and/or other evaluation metrics. This module may ingest and generate logs, reports, and/or metrics, etc., to assess the health of the model over time. It may include, but is not limited to, providing alerts, notifications, text messages, and/or emails, etc., to users about the health and/or performance of their models.

### 31.8) Adversarial Attack Detection

The analysis system may include an adversarial attack detection 3140 module may detect and/or (e.g., automatically) remediate and/or mitigate adversarial attacks performed on AI models (e.g., live production models). The data this model receives may come from a monitoring module 3135. Adversarial attack detection may include, but is not limited to, detecting noise, detecting evasion attacks, detecting anomalous characters, words, or phrases for a text-based model, detecting physical attacks, predicting the type of attack, predicting the type of noise, detecting latency attacks for Edge devices, and/or detecting OOD data, etc. This module may quarantine adversarial data and/or prevent further downstream actions. It may provide results to the monitoring module for hardening and/or defense.

### 32) Function of the Invention: Analyzing Containers for AI Systems

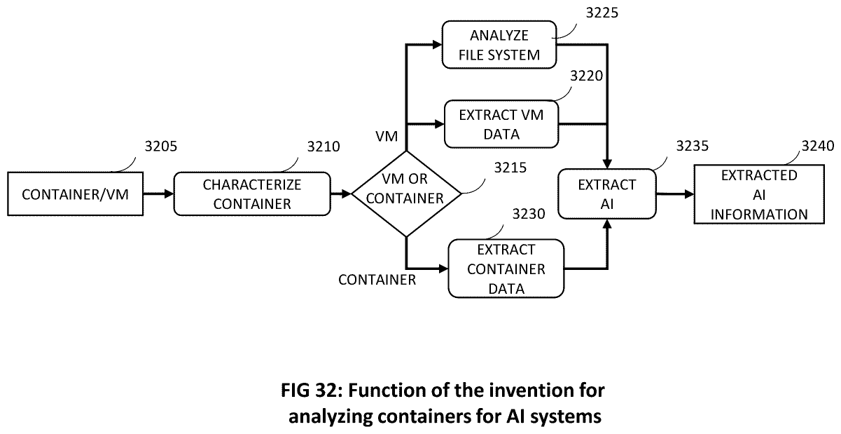

FIG. 32 depicts the analysis system for extracting and reversing AI components from containers and/or virtual machines (VM). the container and/or VM may be ingested by the analysis system and AI components are extracted, such as (but not limited to) analyzing files on the file system, reversing binaries and extracting AI components, detecting installed AI dependencies, analyzing AI dependency versions and metadata, etc. This may be implemented for example as a program running on a Cloud service as software-as-a-service, a program running on a localized computer reading and taking in the inputted container or VM, a program running on a computer server that may be accessed via API, a plugin for an existing VM application (e.g., VirtualBox, and/or VMware, etc.), etc. Only one of a VM and/or a container may be analyzed, thus not all parts depicted in FIG. 32 may be present.

32.1) Container and/or VM

The analysis system may include containers and or VMs 3205 that may form a possible input into the analysis system. this may take several forms, including but not limited to, VM instances currently running on a system that may be manipulated via an API, VM files, VM hard disk files, and/or any other data related to containers or VMs that may or may not contain AI information, and/or other information pertaining to containers or VMs. Containers and VMs may include, but are not limited to, Docker, Hyper-V, Kubernetes, RunC, Canonical MicroK8s, Apache Mesos, OpenVZ, Cloud Foundry, CoreOS rkt, VirtualBox, and/or Vagrant, etc.

### 32.2) Characterize Container

The analysis system may include a characterize container 3210 module characterizes the container and or VM 3205 input that is provided to the analysis system. This may involve determining whether the input is a container or VM, and/or a combination of both. It may determine the actual type of container or VM and what software or tools would be needed to run it. Based on the container or VM detected, the next steps of analysis are selected, which may include analyses at various granularities, such as (but not limited to) for all VMs and containers, for only containers, for only VMs, for specific types of containers, and/or for specific types of VMs, etc.

### 32.3) VM or Container

The analysis system may include a VM or container 3215 module that determines whether an input is a VM or container. It receives this information from a characterize container 3210 module, and then passes the container or VM to the appropriate modules, depending on what form the input takes. If a characterize container 3210 module characterizes the input as a VM, it may provide the VM to an extract VM data 3220 module and an analyze file system 3225 module. If it characterizes the received data as a container, it may provide the container data to an extract container data 3230 module.

### 32.4) Extract VM Data

The analysis system may include an extract VM data 3220 module that extracts AI components from a VM, using techniques known to those skilled in the art. Analyses for VMs may include, but are not limited to, source code analysis, reverse engineering binary analysis, file system analysis, and/or package analysis, etc. AI components extracted may include, but are not limited to, source code, binaries, JIT, bytecode, machine code, assembly code, model files, data (e.g., training, validation, testing, and/or inference, etc.), and/or weights, etc. Virtual Machines may be running a variety of operating systems, including but not limited to MacOS, Windows (e.g., NT 4.0, 2000, XP, Server 2003, Windows Server 2012, Windows Server 2016, Windows Server 2019, Vista, Windows 7, Windows 8, and/or Windows 10, etc.), Linux (e.g., Ubuntu, Debian, CentOS, RHEL, Fedora, Arch Linux, and/or Rocky Linux, etc.), Solaris, and/or OpenBSD, etc. This may be implemented by conducting techniques including, but not limited to, running the VM, using reverse engineering technology, and/or using VM introspection, etc., to extract information from the VM, probing the VM using an API while connected to a remote service, and/or any other form of extracting VM data.

### 32.5) Analyze File System

The analysis system may include an analyze file system 3225 module that analyzes a given file system to extract AI components. This module may handle a variety of inputs, such as a directory tree, file system, CLI prompt results, etc. This may include, but is not limited to, testing to see if data represents a file system, running the file system through known VM software, using file crawling software that can understand and read the files, etc. Files may be in many forms, including but not limited to directories, compressed and/or archived data files such as ZIP, RAR, 7Z and/or other compressed and/or archiving data formats, known formatted disk information such as ISO files, and/or other file information or files that may contain directory information from a VM.

### 32.6) Extract Container Data

The analysis system may include an extract container data 3230 module that extracts and analyzes AI components from a container using one or more techniques. This module, which may be similar to the extract VM data 3220 module, contains extraction and analysis techniques specific to containerized environments. For example, for a Docker container, this may include (but is not limited to): scripts for running and/or using “exec”, and/or for running commands in a container, etc.; mounting or injecting one or more scripts to scan the file system of a container and return any AI components; and/or using protocols, including but not limited to FTP, SFTP, and/or SSH, etc., etc.

### 32.7) Extract AI

The analysis system may include an extract AI 3235 module that extracts individual AI components from an AI system. For example, if it has access to a directory containing data, it may extract and organize data based on, for example, the class, type of data, and/or format of data, etc. It may detect and/or separate out other types of AI components, including but not limited to, model files, architecture files, functions or programs related to operating, training, testing, optimizing, and/or using AI. Datasets extracted may include, but are not limited to, images, videos, text, audio, tabular, and/or other types of data.

### 32.8) Extracted AI Information

The analysis system may include extracted AI information 3240 that represents output of an of the analysis system depicted in FIG. 32 for analyzing containers and VMs. This may include, but is not limited to, AI components, a report of detected AI, a bill of materials of AI components, a list of directory and file paths to AI components, reversed AI components, and/or source code segments, etc. Such output may then be used by the analysis system (or elsewhere), for example for (but not limited to) source code analysis, adversarial attack analysis, and/or bias analysis, etc.

### 33) Function of the Invention: Performing Analysis on AI Inputs and Generating Output

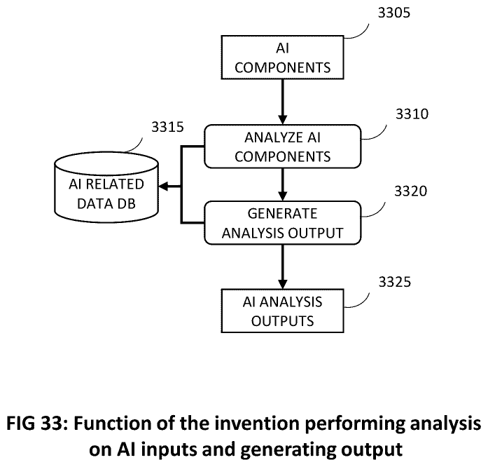

FIG. 33 depicts the analysis system for analyzing one or more AI systems and generating and returning one or more outputs. It may be used for auditing and compliance purposes, such as (but not limited to) generating a report of frameworks, models, data sources, and/or licenses, used in AI systems under analysis, etc. it may include, but is not limited to, a detailed report of vulnerabilities, an AI scorecard, a report of the history of data used in AI systems, supporting evidence (for example for meeting current and/or future legal, regulatory, compliance and/or assurance needs, and/or for legal action/defense) etc. A potential benefit may be to produce evidence about AI systems at times when requirements about AI systems (e.g., legal, regulatory, compliance, and/or assurance, etc.) are unclear and/or in flux, but there may be a need in the future to produce documentation. This may be implemented in a variety of manners, including but not limited to a cloud-based software-as-a-service (SaaS) platform, cloud computing devices, a program or piece of discrete software that, via a processor, generates analysis on AI inputs, a virtual machine (VM) stored on physical media that generates and stores AI analysis, and/or other mechanisms of generating, storing, and/or outputting analysis results.

### 33.1) AI Components

The analysis system may include AI components 3305 that include inputs to the analysis system. AI components may come from one or more AI system, and those AI systems may be on one or more computing systems. This may include, but is not limited to, AI model files, weights files, datasets, binaries containing AI, etc. AI inputs may be provided to an analyze AI components 3310 module.

### 33.2) Analyze AI Components

The analysis system may include an analyze AI components 3310 module that contains one or more analyses related to assessing AI systems. This may include, but is not limited to, adversarial attack detection, analyzing for robustness, analyzing for poisoning data, analyzing for accuracy, analyzing for biases (and/or fairness), explainability analysis, noise detection, and/or ensuring compliance of datasets, etc. It may include analyzing the input and outputs of an AI model or system, characterizing the internal mechanisms of an AI model, and/or calculating similarities between AI component(s), etc. It may execute analyses sequentially, in parallel, selectively, fully, and/or partially, etc.

### 33.3) AI Related Data Database (DB)

The analysis system may include an AI related data database 3315 that stores prior information about AI components and their analysis results. This may include storing information about AI components each time a model is trained. For example, it may include, but is not limited to, archiving and storing datasets used to train a model, the model configurations, model architecture, models, code, and/or executables, etc. It may include (but is not limited to) analysis results associated with the AI components, such as calculated analysis metrics, vulnerabilities, compliance controls, other evidence, and/or documentation, etc. It may include (but is not limited to) metadata, such as data lineage, the users who trained the model, date, and/or version number, etc. The data may be stored in various manners, including but not limited to, in full, in a database, in a file system, and/or in a compressed format, etc. It may be implemented in a variety of ways, including database services hosted in on-premises and/or cloud environments, database servers hosted on local computing machines, files containing data, networked traffic communicated over the internet, and/or other mechanisms.

### 33.4) Generate Analysis Output

The analysis system may include a generate analysis output 3320 module that generates one or more outputs from analysis results. It may use analyze AI components 3310 to generate outputs. For example, generating analysis output may include, but is not limited to, normalizing analysis results, deduplicating analysis results, taking the analysis results and creating a report, outputting analysis metrics, manipulated or changed AI components, creating a scorecard, compressing analysis results, simplifying analysis results, mapping to compliance frameworks and/or laws, identifying the source of data (e.g., by reverse engineering the source, etc.), etc.

### 33.5) AI Analysis Outputs

The analysis system may include an AI analysis outputs 3325 module that includes one or more outputs of the analysis system. Outputs may include, but are not limited to, reports, compliance information, modified and/or altered versions of the AI inputs, metrics, output data, a scorecard, a modified model, a trained model, a scorecard, notifications (e.g., text, email, and/or call, etc.), analysis results, a bill of materials for AI, supporting evidence, recommendations, compliance report, data provenance report, source code, and/or executables, etc.

### 34) Function of the Invention: Detecting AI in Computing Systems

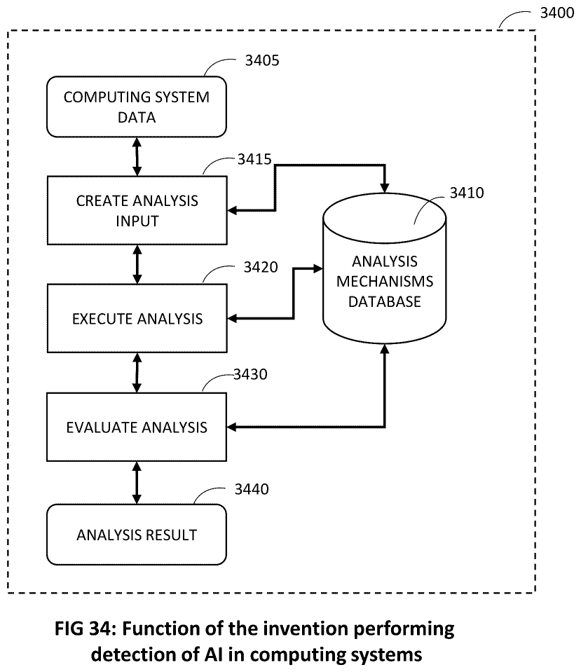

FIG. 34 depicts the analysis system 3400 for detecting whether a computing system includes AI systems or not. Detection may involve analyzing inputs, outputs, and/or behaviors, of a computing device (e.g., “black-box” analysis), while some (or all) internals of a computing system may be taken into account for the detection (“grey-box” and/or “white-box” analysis). It may for example be used by a buyer of a computing system to determine if functionality has been implemented using AI techniques or (for example, but not limited to) algorithmic, statistical, and/or probabilistic techniques. Benefits may include for example (but not limited to), for documenting supporting evidence for future legal, regulatory, and compliance needs (e.g., current/future AI laws and regulations), for determining the kind and level of testing required (e.g., acceptance testing), for determining the trustworthiness of the computing system, for determining the kinds of vulnerabilities the computing system may be susceptible to etc. Benefits may include that user(s) other than manufacturers of computing devices, for example (but not limited to) buyers of commercial-off-the-shelf devices and/or end users of the devices, may be able to detect AI being present in computing devices, allowing them to take potential further actions, such as (but not limited to) producing supporting evidence for compliance, etc. This may be implemented in a variety of manners, including but not limited to a cloud-based software-as-a-service (SaaS) platform, cloud computing devices, container, virtual machine, testing devices, portable device, and/or a program or piece of discrete software that, via a processor, generates analysis on inputs and outputs, and/or other mechanisms of generating, storing, and/or outputting analysis results.

### 34.1) Computing System Data (e.g., Inputs and Outputs)

In the analysis system, computing system data 3405 may include data related to one or more of, but not limited to: the inputs into a computing system, the outputs out of a computing system, measured behaviors of a computing system etc. Inputs include for example, but not limited to, images and/or video (e.g., collected via a camera feed, barcode reader, 3D scanner, eye gaze tracker, and/or fingerprint scanner, etc.), audio (e.g., collected via a microphone, MIDI keyboard, and/or other digital instrument, etc.), textual input (e.g., collected via keyboard, API, and/or any other ways known to one skilled in the art), sensor data (e.g., temperature, vibration, rotation, LIDAR, atmospheric pressure, acceleration, gyroscope, camera, microphone, movement, haptic, velocity, direction, motion, and/or movement, etc.). In the analysis system, computing system data 3405 may or may not include some or all of internal data stored and/or executing on a computing system, such as, but not limited to, code, binary files, scripts, stored data, etc. Computing system data 3405 may form an input into the create analysis input 3415 module.

The detection system 3400 may include a single or more than one analysis objective and/or analysis mechanism. The detection system 3400 may include a way to select one more analysis mechanisms to be executed, for example (but not limited to) based on user input, based on the nature of the computing system and/or computing system data (e.g., which analysis mechanisms work for which computing system), and/or based on the nature of the analysis objectives, etc. The detection system 3400 may include one or more outputs, such as (but not limited to) probability that the computing system includes AI, report, alarm, dashboard, API call, alarm, text, email, and/or instant message, etc.

### 34.2) Analysis Mechanisms Database

The analysis system may include an analysis mechanisms database 3410 that comprises one or more analysis mechanisms to be executed on the computing system data. Analysis mechanisms define one or more approaches of for example (but not limited to) how to create analysis inputs from computing system data, how to execute the analysis based on the created analysis inputs, how to evaluate the analysis etc. Analysis mechanisms meet one or more objectives, for example (but not limited to) detecting whether a computing system contains AI or not, whether a computing system's contained AI is trustworthy and/or vulnerable, a predicted type of AI model, whether a computing system's contained AI is compliant with laws, regulations, and/or ethics, etc.

The analysis system may include analysis mechanisms that include for example (but are not limited to) one or more of: definition of the analysis objective(s) (e.g., detecting AI, detecting vulnerable AI, and/or detecting the type of AI, etc.); mechanisms to create analysis input 3415; mechanisms to execute analysis 3420, which may depend on the analysis objectives, created analysis input the analysis evaluation; and/or mechanisms to evaluate analysis 3430, etc.

Mechanisms to create analysis input 3415 may for example include (but are not limited to) creating synthetic data or operating the computing system in particular ways to create analysis input. Analysis input data may for example be synthetically created (e.g., generated) and/or captured (e.g., from the computing system) to trigger analysis conditions, and/or may be generated by modifying computing system data 3405 to trigger analysis conditions, etc. For example, to detect whether a computing system with video/camera input recognizes particular objects staying within a particular area includes AI, synthetic data may be created to test (e.g., through gradual movement of synthetically generated data towards detection failure) whether there are clear conditions (e.g., boundaries) what the system can detect vs. not detect, etc. For example, analysis input may be modified to include: cases that are physically impossible (which may still be detected by AI, but maybe not by human-programmed algorithms) such as “flying” persons or “ghosts”, gradual; cases where output is classified along a clean/clear demarcation line (vs. possible blurry “grey area” lines between classifications using AI such as deep learning); and/or cases with outliers that indicate an AI system (and/or algorithmic) system have been fooled; applying adversarial attacks on AI that, if successful, would indicate AI is used. Mechanisms to execute analysis 3420 and evaluate analysis 3430 may for example include running the analysis input through the computing system (or a simulated/emulated system, as described below), and analyzing outputs and/or behaviors of the computing system, as described above.

Analysis mechanisms to create analysis input 3415 may include for example (but are not limited to) mechanisms to simulate/emulate the computing system, and/or through the use of surrogate modeling. To create an analysis input and execute the analysis, this may include creating a surrogate model, for example by collecting computing system inputs and outputs as labeled data, and confirming (e.g., through testing) that the surrogate model's behavior is appropriately similar or identical (e.g., in terms of producing outputs from inputs) to the computing system's behavior. Mechanism to execute analysis 3420 and evaluate analysis 3430 may for example (but not limited to) include determining characteristics of the surrogate model, such as mathematical and/or algorithmic complexity, and evaluating if the complexity is very low (indicating a potentially simple algorithm) or very high indicating that only (for example) a deep learning AI system could produce the observed outputs. For example, if the surrogate model produces identical outputs for inputs as the computing system, and has a very low complexity (e.g., mathematical formula, algorithm, etc.), there is an increased probability that the computing system does not use certain AI (e.g., deep learning) to determine outputs from inputs. If the complexity is high, or the surrogate model is not able to behave appropriately similar (e.g., due to high complexity), there is an increased probability that the computing system does use certain AI (e.g., deep learning) to determine outputs from inputs.

### 34.3) Create Analysis Input

The analysis system may include a create analysis input 3415 module that produces input data to support one or more analyses to be executed, including (but not limited to) capturing computing system data 3405 from a computing system or other sources, modifying captured data, synthetically creating data, searching online data, using NLP to analyze (e.g., from manuals and documentation) types of inputs a device takes in, and/or using a corpus of data, etc.

### 34.4) Execute Analysis

The analysis system may include an execute analysis 3420 module that executes one or more analysis mechanisms on the analysis input provided by a create analysis input 3415 module, such as for example (but not limited to) running data through a computing system and/or a simulation/emulation of a computing system (e.g., rehosted computing system, surrogate model, and capturing the output. Examples of outputs include (but are not limited) detection of objects leaving boundaries in camera systems, etc. Output from an execute analysis 3420 module may be provided to an evaluate analysis 3430 module.

### 34.5) Evaluate Analysis

The analysis system may include an evaluate analysis 3430 module that evaluates whether outputs from an execute analysis 3420 module indicate one or more result based on one or more objective associated with analysis mechanisms executed. Evaluating an analysis may for example include (but is not limited to): determining the complexity of a surrogate model is below or above a threshold indicating the computing system uses algorithmic vs. AI models, respectively; determining particular algorithmic classification boundaries indicating algorithmic vs. AI models, such as clear vs. gradual classification failures, outliers, anomalies etc.; and/or determining AI specific adversarial attack examples were successful, thus indicating AI is included in the computing system; etc.

### 34.6) Analysis Result

Analysis result(s) 3440 in the analysis system may include results based on one or more objectives associated with analysis mechanisms executed, including for example (but not limited to) the probability that a computing device uses AI, and/or that a computing device's AI is trustworthy, vulnerable, robust, secure, flexible, compliant, ethical, etc. Results may include for example (but not limited to) reports, screen outputs, dashboards, API calls, alarms, alerts, text messages, instant messages, emails, documents, machine-readable files, compressed files, and/or supporting evidence, etc.

35) Function of the Invention: Detecting and Mitigating Anomalous Data and/or Model Drift

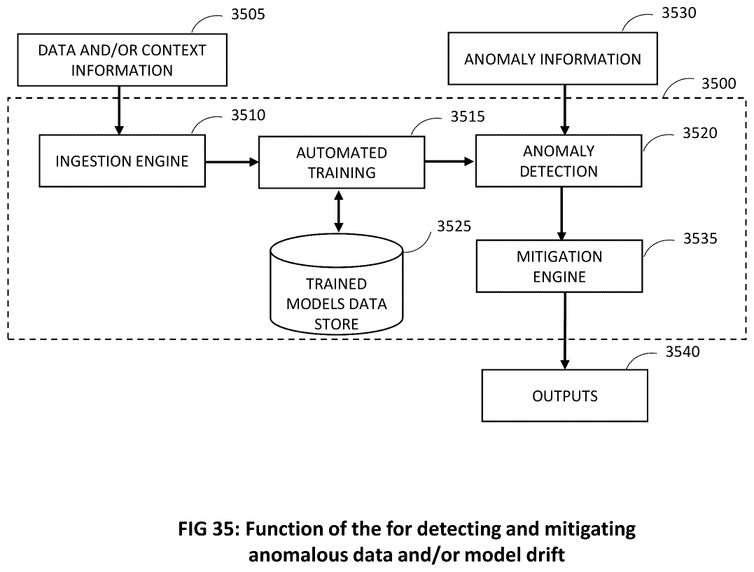

FIG. 35 depicts the analysis system for detecting and mitigating anomalous data that may be present in a dataset 3500. The analysis system may detect the likeliness of model drift occurring based on how the AI components and data are configured and stored. Both proactive and reactive, or just proactive or just reactive, mitigation of anomalous data and model drift may take place in the analysis system.

To detect the likeliness of model drift occurring, the analysis system may analyze context information. AI systems that may be analyzed include, but are not limited to, AI systems that rely on data from external data sources (e.g., online databases, and/or queries, etc.), reinforcement learning systems, continuous learning, AI systems that get continually retrained, AI systems that utilize customer data, AI systems that utilize data that relies on how users interact with a UI/UX, etc. Analyses to detect model drift may analyze, but is not limited to, the way in which data is stored, who has access to modify and add data to the dataset, the frequency in which data may be added, the user roles that may add data, and/or what type of data is included with the data, etc.

The analysis system may analyze a recommendation engine for an online shop for the likeliness of model drift occurring in its AI systems. This may take place prior to training, during training, and/or after training, etc. The recommendation engine may be continually retrained based on queries from users of the platform, such as (but not limited to) their search queries, what items they click on after a search query, if they click on any recommended search queries, and/or how long they look at a product's page, etc. Models may be trained for an individual user (e.g., how the individual user interacts with the online shop), and/or models may be trained globally (e.g., how many or all users interact with the online shop). There may be a possibility that the AI system may be susceptible to model drift in both instances, wherein the data may cause the AI system to drift from its original objective. If the analysis system is used for a recommendation engine for an online shop, the analysis system may determine for example, but not limited to, that users have no limit on how many data points they may represent, users may represent too many data points within a given frequency, and/or users may introduce malicious data through their recorded behavior, etc. the analysis system may preemptively mitigate model drift. It may do this in a variety of ways, including but not limited to, automatically limiting the amount of data a single user may introduce to the training data, limiting how often users may introduce data to the training data, limiting who can introduce data to the training data, and/or preventing users who have previously introduced malicious data from introducing data to the training data, etc.

The analysis system may detect model drift as it is occurring or has already occurred and may mitigate it. The analysis system may be analyzing for example (but not limited to) an Intrusion Detection System (IDS), monitoring system, logging system, logs, network traffic, API calls, and/or sensors etc., for vulnerabilities. Over time, a threat actor may introduce data to intentionally cause certain behavior to go undetected. The analysis system may detect this type of data being introduced, and/or may mitigate for example (but not limited to) by removing the malicious data, by removing all data originating from the user introducing it, by limiting the number of queries the user can make, and/or by providing alerts to administrators, etc. The data being introduced may not be intentionally malicious but may still result in model drift.

If, for example, the analysis system is to be used for analyzing an AI-based recommendation system for an online shop, and/or a similar use case involving AI systems, it may take a user's actions, record the actions, and then use for training the AI system on a continuous basis. Every time a user clicks on a product, it may for example record how often and how long they stay on a product screen, and use that data for retraining a global model. To skew the data toward their user behavior, a user may for example (but not limited to) click and view a product far more often or far longer than other users. The analysis system may detect that a user is introducing too many data points in comparison to other users. A set amount of data points per user may be determined for users of the analysis system, and the analysis system may limit the amount of data points from a single user or remove data points that are above a specific limit. the analysis system may detect a user introducing malicious data to the recommendation system and mitigate the malicious data and/or user (e.g., by banning the user, removing the user's data, etc.).

FIG. 35 depicts the analysis system for detecting and mitigating anomalous data and/or model drift. Other modules may be present, modules may be removed, and/or modules may be reordered. Data from multiple systems may be analyzed using the analysis system.

35.1) Data and/or Context Information

Data and or context information 3505 may be provided to the analysis system as input. Data may include, but is not limited to, training data, inference data, validation data, and/or testing data, etc. It may be data that has already been used to train a model. It may be data that engineers are planning to introduce to training data. It may be data that may be included in reinforcement learning and/or continuous learning. The data may include, but is not limited to, images, videos, text, audio, and/or tabular data, etc. The data may pertain to or come from one or more user. The data may be supplemented with context information about the data, such as (but not limited to), usernames, user IDs, emails, names, medium, and/or frequency, etc., that may provide more context into who, how, and/or where the data was derived from. This data may be retrieved or received by the analysis system through various mechanisms, including but not limited to, through analyzing and extracting data from the file system of a computing system, through an API, through a web GUI (e.g., a user defining the path to the data, and/or dragging and dropping data, etc.), through a MLaaS pipeline, a CI/CD pipeline, a MLOps pipeline, logs, intrusion detection systems, logging systems, monitoring systems, and/or sensors, etc.

### 35.2) Ingestion Engine

An ingestion engine 3510 may take in and handle the data and or context information 3505 provided. It may perform several actions on the data, including but not limited to, loading, preprocessing, normalizing, sorting, removing, modifying, storing and/or other action on the data. The ingestion engine may map how the additional context information relates to data provided (e.g., mapping the column or feature name, etc.).

### 35.3) Automated Training

The analysis system may train one or more models through automated training 3515 to analyze the data for a single user, multiple users, or all users, to determine if there is any anomalous data and/or to determine the likeliness of model drift occurring. Automated training may include training a machine learning model to detect anomalous data in the data provided in relation to the context information. It may create one or more baseline models that determine normal usage and may detect deviations. The resulting models may be stored for later use (e.g., for when new data is introduced by a user) in a trained models data store 3325. The models may be sent to an anomaly detection 3320 module for determining if the data contains anomalous data and/or is prone to model drift.

### 35.4) Anomaly Detection

The analysis system may include an anomaly detection 3320 module that may be used to detect anomalous data and/or detect the likeliness of model drift occurring based on the data and context information. Anomaly information may be externally provided that may define what constitutes an anomaly (e.g., a user making more than 30 queries a minute, a user adding more than 200 data points to the dataset a day, examples of outlier data, etc.). Anomaly detection analyses may include for example, but not limited to, AI-based analyses, statistics-based analyses, rules-based analyses, NLP-based analyses (e.g., on user queries), algorithmic-based analyses, and/or probabilistic-based analyses, etc. Anomaly detection may include for example, but not limited to, finding outliers, determining that data may result in model drift, detecting adversarial attacks, and/or detecting malicious data being introduced, etc. It may use rules provided from a user of the analysis system to detect anomalies (e.g., data being out of boundaries, and/or beyond limits, etc.). This module may result in for example (but is not limited to) a list of anomalous data, samples of anomalous data, a scorecard of anomalous data, a scorecard of the likeliness of model drift, an auditable log of the source of anomalous data, and/or a list of mitigations, etc.

### 35.5) Trained Models Data Store

The analysis system may include one or more trained models that are stored in a trained models data store 3525. Trained models from an automated training 3515 module may be stored in a variety of ways, including but not limited to, a file system, a distributed file system, in the Cloud, in a database, in a compressed format, and/or in a serialized format, etc. Information may be provided with the models (e.g., to query and/or retrieve models). Information provided with the models may include for example, but not limited to, the users the model was trained for, the date the model was trained, and/or the system the data came from, etc.

### 35.6) Anomaly Information

The analysis system may include anomaly information 3530 that may be provided to an anomaly detection 3520 module in the analysis system. Anomaly information may contain data on what constitutes an anomaly. This may include for example, but is not limited to, patterns of an anomaly, example datasets that contain known anomalies, and/or limits and/or boundaries for specific features, etc. Anomaly information may be provided a human (e.g., user), for example (but not limited to) via a Domain Specific Language (DSL), web interface, and/or file uploader etc. Anomaly information may be provided automatically from another system. This may for example (but not limited to) be provided from an instance of an analysis system, from a report from anomaly detection from another analysis tool, and/or from past results of the analysis system, etc.

### 35.7) Mitigation Engine

The analysis system may include a mitigation engine 3535 that may automatically mitigate detected anomalies and/or model drift. This may include but is not limited to removing data, modifying data, and/or limiting data from users, etc. Mitigations may be automatically determined by the analysis system. Mitigations may be mapped by a user or in a semi-automated manner based on the results of anomaly detection. Mitigations are not performed, and outputs 3540 are instead returned to the user directly from other modules.

### 35.8) Outputs

Outputs 3540 of the analysis system may be returned. Outputs may include, but are not limited to, a scorecard of how vulnerable the model and/or data are to model drift, if there is any anomalous data, a report of how compliant the model, data are in terms of privacy, a mitigated dataset, one or more trained models to detect anomalies, one or more trained models on the mitigated dataset, a list of users introducing anomalous data, report of supporting evidence, compressed file, document, file, screen output, alarm, alert, email, direct message, and/or API call, etc.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for analyzing at least one computing system for properties of at least one machine learning model comprised in the at least one computing system, the method comprising:
loading, via a processor, from a data storage, a memory, or via a communication, or via a user entry through a user interface, at least one input data for at least one machine learning model;
generating, via the processor, at least one surrogate model that simulates the behavior or characteristics, or an approximation of the behavior or the characteristics of the machine learning model, by using segments or an entirety of the loaded input data;
adjusting the at least one input data or the at least one surrogate model to enable the at least one analysis;
loading, from the data storage, the memory, or via the communication, or via the user entry through the user interface, and executing, via the processor, at least one analysis of a correlation between inputs and outputs of the at least one surrogate model, to identify at least one result pertaining to the at least one input data or the at least one machine learning model;
generating, via the processor, an output data describing the at least one result;
storing, via the processor, the output data pertaining to the at least one result in a memory; and
determining, via the processor, if the at least one result satisfies a predetermined condition, and if so, executing at least one action corresponding to the at least one result on the computing system.

2. The method according to claim 1, wherein the at least one computing system comprises at least one of an artificial intelligence system, machine learning model, simulation, control system, edge device, embedded device, information technology device, operational technology device, industrial control system, cyber-physical system, headset, mobile device, tablet device, or robotics system.

3. The method according to claim 1, wherein the properties comprise at least one of robustness, fairness, non-bias, transparency, interpretability, safety, security, reliability, accuracy, trust, explainability, privacy, or accountability.

4. The method according to claim 1, wherein analyzing the at least computing system is triggered after the machine learning model has been trained, or is triggered during CI/CD DevOps/DevSecOps.

5. The method according to claim 1, wherein the at least one machine learning model comprises at least one of Deep Learning (DL), Convolutional Neural Network (CNN), Multi-Layer Perceptrons (MLP), Natural Language Processing (NLP), Recurrent Neural Networks (RNN), Artificial Neural Networks (ANN), Reinforcement Learning (RL), Deep Neural Networks (DNN), Feed Forward Networks (FFNN), Long Short Term Memory (LSTM), or Generative Adversarial Networks (GAN).

6. The method according to claim 1, wherein the at least one machine learning model include specifications, source code, assembly code, binaries, compiled code, machine code, bitstreams, or FPGA bitstreams.

7. The method according to claim 1, wherein the at least one machine learning model is converted to IR before being used for inference for the surrogate model.

8. The method according to claim 1, wherein the at least one input data comprises at least one of training data, validation data, testing data, inference data, holdout data, cross-validation data, machine learning model, or a machine learning model's inference results such as the predicted features or the calculated gradient descent, data gathered from MLOps systems, Machine Learning as a Service, API-hosted models or data, cloud system, data bucket, data warehouse or data lake.

9. The method according to claim 1, wherein input data is loaded once, multiple times, or on a continuous basis.

10. The method according to claim 1, wherein loading the input data further comprises processing, including analyzing the input data for unexpected data, inconsistencies, anomalies, or out-of-distribution data.

11. The method according to claim 1, wherein input data comprises multiple sets of training data, validation data, testing data, multiple machine learning used as input, or where some or all models are considered as part of the analysis of the system.

12. The method according to claim 1, wherein the at least one surrogate model comprises at least one of a polynomial regressions, decision trees, sparse identification of nonlinear dynamics (SINDy), dynamic mode decomposition with control (DMDc), support vector machines, neural networks, forward stepwise regression, least absolute shrinkage and selection operator (LASSO), sequentially thresholded Ridge regression (STLSQ), sparse relaxed regularized regression (SR3), stepwise sparse regression (SSR), forward regression orthogonal least-squares (FROLS), or mixed-integer optimized sparse regression (MIOSR), multiple surrogate models pertaining to different data creating a single surrogate model, or a surrogate model that is less complex than the machine learning model it was created from.

13. The method according to claim 1, where the at least one surrogate model adapts to changing conditions, by training on new input data or results over time

14. The method according to claim 13, where adapting to changing conditions uses reinforcement learning.

15. The method according to claim 1, wherein adjusting the at least one input data or the at least one surrogate model comprises retraining surrogate models, modifying inputs into surrogate models, modifying input data, modifying surrogate model architecture, or changing surrogate model architecture.

16. The method according to claim 1, wherein the at least one analysis to be executed comprises equation analysis, scoring and clustering, detecting and mitigating biases in machine learning models, by analyzing the input data and model outputs for any systematic disparities in prediction accuracy for different groups of data samples, identifying incoming attacks on the machine learning model, detecting inconsistencies, detecting anomalies, analyzing multiple machine learning models on various subsets of data to identify which models perform best on specific subsets, comparing results of multiple surrogate models, or detecting similarities and differences between the at least one surrogate model and the machine learning model.

17. The method according to claim 1, wherein generating comprises generating at least one adversarial attack for the machine learning model using the input data, and creating at least one updated or new surrogate model that detects the at least one generated adversarial attack, wherein adversarial attacks comprise poison attacks, patch attacks, evasion attacks, inference attacks, extraction attacks, backdoor attacks, inversion attacks, mimic attacks, black-box attacks, white-box attacks, or gray-box attacks.

18. The method according to claim 1, wherein the at least one results comprises at least one of patterns, explainability/transparency, interpretability, biases, weaknesses, vulnerabilities, attacks, or anomalies of the at least one input data or the at least one surrogate model, interpretations of the model's predictions and decisions, or similarity between multiple sets of data or multiple machine learning models.

19. The method according to claim 1, wherein the at least one output data comprises at least one of an analysis report, user-readable analysis report, visualizations, suggestions, recommendations, scorecard, machine-readable analysis report, or API call.

20. The method according to claim 1, wherein the at least one action comprises at least one of presenting output data to a user, communicating output data to another machine, storing output data, triggering one or more notifications or alarms, blocking the functioning of the machine learning system, or triggering automated hardening of the machine learning system.

21. A system for analyzing at least one computing system for properties of at least one machine learning model comprised in the at least one computing system, the system comprising:
a processor;
a memory or a data storage that stores data and a program;
a communication device that communicates with the at least one computing system; and
a user interface that receives a user entry, wherein
when the program is executed by the processor, the processor is caused to
load, from the data storage, the memory, or via the communication device, or the user entry, at least one input data for at least one machine learning model;
generate, at least one surrogate model that simulates the behavior or characteristics, or an approximation of the behavior or the characteristics of the machine learning model, by using segments or an entirety of the loaded input data;
adjust the at least one input data or the at least one surrogate model to enable the at least one analysis;
load, from the data storage, the memory, or via the communication device, or via the user entry through the user interface, and execute at least one analysis of a correlation between inputs and outputs of the at least one surrogate model, to identify at least one result pertaining to the at least one input data or the at least one machine learning model;
generate an output data describing the at least one result;
store the output data pertaining to the at least one result in a memory; and
determine if the at least one result satisfies a predetermined condition, and if so, executing at least one action corresponding to the at least one result on the computing system.

22. The system according to claim 21, wherein the at least one computing system comprises at least one of an artificial intelligence system, machine learning model, simulation, control system, edge device, embedded device, information technology device, operational technology device, industrial control system, cyber-physical system, headset, mobile device, tablet device, or robotics system.

23. The system according to claim 21, wherein the properties comprise at least one of robustness, fairness, non-bias, transparency, interpretability, safety, security, reliability, accuracy, trust, explainability, privacy, or accountability.

24. The system according to claim 21, wherein the at least computing system is analyzed after the machine learning model has been trained, or is triggered during CI/CD DevOps/DevSecOps.

25. The system according to claim 21, wherein the at least one machine learning model comprises at least one of Deep Learning (DL), Convolutional Neural Network (CNN), Multi-Layer Perceptrons (MLP), Natural Language Processing (NLP), Recurrent Neural Networks (RNN), Artificial Neural Networks (ANN), Reinforcement Learning (RL), Deep Neural Networks (DNN), Feed Forward Networks (FFNN), Long Short Term Memory (LSTM), or Generative Adversarial Networks (GAN).

26. The system according to claim 21, wherein the at least one machine learning model include specifications, source code, assembly code, binaries, compiled code, machine code, bitstreams, or FPGA bitstreams.

27. The system according to claim 21, wherein the at least one machine learning model is converted to IR before being used for inference for the surrogate model.

28. The system according to claim 21, wherein the at least one input data comprises at least one of training data, validation data, testing data, inference data, holdout data, cross-validation data, machine learning model, or a machine learning model's inference results such as the predicted features or the calculated gradient descent, data gathered from MLOps systems, Machine Learning as a Service, API-hosted models or data, cloud system, data bucket, data warehouse or data lake.

29. The system according to claim 21, wherein input data is loaded once, multiple times, or on a continuous basis.

30. The system according to claim 21, wherein loading the input data further comprises processing, including analyzing the input data for unexpected data, inconsistencies, anomalies, or out-of-distribution data.

31. The system according to claim 21, wherein input data comprises multiple sets of training data, validation data, testing data, multiple machine learning used as input, or where some or all models are considered as part of the analysis of the system.

32. The system according to claim 21, wherein the at least one surrogate model comprises at least one of a polynomial regressions, decision trees, sparse identification of nonlinear dynamics (SINDy), dynamic mode decomposition with control (DMDc), support vector machines, neural networks, forward stepwise regression, least absolute shrinkage and selection operator (LASSO), sequentially thresholded Ridge regression (STLSQ), sparse relaxed regularized regression (SR3), stepwise sparse regression (SSR), forward regression orthogonal least-squares (FROLS), or mixed-integer optimized sparse regression (MIOSR), multiple surrogate models pertaining to different data creating a single surrogate model, or a surrogate model that is less complex than the machine learning model it was created from.

33. The system according to claim 21, where the at least one surrogate model adapts to changing conditions, by training on new input data or results over time.

34. The system according to claim 33, where adapting to changing conditions uses reinforcement learning.

35. The system according to claim 21, wherein adjusting the at least one input data or the at least one surrogate model comprises retraining surrogate models, modifying inputs into surrogate models, modifying input data, modifying surrogate model architecture, or changing surrogate model architecture.

36. The system according to claim 21, wherein the at least one analysis to be executed comprises equation analysis, scoring and clustering, detecting and mitigating biases in machine learning models, by analyzing the input data and model outputs for any systematic disparities in prediction accuracy for different groups of data samples, identifying incoming attacks on the machine learning model, detecting inconsistencies, detecting anomalies, analyzing multiple machine learning models on various subsets of data to identify which models perform best on specific subsets, comparing results of multiple surrogate models, or detecting similarities and differences between the at least one surrogate model and the machine learning model.

37. The system according to claim 21, wherein the surrogate model is generated by generating at least one adversarial attack for the machine learning model using the input data, and creating at least one updated or new surrogate model that detects the at least one generated adversarial attack, wherein adversarial attacks comprise poison attacks, patch attacks, evasion attacks, inference attacks, extraction attacks, backdoor attacks, inversion attacks, mimic attacks, black-box attacks, white-box attacks, or gray-box attacks.

38. The system according to claim 21, wherein the at least one results comprises at least one of patterns, explainability/transparency, interpretability, biases, weaknesses, vulnerabilities, attacks, or anomalies of the at least one input data or the at least one surrogate model, interpretations of the model's predictions and decisions, or similarity between multiple sets of data or multiple machine learning models.

39. The system according to claim 21, wherein the at least one output data comprises at least one of an analysis report, user-readable analysis report, visualizations, suggestions, recommendations, scorecard, machine-readable analysis report, or API call.

40. The system according to claim 21, wherein the at least one action comprises at least one of presenting output data to a user, communicating output data to another machine, storing output data, triggering one or more notifications or alarms, blocking the functioning of the machine learning system, or triggering automated hardening of the machine learning system.
